(19) United States
(12) Patent Application Publication
(10) Pub. No.: US 2026/0029173 A1
(43) Pub. Date: Jan. 29, 2026

(54) HIGH-EFFICIENCY THERMOELECTRIC COOLING AND HEATING SYSTEMS

(71) Applicant: ACTA-TechUS, Inc., Fresh Meadows, NY (US)

(72) Inventors: Peter N. Kaufman, Fresh Meadows, NY (US); Gilbert H. Dunham, JR., Irvington, NY (US); Andrew E. Masters, Berlin, MD (US)

(21) Appl. No.: 19/250,390

(22) Filed: Jun. 26, 2025

Related U.S. Application Data
(60) Provisional application No. 63/675,597, filed on Jul. 25, 2024.

(51) Int. Cl. F25B 21/04; H10N 10/17

(52) U.S. Cl. CPC F25B 21/04; H10N 10/17

(57) ABSTRACT

A device which comprises a thermoelectric module, where the thermoelectric module comprises a support structure, a first array of interconnect pads, a second array of interconnect pads, and a plurality of thermoelectric semiconductor pellets. The support structure has a first outer side and a second outer side, opposite the first outer side. The first array of interconnect pads is disposed on the first outer side of the support structure. The second array of interconnect pads is disposed on the second outer side of the support structure. The plurality of thermoelectric semiconductor pellets is disposed within the support structure, wherein each thermoelectric semiconductor pellet is connected to at least one interconnect pad of the first array of interconnect pads or the second array of interconnect pads.

### CROSS-REFERENCE TO RELATED APPLICATION

This application claims the benefit of U.S. Provisional Application Ser. No. 63/675,597, filed on Jul. 25, 2024, the disclosure of which is fully incorporated herein by reference.

### BACKGROUND

This disclosure relates generally to techniques for implementing thermoelectric cooling and heating. In general, as is known in the art, thermoelectric (TE) technology is based on a thermoelectric effect known as the Peltier effect. The Peltier effect occurs whenever electrical current flows through two dissimilar conductors, wherein depending on the direction of current flow, a junction of the two conductors will either absorb or release heat. Thermoelectric devices are typically utilized as solid-state heat pumps for heating and cooling applications on a small scale. For example, solid-state thermoelectric devices are typically utilized for applications such as, e.g., cooling small enclosures (e.g., coolers), active cooling of integrated circuit chips and electrical components (e.g., processors, laser diodes, etc.), implementing thermoelectric plates for wafer processing, etc. However, thermoelectric devices are not utilized for larger cooling/heating systems such as standard-size refrigerators systems, and air-conditioning systems for homes, commercial buildings, and motor vehicles. Instead, larger cooling/heating applications are implemented using compressor-based systems that rely on using evaporative refrigerants which are harmful to the environment, and which are very expensive. Thermoelectric devices enable cooling and heating without the use of harmful and expensive refrigerants.

### SUMMARY

Exemplary embodiments of the disclosure include techniques for implementing thermoelectric systems, modules, and devices for high-efficiency heating and cooling systems.

For example, an exemplary embodiment includes a device which comprises a thermoelectric module, which comprises: a support structure having a first outer side and a second outer side, opposite the first outer side; a first array of interconnect pads disposed on the first outer side of the support structure; a second array of interconnect pads disposed on the second outer side of the support structure; and a plurality of thermoelectric semiconductor pellets disposed within the support structure. Each thermoelectric semiconductor pellet is connected to at least one interconnect pad of the first array of interconnect pads or the second array of interconnect pads.

Another exemplary embodiment includes a system which comprises a thermoelectric module, a first fluid chamber, and a second fluid chamber. The thermoelectric module comprises: a support structure having a first outer side and a second outer side, opposite the first outer side; a first array of interconnect pads disposed on the first outer side of the support structure; a second array of interconnect pads disposed on the second outer side of the support structure; and a plurality of thermoelectric semiconductor pellets disposed within the support structure. Each thermoelectric semiconductor pellet is connected to at least one interconnect pad of the first array of interconnect pads or the second array of interconnect pads. The thermoelectric module is disposed between the first fluid chamber and the second fluid chamber. The first array of interconnect pads is disposed within a first opening of the first fluid chamber to enable the first array of interconnect pads to be in direct contact with a thermal transfer fluid which flows in the first fluid chamber. The second array of interconnect pads is disposed within a second opening of the second fluid chamber to enable the second array of interconnect pads to be in direct contact with a thermal transfer fluid which flows in the second fluid chamber.

Another exemplary embodiment includes a system which comprises a first fluid chamber, a second fluid chamber, and an array of thermoelectric semiconductor pellets. The first fluid chamber comprises a first array of interconnect pads disposed on a first outer surface of the first fluid chamber. The second fluid chamber comprises a second array of interconnect pads disposed on second outer surface of the second fluid chamber. The array of thermoelectric semiconductor pellets is disposed between the first outer surface of the first fluid chamber and the second outer surface of the second fluid chamber, where each thermoelectric semiconductor pellet comprises (i) a first end which is connected to a given interconnect pad of the first array of interconnect pads disposed on the first outer surface of the first fluid chamber, and (ii) a second end which is connected to a given interconnect pad of the second array of interconnect pads disposed on the second outer surface of the second fluid chamber.

Another exemplary embodiment includes a system which comprises a first fluid chamber, a second fluid chamber, and a thermoelectric module. The first fluid chamber comprises a first opening, and the second fluid chamber comprises a second opening. The thermoelectric module comprises a first outer side and a second outer side. The first outer side of the thermoelectric module is disposed within the first opening of the first fluid chamber to enable the first outer side of the thermoelectric module to be in direct contact with a thermal transfer fluid which flows in the first fluid chamber. The second outer side of the thermoelectric module is disposed within the second opening of the second fluid chamber to enable the second outer side of the thermoelectric module to be in direct contact with a thermal transfer fluid which flows in the second fluid chamber.

Other embodiments will be described in the following detailed description of exemplary embodiments, which is to be read in conjunction with the accompanying figures.

### BRIEF DESCRIPTION OF THE DRAWINGS

FIGS. 1A and 1B schematically illustrate a thermoelectric device which utilizes a thermoelectric effect to transfer heat flux through the thermoelectric device for temperature regulation applications.

FIG. 1C schematically illustrates an exemplary configuration of a thermoelectric device having a plurality of serially-connected thermoelectric couples.

FIG. 1D schematically illustrates an exemplary configuration of a thermoelectric system that is designed to cool air in a small enclosure.

FIG. 2A schematically illustrates a thermoelectric system, according to an exemplary embodiment of the disclosure.

FIG. 2B schematically illustrates a thermoelectric system, according to another exemplary embodiment of the disclosure.

FIGS. 3A, 3B, and 3C schematically illustrate a thermoelectric device which can be utilized to implement a thermoelectric system, according to an exemplary embodiment of the disclosure.

FIG. 4 schematically illustrates a thermoelectric device which can be utilized to implement a thermoelectric system, according to another exemplary embodiment of the disclosure.

FIGS. 5A, 5B, 5C, 5D, and 5E schematically illustrate a thermoelectric module, according to an exemplary embodiment of the disclosure.

FIGS. 6A, 6B, 6C, and 6D schematically illustrate a thermoelectric module, according to another exemplary embodiment of the disclosure.

FIG. 7A schematically illustrates a thermoelectric system, according to an exemplary embodiment of the disclosure.

FIG. 7B schematically illustrates a thermoelectric system, according to another exemplary embodiment of the disclosure.

FIGS. 8A and 8B schematically illustrate a thermoelectric system, according to another exemplary embodiment of the disclosure.

FIGS. 8C and 8D schematically illustrate a thermoelectric system, according to another exemplary embodiment of the disclosure.

FIGS. 8E and 8F schematically illustrate a thermoelectric system, according to another exemplary embodiment of the disclosure.

FIG. 9A schematically illustrates a thermoelectric system, according to another exemplary embodiment of the disclosure.

FIG. 9B schematically illustrates a thermoelectric system, according to another exemplary embodiment of the disclosure.

FIG. 9C schematically illustrates a thermoelectric system, according to another exemplary embodiment of the disclosure.

FIG. 9D schematically illustrates a thermoelectric system, according to another exemplary embodiment of the disclosure.

FIG. 9E is a perspective view of an exemplary configuration of a fluid chamber of the thermoelectric system of FIG. 9A, according to an exemplary embodiment of the disclosure.

FIG. 9F schematically illustrates a thermoelectric system, according to another exemplary embodiment of the disclosure.

FIGS. 10A and 10B schematically illustrate a thermoelectric system, according to another exemplary embodiment of the disclosure.

FIG. 11A schematically illustrates a thermoelectric system, according to another exemplary embodiment of the disclosure.

FIG. 11B schematically illustrates a thermoelectric system, according to another exemplary embodiment of the disclosure.

FIG. 12A schematically illustrates a thermoelectric module, according to another exemplary embodiment of the disclosure.

FIG. 12B schematically illustrates a thermoelectric system which can be implemented using the thermoelectric module of FIG. 12A, according to another exemplary embodiment of the disclosure.

FIGS. 13A and 13B schematically illustrate a thermal fluid chamber which can be fabricated using modular components, according to an exemplary embodiment of the disclosure.

FIG. 14 schematically illustrates a thermoelectric system, according to another exemplary embodiment of the disclosure.

FIG. 15 schematically illustrates a thermoelectric system, according to another exemplary embodiment of the disclosure.

FIG. 16A schematically illustrates a thermoelectric module, according to another exemplary embodiment of the disclosure.

FIGS. 16B, 16C, and 16D schematically illustrate a thermoelectric system which is implemented using the thermoelectric module of FIG. 16A, according to another exemplary embodiment of the disclosure,

FIG. 17A schematically illustrates a thermoelectric module, according to another exemplary embodiment of the disclosure.

FIGS. 17B, 17C, 17D, 17E, and 17F schematically illustrate plan views of various layers of a support structure of the thermoelectric module of FIG. 17A, according to an exemplary embodiment of the disclosure.

FIG. 18 schematically illustrates a thermoelectric module, according to another exemplary embodiment of the disclosure.

FIG. 19A schematically illustrates a thermoelectric module, according to another exemplary embodiment of the disclosure.

FIGS. 19B and 19C schematically illustrate a thermoelectric module, according to another exemplary embodiment of the disclosure.

FIG. 20A schematically illustrates a thermoelectric module, according to another exemplary embodiment of the disclosure.

FIG. 20B schematically illustrates a thermoelectric module, according to another exemplary embodiment of the disclosure.

FIG. 21A schematically illustrates a thermoelectric module, according to another exemplary embodiment of the disclosure.

FIG. 21B schematically illustrates a thermoelectric system which can be implemented using the thermoelectric module of FIG. 21A, according to another exemplary embodiment of the disclosure.

FIG. 22 schematically illustrates a thermoelectric module, according to another exemplary embodiment of the disclosure.

FIG. 23A schematically illustrates heat transfer characteristics of thermoelectric modules, according to exemplary embodiments of the disclosure.

FIG. 23B schematically illustrates heat transfer characteristics of a conventional thermoelectric module.

FIG. 24 schematically illustrates a thermoelectric system, according to another exemplary embodiment of the disclosure.

FIGS. 25A and 25B schematically illustrate a thermoelectric system, according to another exemplary embodiment of the disclosure.

FIGS. 26A and 26B illustrate perspective views of a thermoelectric system, according to another exemplary embodiment of the disclosure.

FIGS. 27A and 27B illustrate perspective views of a thermoelectric system, according to another exemplary embodiment of the disclosure.

FIG. 28 illustrates a perspective view of a thermoelectric system, according to another exemplary embodiment of the disclosure.

FIG. 29 illustrates a perspective view of a thermoelectric system, according to another exemplary embodiment of the disclosure.

FIG. 30 illustrates a perspective view of a thermoelectric system, according to another exemplary embodiment of the disclosure.

FIG. 31A schematically illustrates a thermoelectric system, according to another exemplary embodiment of the disclosure.

FIG. 31B schematically illustrates a thermoelectric system, according to another exemplary embodiment of the disclosure.

FIGS. 32A and 32B schematically illustrate a thermoelectric system, according to another exemplary embodiment of the disclosure.

FIG. 33A schematically illustrates a thermoelectric heating and cooling system, according to an exemplary embodiment of the disclosure.

FIG. 33B schematically illustrates a thermoelectric heating and cooling system, according to another exemplary embodiment of the disclosure.

FIGS. 34A and 34B schematically illustrate a thermoelectric heating and cooling system, according to another exemplary embodiment of the disclosure.

FIG. 35A schematically illustrates a thermoelectric heating and cooling system, according to another exemplary embodiment of the disclosure.

FIG. 35B schematically illustrates a thermoelectric heating and cooling system, according to another exemplary embodiment of the disclosure.

FIG. 36 schematically illustrates a system for controlling a thermoelectric heating and cooling system, according to an exemplary embodiment of the disclosure.

FIG. 37 schematically illustrates a thermoelectric heating and cooling system which can be implemented in a residential or commercial building, according to an exemplary embodiment of the disclosure.

FIG. 38 schematically illustrates a thermoelectric heating and cooling system which can be implemented with a geothermal system, according to an exemplary embodiment of the disclosure.

FIG. 39 schematically illustrates a thermoelectric module, according to another exemplary embodiment of the disclosure.

### DETAILED DESCRIPTION OF EXEMPLARY EMBODIMENTS

Embodiments of the disclosure will now be described in further detail with regard to techniques for implementing thermoelectric systems, thermoelectric modules, and thermoelectric devices for use in high-efficiency heating and cooling systems.

It is to be understood that same or similar reference numbers are used throughout the drawings to denote the same or similar features, elements, or structures, and thus, a detailed explanation of the same or similar features, elements, or structures will not be repeated for each of the drawings. The term “exemplary” as used herein means “serving as an example, instance, or illustration”. Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., ASICS, FPGAs, etc.), processing devices (e.g., central processing units, microprocessors, microcontrollers, etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

The term “thermal conductivity” of a material as used herein refers to a measure of the ability of the material to conduct heat through, e.g., thermal conduction or diffusion of thermal energy (heat) within the material and/or between materials that are in direct contact. The thermal conductivity, denoted κ, of a given material is a measure of how fast (or how much) heat can transfer through a given material, and is measured in watts per meter-kelvin (W/m·K) (based on the International System of units (SI base units)). For example, for a given layer of material with a given unit thickness (denoted d) and a given unit area (denoted A), the thermal conductivity κ of the given layer of material refers to the quantity of heat (denoted Q) that is transmitted through the given layer of material in a direction normal to the unit surface area A due to a temperature gradient (ΔT), i.e., κ=Q×(d/Δ×ΔT). In this regard, thermal conductivity is a measure of how easily heat energy moves through a given material or how well that material can transfer heat, which depends on the thermal properties of the given material. Materials with high thermal conductivity are good conductors of thermal energy, while objects with low thermal conductivity are good insulators.

The term “thermal conductance” of a given layer or element as used herein refers to a measure of how well heat can move through the given layer or element per unit time, wherein thermal conductance is based on the thermal conductivity κ of the material of the given layer or element, and the size and shape of the given layer or element. For example, for a given layer or element having a cross-sectional area A, and a total thickness D (or length), the thermal conductance C of the given layer or element is given by: C=κA/D, where D denotes the total thickness (or length) of the given layer or element in the direction of heat flow. The SI base units of thermal conductance C are watts per kelvin (W/K).

Moreover, the rate at which heat energy Q flows (heat flow) through the total thickness D (or length) of the given layer or element, with a temperature difference ΔT between the opposing sides/ends or surfaces of the given layer or element, is given by Q/t=K·A·ΔT/D=CΔT. In this regard, heat flow is a result of a temperature difference ΔT, and is measured in watts.

The term “heat flux” or “thermal flux” as used herein refers to a measure of the flow of heat energy Q (or heat transfer) per unit area A per unit time t, and is typically measured in SI base units of watts per square meter (W/m²). In this regard, heat flux (or thermal flux) is a derived quantity based on the principle of heat transfer and the area through which the heat is being transferred.

The term “British Thermal Unit (BTU)” as used herein represents a unit that is utilized to measure thermal (heat) energy, in particular, the amount of energy needed to raise 1 pound of water 1° F. at sea level. Typically, the term BTU is utilized in relation to air conditioning (AC) systems or heater systems to represent how many BTUs of heat the AC system or heating system can remove or add, respectively, to ambient air of a given environment for temperature control. It is known that one (1) watt of thermal energy is equal to 3.412141633 BTU per hour (i.e., 1 Watt=3.412 BTU/h). The conversion formula is standardized by the International Organization for Standardization (ISO), and is widely accepted for HVAC (heating, ventilation, and air conditioning) system engineering.

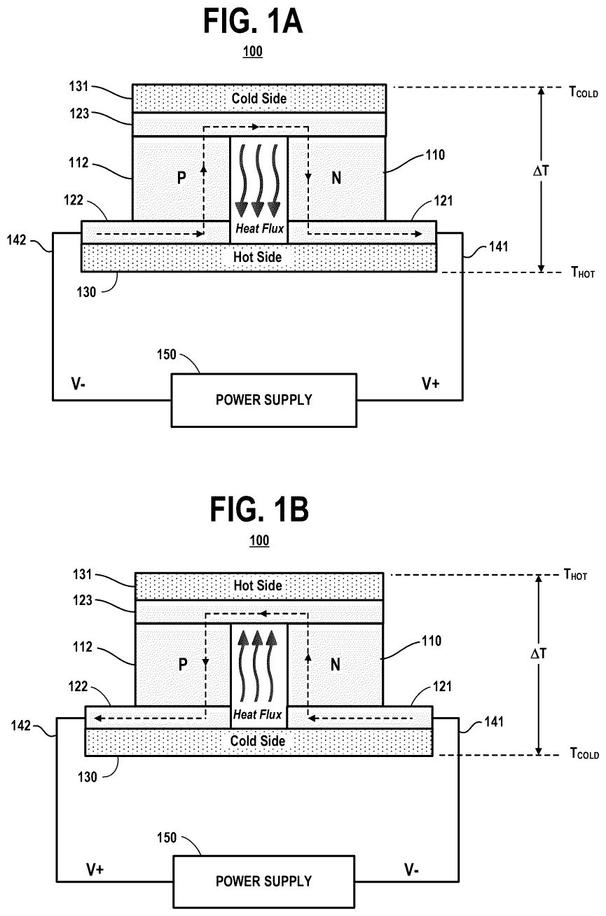

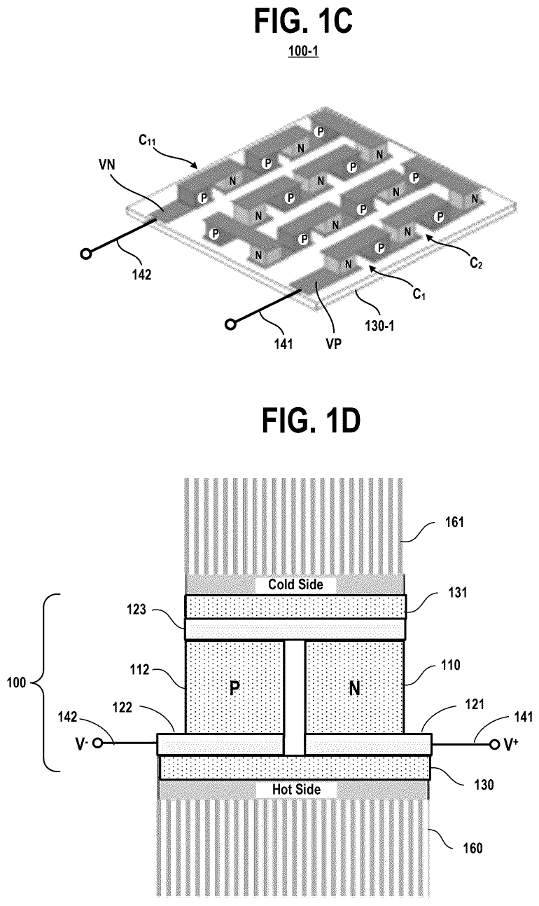

FIGS. 1A and 1B schematically illustrate a thermoelectric device which utilizes a thermoelectric effect to transfer heat flux through the thermoelectric device for temperature regulation applications. In particular, FIGS. 1A and 1B schematically illustrate a thermoelectric device 100 (or thermoelectric module) which comprises an N-type semiconductor thermoelectric element 110 (or N-type thermoelectric pellet) and a P-type semiconductor thermoelectric element 112 (or P-type thermoelectric pellet), first, second, and third electrical conductors 121, 122, and 123 (or electrical pads), a first substrate 130, and a second substrate 131. The first electrical pad 121 and the second electrical pad 122 are disposed on the first substrate 130, and the third electrical pad 123 is disposed on the second substrate 131. The pair of N-type and P-type thermoelectric pellets 110 and 112 form a “thermoelectric couple” which is disposed between the first and second substrates 130 and 131.

The N-type and P-type thermoelectric pellets 110 and 112 are formed using suitable thermoelectric semiconductor materials. For instance, the N-type and P-type thermoelectric pellets 110 and 112 can be formed of suitable semiconductor alloy materials such as bismuth-telluride (BiTe) based alloys, bismuth-antinomy (BiSb) alloys, bismuth-antinomy-telluride (BiSbTc) alloys, bismuth-selenium-telluride (BiSeTe) alloys, etc., depending on the application. While the N-type and P-type thermoelectric pellets 110 and 112 can be formed of similar alloy materials, the N-type and P-type thermoelectric pellets 110 and 112 have different free electron densities at the same temperature. In particular, the P-type thermoelectric pellet 112 is formed of a thermoelectric semiconductor material having a deficiency of electrons (i.e., having positive charge carriers or “holes”), while the N-type thermoelectric pellet 110 is formed of a thermoelectric semiconductor material having an excess of electrons (i.e., negative charge carriers).

The first and second substrates 130 and 131 can be formed of a ceramic material including, e.g., aluminum oxide (Al₂O₃) or aluminum nitride (AlN). When formed of ceramic, the first and second substrates 130 and 131 are structurally rigid to provide mechanical integrity of the thermoelectric device 100. In addition, ceramic substrates include other desirable properties for constructing thermoelectric devices such as, e.g., high thermal conductivity (high thermal conductance to provide heat transfer in and out of the thermoelectric device 100 with minimal thermal resistance), and high electrical insulation properties to, e.g., electrically isolate electrical pads that are formed on a surface of ceramic substrate.

The first, second, and third electrical pads 121, 122, and 123 are formed of a low-resistance metallic material, such as copper. The first, second, and third electrical pads 121, 122, and 123 can be formed by a direct bond copper process, or otherwise such as depositing and patterning one more layers of metallic material on the surfaces of the first and second substrates 130 and 131 to form a pattern of electrical interconnect pads that are arranged to serially connect the N-type and P-type thermoelectric pellets 110 and 112. The N-type and P-type thermoelectric pellets 110 and 112 can be soldered to the first, second, and third electrical pads 121, 122, and 123 using suitable solder material such as lead-tin (Pb—Sn), antimony-tin (Sb—Sn) and gold-tin (Au—Sn) alloys, or other suitable solder materials with melting points that are greater than the highest operating temperature of the thermoelectric device 100.

As further schematically shown in FIGS. 1A and 1B, a first lead wire 141 is connected (e.g., soldered) to the first electrical pad 121, and a second lead wire 142 is connected (e.g., soldered) to the second electrical pad 122. The first and second lead wires 141 and 142 deliver direct current (DC) power from a DC power supply 150 to operate the thermoelectric device 100, as discuss in further detail below.

The N-type and P-type thermoelectric pellets 110 and 112 are electrically connected in series, and thermally connected in parallel between the first and second substrates 130 and 131. In particular, the N-type thermoelectric pellet 110 is connected (e.g., soldered) to and between the first and third electrical pads 121 and 123, and the P-type thermoelectric pellet 112 is connected (e.g., soldered) to and between the second and third electrical pads 122 and 123. In this configuration, an electrical current path is formed through the thermoelectric device 100, wherein the electrical current path includes a series connection of the first electrical pad 121, the N-type thermoelectric pellet 110, the third electrical pad 123, the P-type thermoelectric pellet 112, and the second electrical pad 122.

The thermoelectric device 100 operates as a solid-state heat pump based on the thermoelectric effect (in particular, the Peltier effect) to generate a heat flux movement through the N-type and P-type thermoelectric pellets 110 and 112 from one side of the thermoelectric device 100 to the other side, with consumption of electrical energy, depending on the direction of the current flow through the electrical path. The N-type and P-type thermoelectric pellets 110 and 112 operate in parallel, thermally, to perform the heat pumping operation of the thermoelectric device 100. In particular, the N-type and P-type thermoelectric pellets 110 and 112 operate in parallel to “pump” heat in the direction of charge carrier movement through the N-type and P-type thermoelectric pellets.

For example, FIG. 1A illustrates an exemplary mode of operation of the thermoelectric device 100 with the power supply 150 connected to the thermoelectric device 100 with a positive polarity (V+) applied to the first electrical pad 121, and a negative polarity (V−) applied to the second electrical pad 122, resulting in a current flow (flow of electrons) through the thermoelectric device 100 in the electrical path (as schematically illustrated by the dashed-line arrows) from the second electrical pad 122 to the first electrical pad 121. With the electrons flowing through the N-type thermoelectric pellet 110 from top to bottom, heat is absorbed at the top junction of the N-type thermoelectric pellet 110 and actively transferred to the bottom junction. Similarly, with the “holes” flowing through the P-type thermoelectric pellet 112 (opposite to electron flow) from the top to bottom, heat is absorbed at the top junction of the P-type thermoelectric pellet 112 and actively transferred to the bottom junction.

The resulting current flow through the N-type and P-type thermoelectric pellets 110 and 112 causes the first substrate 130 to be heated (THOT) and the second substrate 131 to be cooled (T_{COLD}), creating a temperature differential ΔT between a “cold side” and a “hot side” of the thermoelectric device 100. The temperature differential ΔT (between the first and second substrates 130 and 131) allows a heat load to be absorbed by the second substrate 131 (cold side substrate) and transferred to the first substrate 130 (hot side substrate) through the N-type and P-type thermoelectric pellets 110 and 112, where the absorbed heat can be dissipated. In this regard, wavey solid line arrows in FIG. 1A schematically illustrate a direction of heat flux (conduction heat transfer) from the second substrate 131 (cold side substrate) to the first substrate 130 (hot side substrate) through the N-type and P-type thermoelectric pellets 110 and 112.

On the other hand, FIG. 1B illustrates an exemplary mode of operation of the thermoelectric device 100 with the power supply 150 connected to the thermoelectric device 100 in a “reverse polarity” with the positive polarity (V+) applied to the second electrical pad 122, and the negative polarity (V−) applied to the first electrical pad 121, resulting in a current flow (flow of electrons) through the thermoelectric device 100 in the electrical path (as schematically illustrated by the dashed-line arrows) from the first electrical pad 121 to the second electrical pad 122. The resulting current flow through the N-type and P-type thermoelectric pellets 110 and 112 causes the first substrate 130 to be cooled (T_{COLD}) and the second substrate 131 to be heated (T_{HEAT}), creating a temperature differential ΔT between the “cold side” and the “hot side” of the thermoelectric device 100. The temperature differential ΔT (between the first and second substrates 130 and 131) allows a heat load to be absorbed by the first substrate 130 (cold side substrate) and transferred to the second substrate 131 (hot side substrate) through the N-type and P-type thermoelectric pellets 110 and 112, where the absorbed heat can be dissipated. In this regard, wavy solid line arrows in FIG. 1B schematically illustrate a direction of heat flux (conduction heat transfer) from the first substrate 130 (cold side substrate) to the second substrate 131 (hot side substrate) through the N-type and P-type thermoelectric pellets 110 and 112.

It is to be noted that for case of illustration and discussion, the thermoelectric device 100 of FIGS. 1A and 1B is shown as including a single thermoelectric couple (single pair of N-type and P-type thermoelectric pellets 110 and 112). However, thermoelectric devices according to exemplary embodiments of the disclosure includes multiple thermoelectric couples that are serially connected to each other in a given rectangular array configuration 100 to provide greater heat-pumping capacity, as compared to a single thermoelectric couple. For example, FIG. 1C schematically illustrates an exemplary configuration of a thermoelectric device 100-1 having eleven (11) thermoelectric couples (C₁, C₂, . . . , C₁₁) that are serially connected via a pattern of lower interconnect pads formed on a first substrate 130-1, and a pattern of upper interconnect pads formed on a second substrate (not shown). The thermoelectric couples (C₁, C₂, . . . , C₁₁) are serially connected between first (positive) power pad VP and second (negative) power pad VN. While FIG. 1C illustrates 11 thermocouple pairs for case of illustration, as explained in further detail below, a thermoelectric device can be formed with hundreds of thermoelectric couples which are electrically connected in series between first (positive) and second (negative) power pads, and which are thermally connected in parallel between first and second substrates. The N-type and P-type thermoelectric pellets are arranged in an alternating pattern and connected by electrical interconnect pads with a corresponding pad pattern to form a series circuit (chain of serially connected thermoelectric couples) through the thermoelectric device.

In general, a cooling capacity (denoted Q) of a thermoelectric device is based on various factors including, but not limited to, the number of thermoelectric couples, and the sizes (height and cross-sectional area) of the N-type and P-type thermoelectric pellets. The cooling capacity of a thermoelectric device is proportional to the total cross-sectional area of all the N-type and P-type thermoelectric pellets. For a given number of thermoelectric pellets, a higher cooling capacity can be achieved by decreasing the heights of the thermoelectric pellets and/or increasing the cross-sectional area of the thermoelectric pellets, at the cost of increasing the operating current and a total power consumption. On the other hand, decreasing the cross-sectional area and increasing the height of the thermoelectric pellets serves to increase a maximum temperature difference and reduce power consumption, at the cost of reduced cooling capacity. In this regard, the height of the thermoelectric pellets is a balance between (i) taller thermoelectric pellets, which will have a greater thermal resistance between the hot and cold sides of the thermoelectric device, and allow a lower temperature to be reached, but produce more resistive heating, and (ii) shorter thermoelectric pellets, which will have a greater electrical efficiency but allow more heat leakage from the hot side to the cold side by thermal conduction.

A conventional thermoelectric device is typically characterized by various performance parameters and properties. For example, the term T_{COLD} denotes the temperature of the cold-side surface of the thermoelectric device. The term T_{HOT} denotes the temperature of the hot-side surface of the thermoelectric device. The term ΔT denotes an operating temperature difference (e.g., T_{HOT}−T_{COLD}) between the hot-side and the cold-side surfaces of the thermoelectric device. The term ΔT_{MAX} denotes a maximum possible ΔT across the thermoelectric device for a given level of T_{HOT} when the thermal load (Q) (at the cold side) is at zero watts. The term Q_{MAX} denotes a maximum cooling capacity of the thermoelectric device with ΔT_{MAX}=0. It is to be noted that as the thermal load (Q) increases, the resultant ΔT decreases. At a certain thermal load specification, the ΔT will be reduced to zero, wherein the thermal load which produces this condition is referred to as Q_{MAX}. This specification does not represent a maximum amount of heat that the thermoelectric device can handle, since if the thermal load increases beyond Q_{MAX}, the thermoelectric device will still pump heat, but the thermal load will wind up at an above-ambient temperature.

The term V_{MAX} denotes a DC voltage that will achieve a maximum possible ΔT across the thermoelectric device at a given T_{HOT}. At voltages below V_{MAX}, there is insufficient current to achieve the greatest ΔT, while at voltages above V_{MAX}, the power dissipation within the thermoelectric device begins to increase the device temperatures and diminish ΔT. Note that V_{MAX} is temperature dependent in that the higher the temperature, the higher the V_{MAX} rating for a given thermoelectric device. The term I_{MAX} denotes the DC current level which will produce the maximum possible ΔT across the thermoelectric device. When operating below I_{MAX}, there is insufficient current to achieve the greatest ΔT. On the other hand, when operating above I_{MAX}, the power dissipation (I²R) within the thermoelectric device begins to increase the device temperatures and diminish ΔT. The parameters I_{MAX} and V_{MAX} occur at the same operating point, i.e., I_{MAX} is the current level that is generated when V_{MAX} is applied to the thermoelectric device. Unlike V_{MAX}, I_{MAX} is not especially temperature dependent and tends to be fairly constant throughout the operating range of the thermoelectric device.

The term coefficient of performance (COP) denotes an efficiency of a thermoelectric cooling (or heating) device. The COP is essentially a ratio of (i) the heat pumped by a thermoelectric device (in watts) and (ii) the amount of power supplied to the thermoelectric device, i.e.,

$$C O P = \frac{Q}{V \times I} ,$$

where Q denote the amount of watts pumped, and V×I represents the amount of power supplied to the thermoelectric device based on the voltage V and/supplied to the thermoelectric device.

FIG. 1D schematically illustrates an exemplary configuration of a thermoelectric system that is designed to cool air in a small enclosure. In particular, FIG. 1D schematically illustrates the exemplary thermoelectric device 100 of FIGS. 1A and 1B coupled to a first heat sink 160 and a second heat sink 161. The first heat sink 160 is thermally coupled to the first (hot side) substrate 130, and the second heat sink 161 is coupled to the second (cold side) substrate 131. The second heat sink 161 can be disposed within an enclosure (e.g., cooler), wherein the second heat sink 161 absorbs heat within the enclosure, and the thermoelectric device 100 pumps the heat from the second heat sink 161 to the first heat sink 160 disposed on the outside of the enclosure, wherein the first heat sink 160 serves as a heat exchanger that releases the collected heat into the ambient air. A fan can be used to blow/circulate air through fins of the first heat sink 160 to enhance the release of the collected heat from the first heat sink 160. The heat dissipated on the hot side includes what is pumped from the cold side, but also the heat produced within the thermoelectric device 100.

A disadvantage with the exemplary thermoelectric system configuration shown in FIG. 1D is that (i) the thermal interface between the first substrate 130 and the first heat sink 160, (ii) the thermal interface between the second substrate 131 and the second heat sink 161, and (iii) the first and second heat sinks 160 and 161 themselves, all collectively add to a total thermal resistance R_{TH} in the thermal path between the hot and cold sides of the thermoelectric system, which can prevent the thermoelectric device 100 from achieving the maximum level of thermal transfer from the cold side to the hot side for a cooling operation (and vice versa for a heating operation). In other words, heat sink configurations are inefficient because the thermal path includes many transition interfaces and is relatively long before the thermal energy reaches its intended dissipation. For example, on the hot side, thermal energy leaves the thermoelectric pellets, passes through the metallic pads 121 and 122 and the first substrate 130, passes through the interface material (e.g., thermal paste or thermal interface material) between the first substrate 130 and the first heat sink 160, and then passes through the material of the first heat sink 160 before being dissipated from the first heat sink 160 to the ambient. Each of these heat transfer elements/materials has its own thermal conductivity, thermal time constant and thermal capacity, and adds to the total thermal resistance in the thermal path.

As noted above, exemplary embodiments of the disclosure include various configurations of thermoelectric systems for cooling and heating applications, which are configured to reduce or otherwise eliminate thermal resistance in the thermal path beyond the hot and cold sides of a thermoelectric device. In some embodiments, thermoelectric systems as described herein utilize thermal fluid chambers which are configured to allow a thermal fluid to flow in direct contact with the hot-side and cold-side substrates of the thermoelectric devices, thereby achieving a 100% thermal transfer between the hot-side surface of the thermoelectric devices and the hot end point (e.g., heated thermal fluid), and a 100% thermal transfer between the cold-side surfaces of the thermoelectric devices and the cold end point (e.g., cooled thermal fluid).

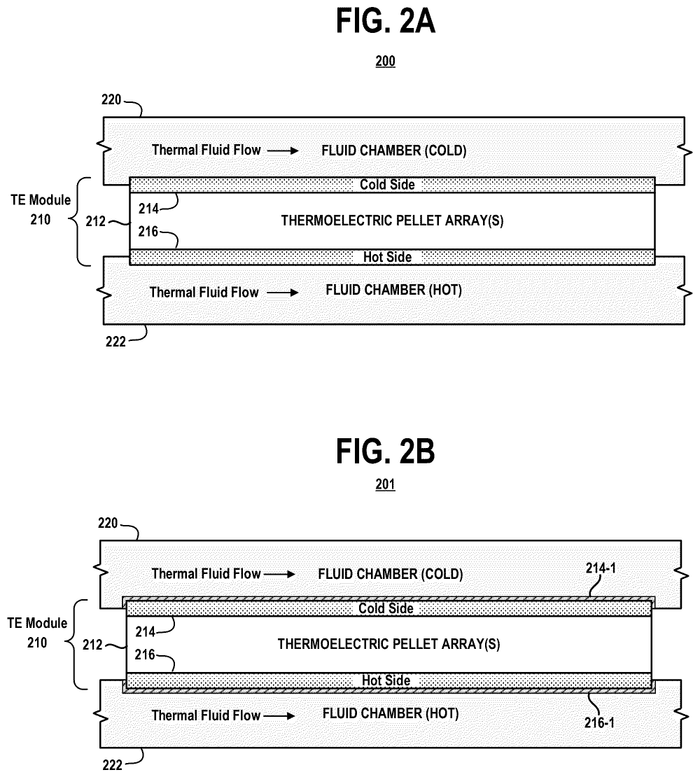

For example, FIG. 2A schematically illustrates a thermoelectric system according to an exemplary embodiment of the disclosure. In particular FIG. 2A schematically illustrates a thermoelectric system 200 which comprises a thermoelectric module 210 (or TE module), a first fluid chamber 220, and a second fluid chamber 222. In general, the thermoelectric module 210 comprises one or more arrays of thermoelectric pellets 212 (e.g., arrays of serially connected thermoelectric couples), a first substrate 214, and a second substrate 216. The thermoelectric pellets 212 are disposed between the first and second substrates 214 and 216. It is to be noted that while the thermoelectric module 210 is generically illustrated in FIG. 2A, the thermoelectric module 210 can be constructed to have one of various thermoelectric module architectures as illustrated and discussed herein. The first substrate 214 of the thermoelectric module 210 has a surface that is disposed within an opening of the first fluid chamber 220 in direct contact with a thermal fluid that flows in the first fluid chamber 220. Similarly, the second substrate 216 of the thermoelectric module 210 has a surface that is disposed within an opening of the second fluid chamber 222 in direct contact with a thermal fluid that flows in the second fluid chamber 222.

FIG. 2A illustrates an exemplary mode of operation of the thermoelectric module 210 in which the first substrate 214 comprises the cold side of the thermoelectric module 210, and the second substrate 216 comprises the hot side of the thermoelectric module 210. In this configuration, the thermoelectric module 210 acts as a heat pump to absorb heat from the thermal fluid flowing in the first fluid chamber 220 (e.g., cold fluid chamber), and transfer the absorbed heat through the thermoelectric module 210 to the hot side where the heat is dissipated to the thermal fluid flowing in the second fluid chamber 222 (e.g., hot fluid chamber). The cold thermal fluid in the first fluid chamber 220 is circulated through a first coil to cool air that is blown through a first coil to cool a given environment (e.g. home). On the other hand, the hot thermal fluid in the second fluid chamber 222 is circulated through a second coil with air blown through the second coil to cool down the hot thermal fluid. The first fluid chamber 220 is part of a first closed-loop system in which the thermal fluid which flows through the first fluid chamber 220 is circulated in the first closed-loop system via a pump. Similarly, the second fluid chamber 222 is part of a second closed-loop system in which the thermal fluid which flows through the second fluid chamber 222 is circulated in the second closed-loop system via a pump.

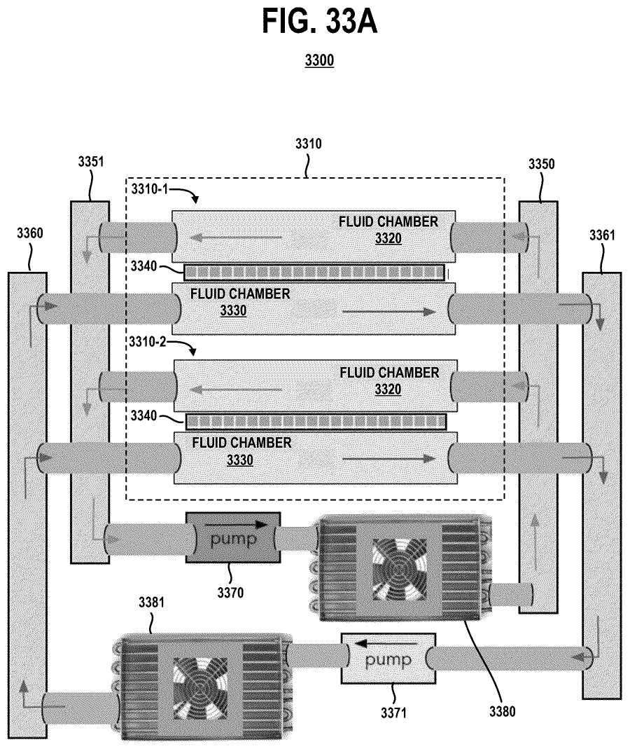

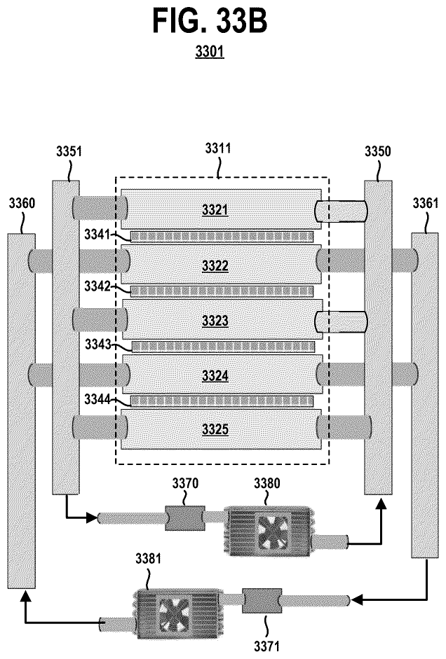

The thermal fluids can be implemented using water, or other suitable types of the thermal fluids (or heat transfer fluids) which are compatible with the materials within the system that are in contact with the thermal fluids (e.g., thermal fluid does not cause corrosion of the materials in contact with the thermal fluid material). For example, besides water, the thermal fluids can be heat transfer fluids such as engineered potassium formate heat transfer fluids, glycol (ethylene or propylene), or any other suitable heat transfer fluid that can be utilized as a suitable thermal transfer medium that can be implemented in a closed loop system and in continuous cycles for the thermoelectric cooling and heating systems and applications as discussed herein, as long as the fluid is compatible with the materials within the system that will come in contact with. An exemplary cooling and heating system which can implement the thermoelectric system 200 will be discussed in further detail below in conjunction with, e.g., FIGS. 33A, 33B, 34A, 34B, 35A, 35B, and 37.

FIG. 2B schematically illustrates a thermoelectric system according to another exemplary embodiment of the disclosure. In particular FIG. 2B schematically illustrates a thermoelectric system 201 which is similar to the thermoelectric system 200 of FIG. 2A, except that the thermoelectric module 210 as shown in FIG. 2B includes a thin protective layer 214-1 formed on the surface of the first substrate 214 which is in contact with the thermal fluid in the first fluid chamber 220, and a thin protective layer 216-1 which is formed on the surface of the second substrate 216 which is in contact with the thermal fluid in the second fluid chamber 222. The first and second protective layers 214-1 and 214-2 are utilized, if needed, to prevent corrosion of the first and second substrates 214 and 216 from the thermal fluid flowing in the first and second fluid chambers 220 and 222.

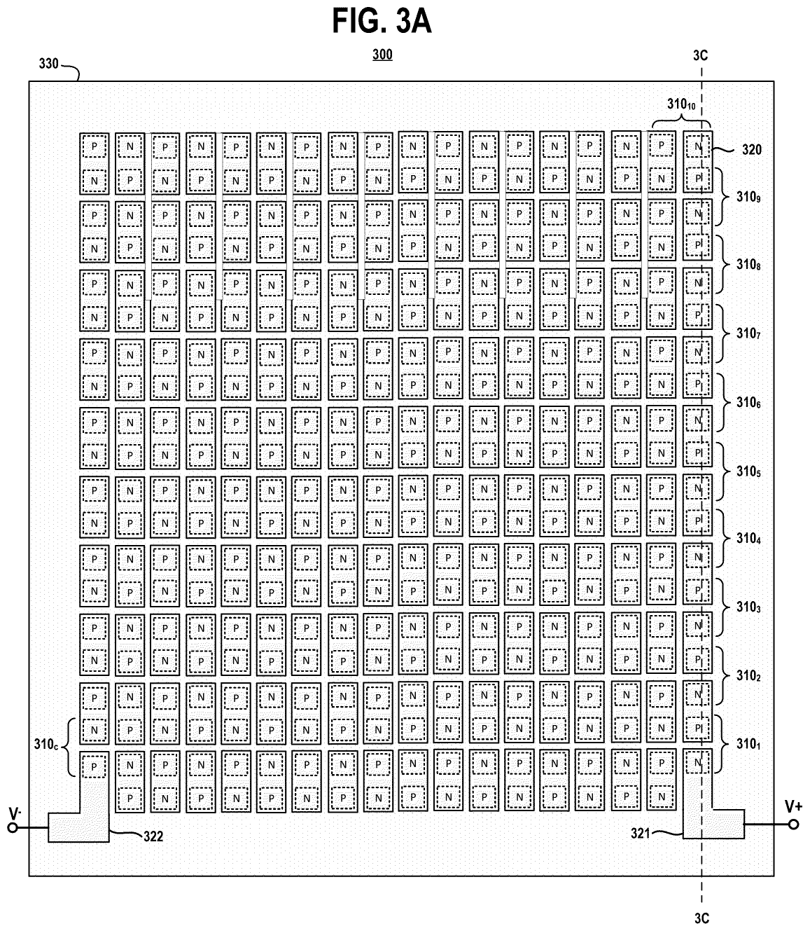

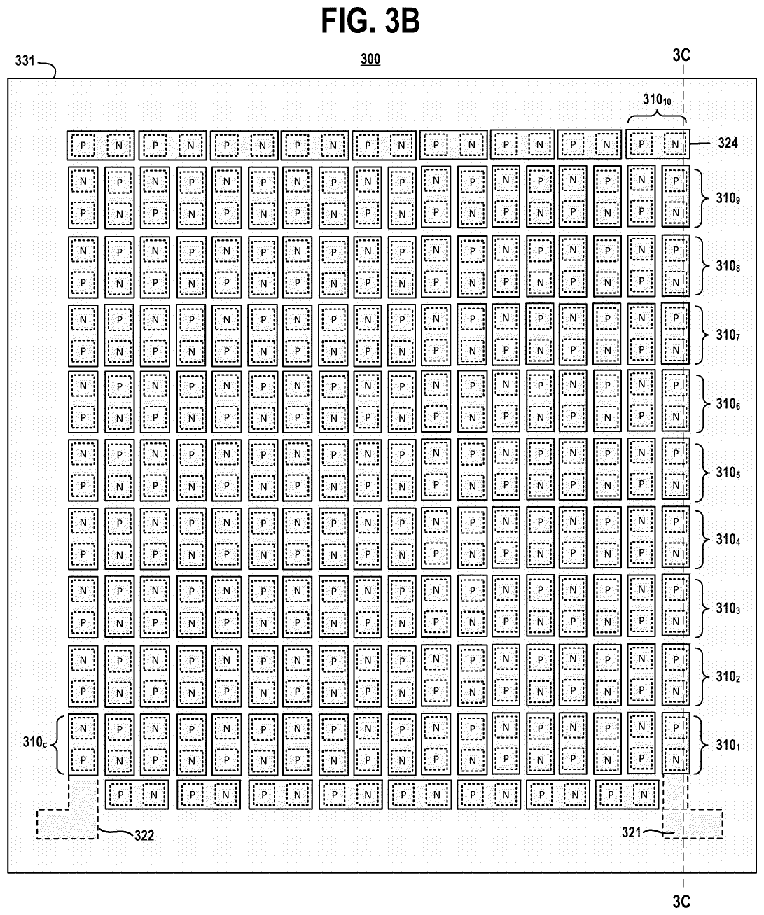

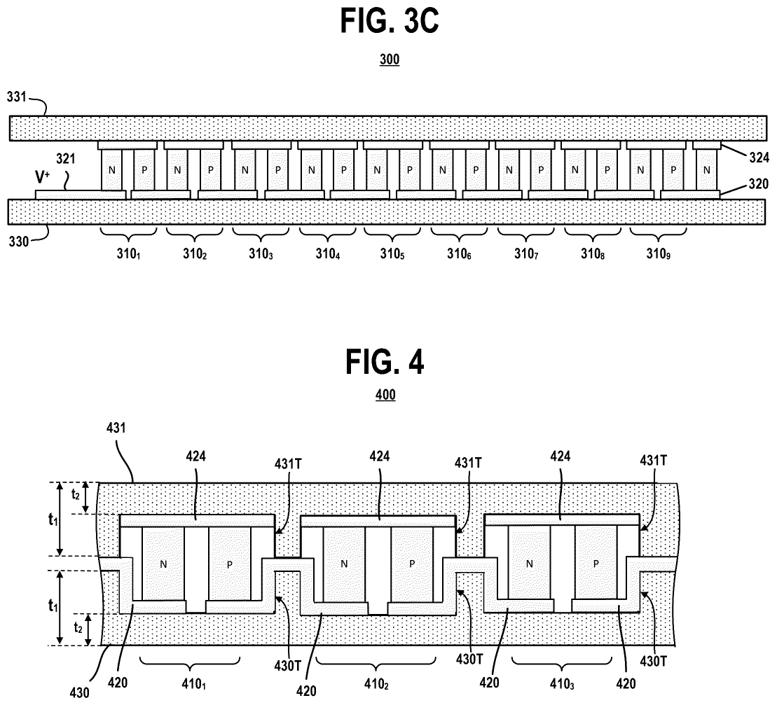

FIGS. 3A, 3B, and 3C schematically illustrate a thermoelectric device which can be utilized to implement a thermoelectric system, according to an exemplary embodiment of the disclosure. In particular, FIG. 3A schematically illustrates a portion of the thermoelectric device 300 which comprises a first substrate 330 (e.g., ceramic substrate), an array of electrical interconnect pads 320, a first power pad 321, and a second power pad 322 disposed on a surface of the first substrate 330, and a plurality of thermoelectric couples 310₁, 310₂, 310₃, 310₄, 310₅, 310₆, 310₇, 310₈, 310₉, 310₁₀, . . . , 310_{c}, each comprising a P-type thermoelectric pellet and an N-type thermoelectric pellet, wherein bottom sides of the thermoelectric pellets are soldered to corresponding ones of the electrical interconnect pads 320, and the first and second power pads 321 and 322, as schematically shown in FIG. 3A. Further, FIG. 3B schematically illustrates a portion of the thermoelectric device 300 which comprises a second substrate 330 (e.g., ceramic substrate) and an array of electrical interconnect pads 324, wherein upper sides of the thermoelectric pellets are soldered to corresponding ones of the electrical interconnect pads 324, as schematically shown in FIG. 3B.

FIG. 3C is a cross-sectional side view of the thermoelectric device 300 along lines 3C-3C in FIGS. 3A and 3B. FIGS. 3A, 3B, and 3C collectively illustrate an exemplary configuration of the thermoelectric device 300 in which the plurality of thermoelectric couples 310₁, 310₂, 310₃, 310₄, 310₅, 310₆, 310₇, 310₈, 310₉, 310₁₀, . . . , 310_{c} are serially connected to each other (via the pattern of lower interconnect pads 320 and upper interconnect pads 324) to form a single electrical path between the first (positive) power pad 321 and the second (negative) power pad 322, wherein the electrical path meanders back and forth in a given rectangular array configuration. The number of thermoelectric couples that are implemented can vary depending on the desired application. For example, in a non-limiting exemplary embodiment, the number of thermoelectric couples can be c=127 (a total of 254 thermoelectric pellets). In another exemplary embodiment, the number of thermoelectric couples can be c=197 (a total of 394 thermoelectric pellets).

In some embodiments, the thermoelectric device 300 of FIGS. 3A, 3B, and 3C can be used to implement the thermoelectric module 210 shown in FIGS. 2A and 2B. In such configuration, the first and second ceramic substrates 330 and 331 of the thermoelectric device 300 would be in direct contact with the thermal fluid in the first and second fluid chambers 220 and 222. In this instance, a full thickness of the first and second ceramic substrates 330 and 331 of the thermoelectric device 300 would be part of the thermal path between the cold side and hot side of the thermoelectric device 300. While the first and second ceramic substrates 330 and 331 are relatively thin and preferably formed with high thermal conductivity ceramics, such as aluminum oxide or aluminum nitride, the first and second ceramic substrates 330 and 311 do provide a small amount of thermal resistance, which can be reduced using the exemplary configuration shown in FIG. 4.

For example, FIG. 4 schematically illustrates a thermoelectric device 400 which can be utilized to implement a thermoelectric system, according to another exemplary embodiment of the disclosure. The thermoelectric device 400 comprises an architecture that facilitates improved thermal transfer from thermoelectric pellets through ceramic substrates to the hot and cold sides of the thermoelectric device. In particular, the thermoelectric device 400 comprises a plurality of thermoelectric couples 410₁, 410₂, and 410₃, a plurality of lower interconnect pads 420, a plurality of upper interconnect pads 424, a first substrate 430, and a second substrate 431. The first and second substrates 430 and 431 are shown to have a same thickness t₁. A set of first trenches 430T are formed (e.g., etched) in a surface of the first substrate 430, and a set of second trenches 431T are formed (e.g., etched) in a surface of the second substrate 431, which are aligned to corresponding ones of the first trenches 430T. The formation of the first trenches 430T and the second trenches 431T in the first and second substrates 430 and 431 results in thinned portions of the first and second substrates 430 and 431 where the first and second trenches 430T and 431T are formed. As schematically illustrated in FIG. 4, the thinned portions of the first and second substrates 430 and 431 have a reduced thickness t₂, where t₂<t₁.

Moreover, as schematically illustrated in FIG. 4, each thermoelectric couple 410₁, 410₂, and 410₃ is disposed in a corresponding pair of trenches of the first and second trenches 430T and 431T, which are aligned to each other over the surfaces of the first and second substrates 430 and 431. The lower interconnect pads 420 are formed on the etched surface of the first substrate 430 to electrically connect adjacent thermoelectric elements that are disposed in adjacent trenches of the first trenches 430T (i.e., each lower interconnect pads 420 is formed to extend between two adjacent trenches of the first trenches 430T). On the other hand, each upper interconnect pad 424 is disposed in a respective one of the second trenches 431T to electrically connect the upper sides of the respective thermoelectric couples 4101, 4102, and 4103 that are disposed within the second trenches 431T.

The first and second trenches 430T and 431T of the first and second substrates 430 and 431 serve multiple purposes. For example, disposing the thermoelectric couples 410₁, 410₂, and 410₃ in the first trenches 430T and the second trenches 431T allows the upper and lower sides of the thermoelectric pellets to be closer to the hot and cold sides of the thermoelectric device 400, thereby providing a shorter thermal path (less thermal resistance) through the thinned portions of the first and second substrates 430 and 431 (with the reduced thickness t₂) which, in turn, results in a higher heat flux through the thinned portions of the first and second substrates 430 and 431 in the regions where the trenches are formed. In addition, the first and second trenches 430T and 431T provide an increased ability to maintain the thermoelectric pellets fixedly secured and counteract thermal expansion (e.g., CTE) caused by temperature differentials during operation of thermoelectric device 400.

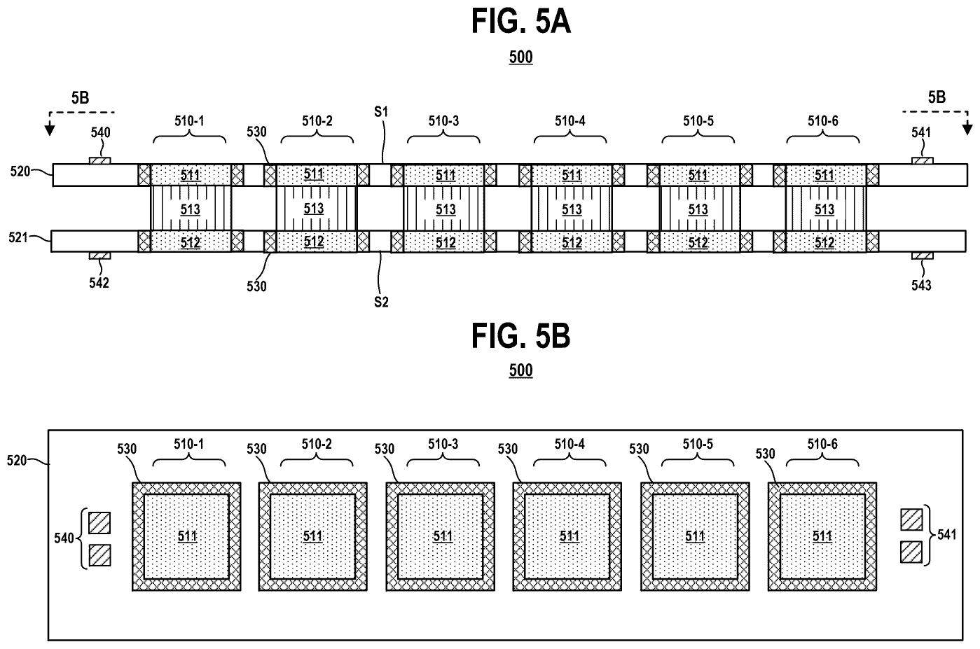

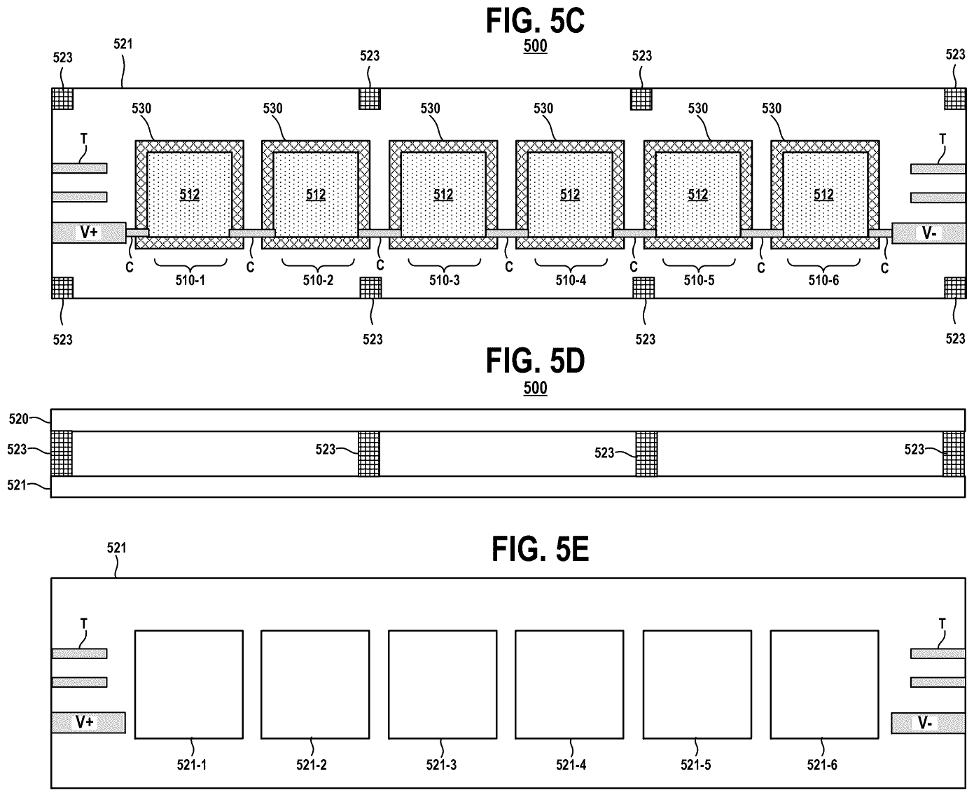

FIGS. 5A, 5B, 5C, 5D, and 5E schematically illustrate a thermoelectric module 500, according to an exemplary embodiment of the disclosure. In general, the thermoelectric module 500 comprises a plurality of thermoelectric devices 510-1, 510-2, 510-3, 510-4, 510-5, and 510-6 (generally, thermoelectric devices 510), a first substrate 520, and a second substrate 521. FIG. 5A is a schematic cross-sectional side view of the thermoelectric module 500. FIG. 5B is a schematic plan view of first (upper) side S1 of the thermoelectric module 500. FIG. 5C is a schematic plan view of an inner surface of the second substrate 521 of the thermoelectric module 500. FIG. 5D is another schematic cross-sectional side view of the thermoelectric module 500. FIG. 5E is a schematic plan view of the inner surface of the second substrate 521 at an initial stage of fabrication of the second substrate 521.

In some embodiments, the thermoelectric devices 510 are nominally identical in architecture, wherein each thermoelectric device 510-1, 510-2, 510-3, 510-4, 510-5, and 510-6 comprise a first ceramic substrate 511, a second ceramic substrate 512, and an array of serially-connected thermoelectric pellets 513 disposed between the first and second ceramic substrates 511 and 512. In an exemplary non-limiting embodiment, each thermoelectric device 510-1, 510-2, 510-3, 510-4, 510-5, and 510-6 has an architecture which is the same or similar to that of the thermoelectric device 300 of FIGS. 3A and 3B. In some embodiments, the first and second substrates 520 and 521 comprise polymer substrates, e.g., FR4 printed circuit boards, with patterned metallization traces, contact pads, wiring, etc., which provide electrical connections to and between electronic components of the thermoelectric module 500. For example, as schematically illustrated in FIG. 5C, the thermoelectric devices 510-1, 510-2, 510-3, 510-4, 510-5, and 510-6 are serially connected via connections C between a first (positive) power pad V+ and second (negative) power pad V−. The connections C can be formed using a combination of patterned metallic traces and wire bonds, etc.

Moreover, as schematically illustrated in FIGS. 5A and 5E, the first and second substrates 520 and 521 have respective cutout regions that are configured to insertably receive the first and second ceramic substrates 511 and 512 of the thermoelectric devices 510-1, 510-2, 510-3, 510-4, 510-5, and 510-6. For example, FIG. 5E specifically illustrates exemplary cutout regions 521-1, 521-2, 521-3, 521-4, 521-5, and 521-6 of the second substrate 521, which insertably receive the second ceramic substrates 512 of the respective the thermoelectric devices 510-1, 510-2, 510-3, 510-4, 510-5, and 510-6. Moreover, as schematically shown in FIGS. 5A, 5B, and 5C, the first ceramic substrates 511 of the thermoelectric devices 510 have sidewalls that are bonded to sidewalls of the cutouts of the first substrate 520 using epoxy material 530, and the second ceramic substrates 512 of the thermoelectric devices 510 have sidewalls that are bonded to sidewalls of the cutouts of the second substrate 521 using epoxy material 530. The epoxy material 530 serves to bond the first and second ceramic substrates 511 and 512 of the thermoelectric devices 510 to the first and second polymer substrates 520 and 521, and to form a seal to prevent thermal fluid from leaking into the space between the first and second polymer substrates 520 and 521.

Moreover, as schematically illustrated in FIG. 5D, the first and second polymer substrates 520 and 521 are fixedly secured, and spaced apart, from each other using spacer elements 523 (e.g., plastic spacer elements) that are glued or epoxied to the inner surfaces of the first and second polymer substrates 520 and 521. The spacer elements 523 provide structural integrity to the thermoelectric module 500, and provide an insulative air space between the inner surfaces of the first and second polymer substrates 520 and 521. In some embodiments, a sealant layer (e.g., RTV silicon) is applied around an outer perimeter portion of the air space to prevent exposure of the inner region of the thermoelectric module 500 to external elements (e.g., dust, moisture, etc.).

As schematically illustrated in FIG. 5A, in some embodiments, on a first side S1 of the thermoelectric module 500, the outer surfaces of the first polymer substrate 520 and the first ceramic substrates 511 of the thermoelectric devices 510 are coplanar or substantially coplanar to minimize the surface drag and turbulence of thermal fluid that flows in contact with the first side S1 of the thermoelectric module 500. In addition, on a second side S2 of the thermoelectric module 500, the outer surfaces of the second polymer substrate 521 and the second ceramic substrates 512 of the thermoelectric devices 510 are coplanar or substantially coplanar to minimize the surface drag and turbulence of thermal fluid that flows in contact with the second side S2 of the thermoelectric module 500.

The thermoelectric module 500 can be utilized to implement a thermoelectric system in which the thermoelectric module 500 is disposed between a first fluid chamber and a second fluid chamber such as shown, for example, in FIG. 2A, wherein the first side S1 of the thermoelectric module 500 is disposed within an opening of the first fluid chamber in direct contact with a thermal fluid that flows in the first fluid chamber, and wherein the second side S2 of the thermoelectric module 500 is disposed within an opening of the second fluid chamber in direct contact with a thermal fluid that flows in the second fluid chamber.

In some embodiments, the thermoelectric module 500 comprises integrated water flow sensors and/or integrated temperature sensors. For example, as schematically shown in FIGS. 5A and 5B, the thermoelectric module 500 comprises a first set of integrated water flow and temperature sensors 540 and a second set of integrated water flow and temperature sensors 541 disposed on the first side S1 of the thermoelectric module 500. In addition, the thermoelectric module 500 comprises a third set of integrated water flow and temperature sensors 542 and a fourth set of integrated water flow and temperature sensors 543 disposed on the second side S2 of the thermoelectric module 500. The integrated water flow and temperature sensors 540, 541, 542, and 543 can be surface mount devices (SMDs) that are mounted directly onto the surfaces of a first and second polymer substrates 520 and 521 (e.g., FR4 printed circuit boards) and electrically connected (using through-vias) to patterned contacts, wiring, and/or traces that disposed on the inner surfaces of the first and second substrates 520 and 521 (e.g., traces T shown in FIGS. 5C and 5E).

The integrated water flow and temperature sensors can be implemented using sensor devices that are suitable for the given application. For example, in some embodiments, the integrated temperature sensors can be implemented using thermistors or thermocouples. In some embodiments, the integrated water flow sensors can be implemented using strain gauges, or solid-state flow sensors such as Hall-effect flow sensors, etc. The integrated water flow and temperature sensors are disposed on the first and second surfaces S1 and S2 of the thermoelectric module 500 to monitor the temperature of the thermal fluids that flow into and out of the first and second fluid chambers (wherein in FIG. 5A, it is assumed that the flow of thermal fluids on the first and second sides S1 and S2 is left to right, or vice versa.

The integrated water flow and temperature sensors are utilized to generate sensor data which is fed back to, and processed by, a control system to monitor system performance and to automatically control the operation of the thermoelectric module 500 by adjusting operating parameters (e.g., voltage bias levels applied to the thermoelectric device, flow rates of the thermal fluids, etc.) to meet target operating levels of a thermoelectric system which implements the thermoelectric module 500 for cooling and or heating. For example, the flow rates of thermal fluids in cold and hot fluid chambers can be regulated to control temperature and power usage. As a room temperature reaches a desired setpoint temperature, the flow rate of the thermal fluids can be reduced to reduce power usage, or increased to facilitate reaching the desired setpoint temperature. Furthermore, one or more of the thermoelectric devices 510-1, 510-2, 510-3, 510-4, 510-5, and 510-6 can have integrated temperature sensors (e.g., thermocouples, thermistors, etc.) to monitor the temperatures of the respective ceramic substrates and/or thermoelectric pellets, and use the temperature sensor data to determine relative temperatures between the thermal fluids, the ceramic substrates, and/or thermoelectric pellets, for various control purposes.

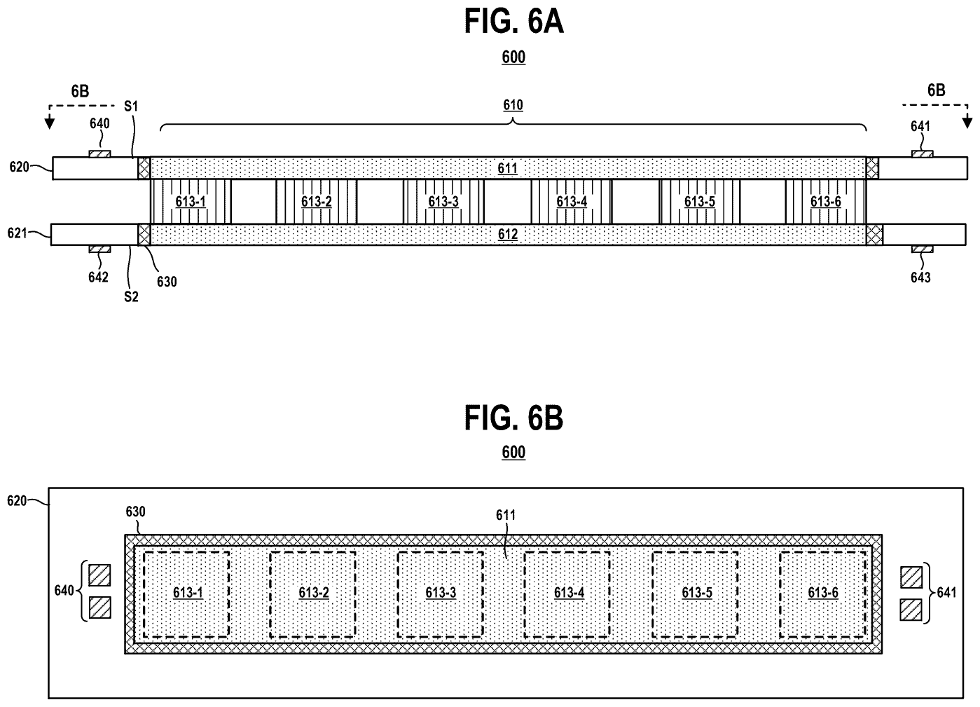

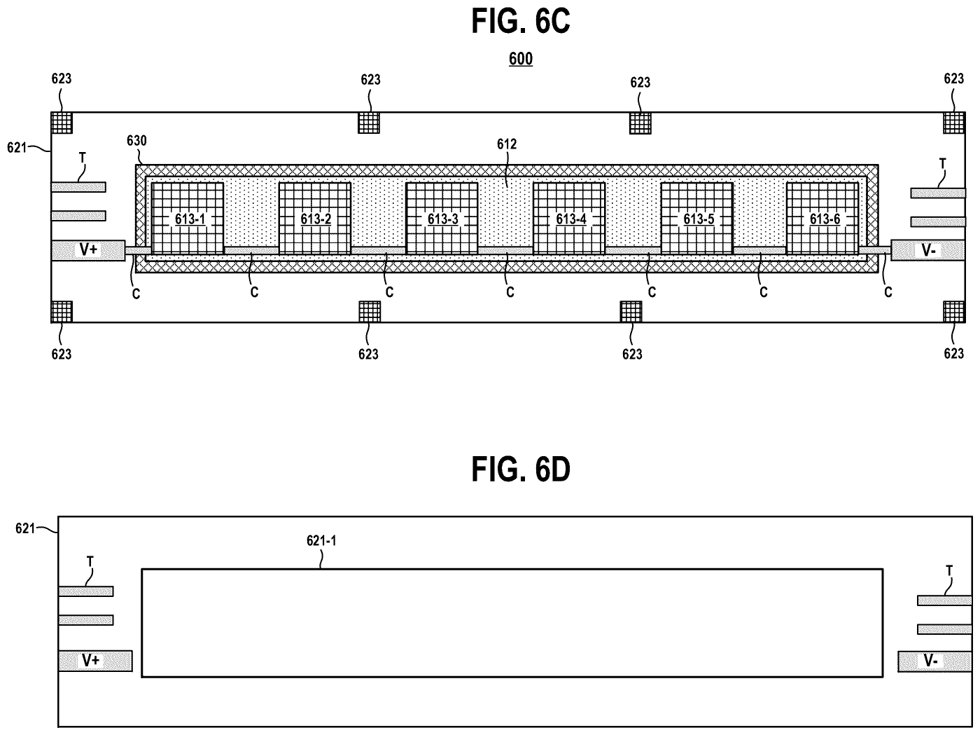

FIGS. 6A, 6B, 6C, and 6D schematically illustrate a thermoelectric module 600, according to another exemplary embodiment of the disclosure. In general, the thermoelectric module 600 comprises a thermoelectric device 610, a first substrate 620, and a second substrate 621. FIG. 6A is a schematic cross-sectional side view of the thermoelectric module 600. FIG. 6B is a schematic plan view of first (upper) side S1 of the thermoelectric module 600. FIG. 6C is a schematic plan view of an inner surface of the second substrate 621 of the thermoelectric module 600. FIG. 6D is a schematic plan view of the inner surface of the second substrate 621 at an initial stage of fabrication of the second substrate 621.

In general, the thermoelectric module 600 is similar to the thermoelectric module 500 discussed above, except that the thermoelectric device 610 comprises a first ceramic substrate 611, a second ceramic substrate 612, and a multiple arrays of serially-connected thermoelectric pellets 613-1, 613-2, 613-3, 613-4, 613-5, and 613-6 disposed between the first and second ceramic substrates 611 and 612, wherein the first and second ceramic substrates 611 and 612 serve as common substrates for the multiple arrays of serially-connected thermoelectric pellets 613-1, 613-2, 613-3, 613-4, 613-5, and 613-6. In some embodiments, the arrays of serially-connected thermoelectric pellets 613-1, 613-2, 613-3, 613-4, 613-5, and 613-6 are nominally identical in architecture (in terms of the number and arrangement of serially-connected thermoelectric pellet couples).

In some embodiments, the first and second substrates 620 and 621 comprise polymer substrates, e.g., FR4 printed circuit boards, with patterned metallization traces, contact pads, wiring, etc., which provide electrical connections to and between electronic components of the thermoelectric module 600. For example, as schematically illustrated in FIG. 6C, the arrays of thermoelectric pellets 613-1, 613-2, 613-3, 613-4, 613-5, and 613-6 are serially connected via connections C between a first (positive) power pad V+ and second (negative) power pad V− where, as noted above, the connections C can be formed using a combination of patterned metallic traces and wire bonds, etc.

Moreover, as schematically illustrated in FIGS. 6A and 6D, the first and second substrates 620 and 621 have respective cutout regions that are configured to insertably receive the first and second ceramic substrates 611 and 612 of the thermoelectric device 610. For example, FIG. 6D specifically illustrates a single cutout region 621-1 of the second substrate 621, which insertably receives the second ceramic substrate 612 of the thermoelectric device 610. Moreover, as schematically shown in FIGS. 6A, 6B, and 6C, the first ceramic substrate 611 of the thermoelectric device 610 has sidewalls that are bonded to sidewalls of the cutout of the first substrate 620 using epoxy material 630, and the second ceramic substrate 612 of the thermoelectric device 610 has sidewalls that are bonded to sidewalls of the cutout of the second substrate 621 using epoxy material 630. As noted above, the epoxy material 630 serves to bond the first and second ceramic substrates 611 and 612 of the thermoelectric device 610 to the first and second polymer substrates 620 and 621, and to form a seal to prevent thermal fluid from leaking into the space between the first and second polymer substrates 620 and 621.

Moreover, the first and second polymer substrates 620 and 621 are fixedly secured, and spaced apart, from each other using spacer elements 623 (e.g., plastic spacer elements) that are glued or epoxied to the inner surfaces of the first and second polymer substrates 620 and 621. The spacer elements 623 provide structural integrity to the thermoelectric module 600. In some embodiments, a sealant layer (e.g., RTV silicon) is applied around an outer perimeter portion of the air space to prevent exposure of the inner region of the thermoelectric module 600 to external elements (e.g., dust, moisture, etc.).

As schematically illustrated in FIG. 6A, in some embodiments, on a first side S1 of the thermoelectric module 600, the outer surfaces of the first polymer substrate 620 and the first ceramic substrate 611 of the thermoelectric device 610 are coplanar or substantially coplanar to minimize the surface drag and turbulence of thermal fluid that flows in contact with the first side SI of the thermoelectric module 600. In addition, on a second side S2 of the thermoelectric module 600, the outer surfaces of the second polymer substrate 621 and the second ceramic substrate 612 of the thermoelectric device 610 are coplanar or substantially coplanar to minimize the surface drag and turbulence of thermal fluid that flows in contact with the second side S2 of the thermoelectric module 600.

In some embodiments, similar to the thermoelectric module 500 of FIGS. 5A-5E, the thermoelectric module 600 comprises first and second sets of integrated water flow and temperature sensors 640 and 641 disposed on the first side S1 of the thermoelectric module 600, and third and fourth sets of integrated water flow and temperature sensors 642 and 643 on the second side S2 of the thermoelectric module 600. The integrated water flow and temperature sensors 640, 641, 642, and 643 can be implemented and utilized as discussed above.

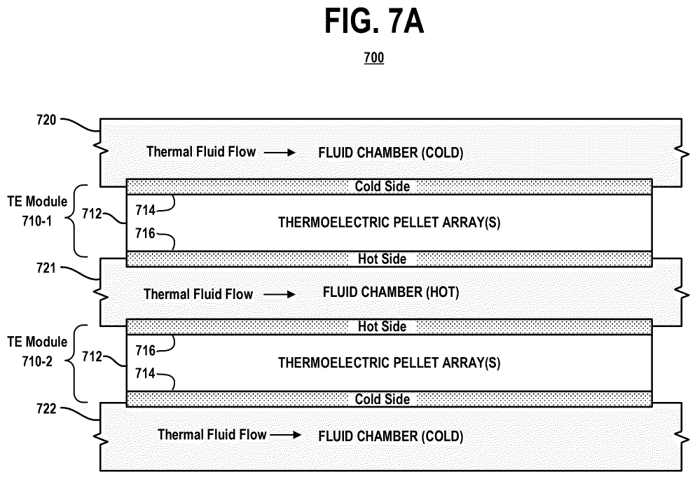

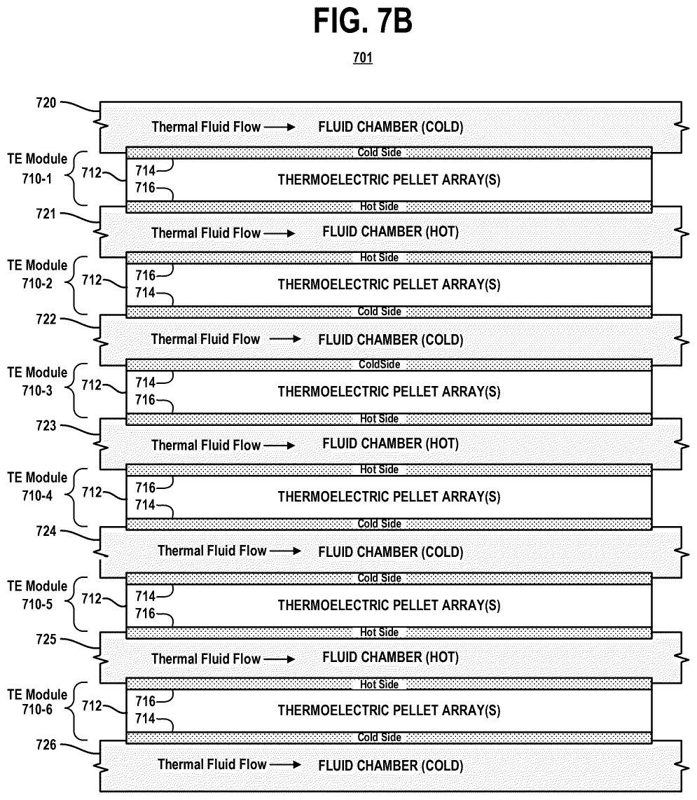

FIGS. 7A and 7B schematically illustrate thermoelectric systems which are implemented by stacking a plurality of thermoelectric modules and thermal fluid chambers, according to exemplary embodiments of the disclosure. For example, FIG. 7A schematically illustrates a thermoelectric system 700 which is implemented by stacking a plurality of thermoelectric modules 710-1 and 710-2 and a plurality of thermal fluid chambers 720, 721, and 722 in an alternating manner. The thermoelectric modules 710-1 and 710-2 are nominally identical thermoelectric modules each comprising one or more arrays of thermoelectric pellets 712 disposed between a first substrate 714 (e.g., cold side) and a second substrate 716 (e.g., hot side). In some embodiments, as shown in FIG. 7A, the thermal fluid chambers 720 and 722 are configured as cold thermal fluid chambers that are part of the same closed loop system which circulates cooled thermal transfer fluid through the thermal fluid chambers 720 and 722, while the thermal fluid chamber 721 is configured as a hot thermal fluid chamber which is part of a closed loop system that circulates heated thermal transfer fluid. In the exemplary implementation of FIG. 7A, the thermoelectric modules 710-1 and 710-2 are configured to operate such that the hots sides (e.g., substrates 716) of the thermoelectric modules 710-1 and 710-2 are disposed within the thermal fluid chamber 721 (which is shared by the thermoelectric modules 710-1 and 710-2), while the cold sides (e.g., substrates 716) of the thermoelectric modules 710-1 and 710-2 are disposed within the thermal fluid chambers 720 and 722, respectively. In this configuration, the thermoelectric modules 710-1 and 710-2 transfer (actively pump) thermal energy from the thermal transfer fluid flowing in the fluid chambers 720 and 722 to the thermal transfer fluid flowing in the thermal fluid chamber 721, to thereby cool down the thermal transfer fluid flowing in the fluid chambers 720 and 722.

In some embodiments, each thermoelectric module 710-1 and 710-2 can be implemented using the exemplary architecture of the thermoelectric module 500 of FIG. 5A, or the exemplary architecture of the thermoelectric module 600 of FIG. 6A. The stacked configuration of the thermoelectric system 700 provides an increased BTU output of the thermoelectric system 700 as compared to the BTU output of a thermoelectric system such as schematically illustrated in FIGS. 2A and 2B with only a single thermoelectric module. While FIG. 7A schematically illustrates an exemplary architecture of thermoelectric system which implements two thermoelectric modules in a stacked configuration with three thermal fluid chambers, the number of alternating thermoelectric modules and thermal fluid chambers can be increased to achieve even larger BTU outputs (e.g., 20K BTUs or more), as desired, to meet the requirements of different refrigeration systems or air conditioning systems that are used for larger homes or buildings.

For example, FIG. 7B schematically illustrates a thermoelectric system 701 which is implemented by stacking a plurality of thermoelectric modules 710-1, 710-2, 710-3, 710-4, 710-5, and 710-6, and a plurality of thermal fluid chambers 720, 721, 722, 723, 724, 725, and 726 in an alternating manner. Again, the thermoelectric modules 710-1, 710-2, 710-3, 710-4, 710-5, and 710-6 are nominally identical thermoelectric modules each comprising one or more arrays of thermoelectric pellets 712 disposed between a first substrate 714 (e.g., cold side) and a second substrate 716 (e.g., hot side). Again, in some embodiments, each thermoelectric module 710-1, 710-2, 710-3, 710-4, 710-5, and 710-6 can be implemented, for example, using the exemplary architecture of the thermoelectric module 500 of FIG. 5A, or the exemplary architecture of the thermoelectric module 600 of FIG. 6A. In some embodiments, as shown in FIG. 7B, the thermal fluid chambers 720, 722, 724, and 726 are configured as cold thermal fluid chambers which are part of the same closed loop system that circulates cooled thermal transfer fluid through the thermal fluid chambers 720, 722, 724, and 726, while the thermal fluid chambers 721, 723, and 725 are configured as hot thermal fluid chambers that are part of a same closed loop system which circulates heated thermal transfer fluid through the thermal fluid chambers 721, 723, and 725.

In the exemplary implementation of FIG. 7B, the thermoelectric modules 710-1, 710-2, 710-3, 710-4, 710-5, and 710-6 are operatively arranged such that (i) the cold side (substrate 714) of the thermoelectric module 710-1 is disposed within the thermal fluid chamber 720, (ii) the hot sides (substrates 716) of the thermoelectric modules 710-1 and 710-2 are disposed within the thermal fluid chamber 721, (iii) the cold sides (substrates 714) of the thermoelectric modules 710-2 and 710-3 are disposed within the thermal fluid chamber 722, (iv) the hot sides (substrates 714) of the thermoelectric modules 710-3 and 710-4 are disposed within the thermal fluid chamber 723, (v) the cold sides (substrates 716) of the thermoelectric modules 710-4 and 710-5 are disposed within the thermal fluid chamber 724, (vii) the hot sides (substrates 716) of the thermoelectric modules 710-5 and 710-6 are disposed within the thermal fluid chamber 725, and (viii) the cold side (substrate 714) of the thermoelectric module 710-6 is disposed within the thermal fluid chamber 726.

In this configuration, the thermoelectric modules 710-1 and 710-2 transfer thermal energy from the thermal transfer fluid flowing in the fluid chambers 720 and 722 to the thermal transfer fluid flowing in the thermal fluid chamber 721. In addition, the thermoelectric modules 710-3 and 710-4 transfer thermal energy from the thermal transfer fluid flowing in the fluid chambers 722 and 724 to the thermal transfer fluid flowing in the thermal fluid chamber 723. Similarly, the thermoelectric modules 710-5 and 710-6 transfer thermal energy from the thermal transfer fluid flowing in the fluid chambers 724 and 726 to the thermal transfer fluid flowing in the thermal fluid chamber 725. The large number of thermoelectric modules of the thermoelectric system 701 allows for an increase in the magnitude/rate of thermal transfer (increased BTU) of thermal energy from the thermal transfer fluid flowing in the cold fluid chambers 720, 722, 726, and 726, to the thermal transfer fluid flowing in the hot fluid chambers 721, 723, and 725.

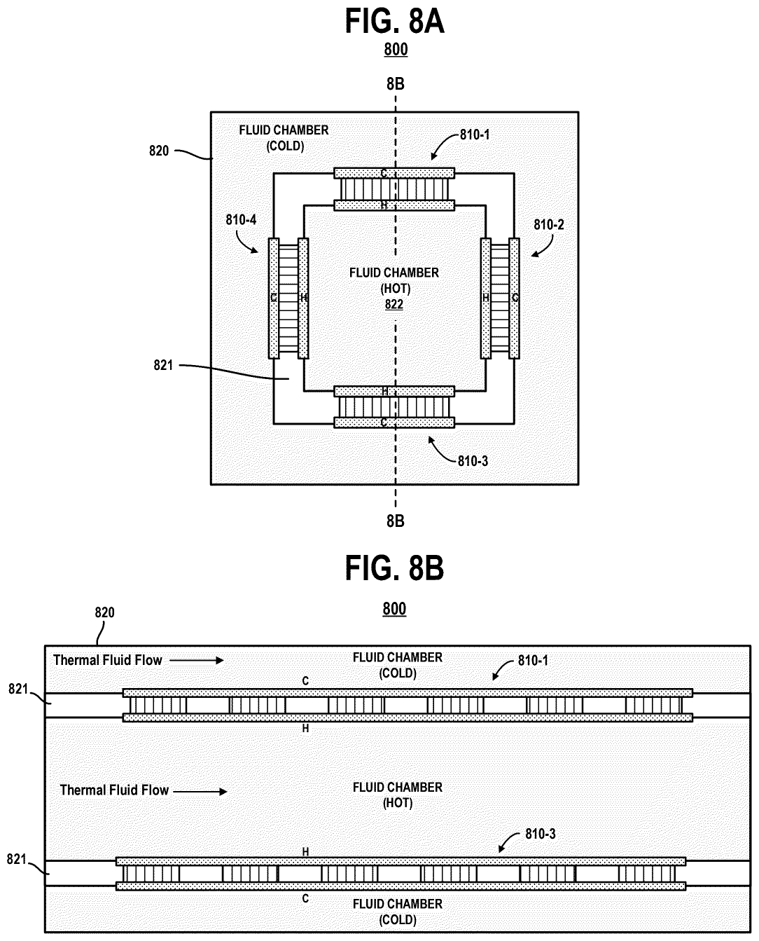

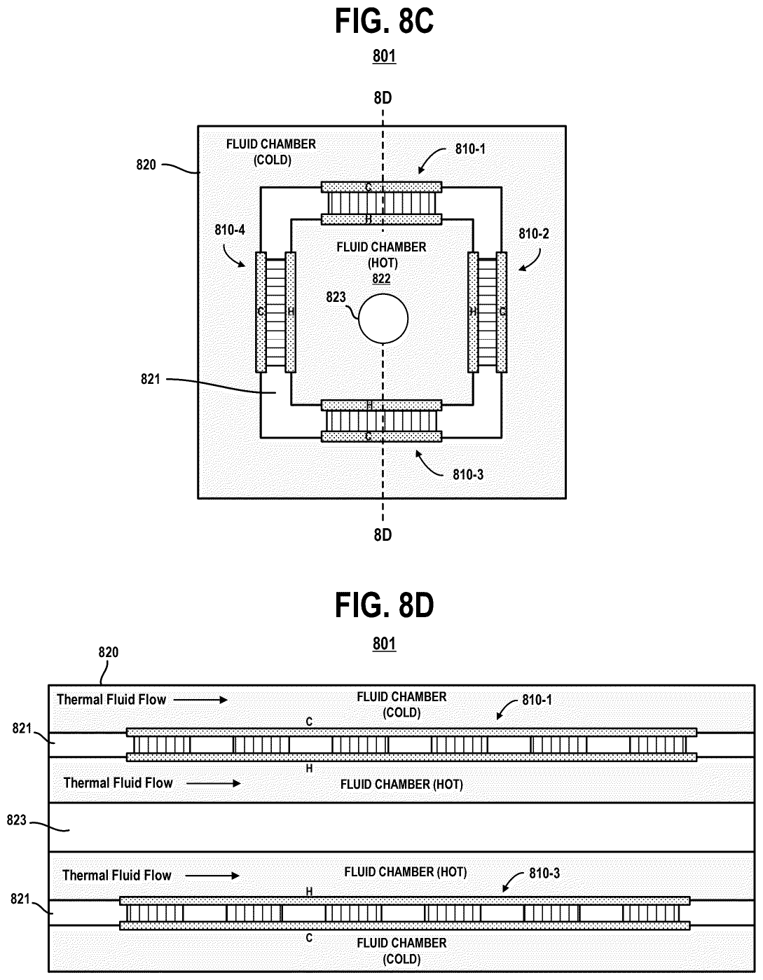

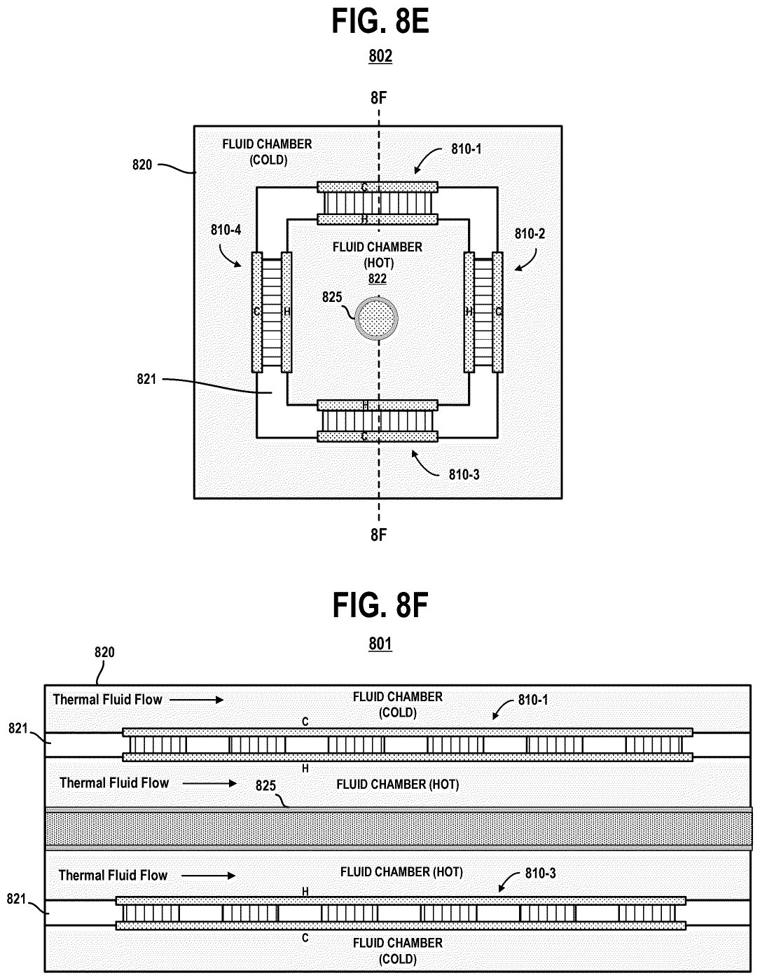

FIGS. 8A and 8B schematically illustrate a thermoelectric system 800, according to another exemplary embodiment of the disclosure. In particular, FIG. 8A is schematic end view of the thermoelectric system 800, and FIG. 8B is a schematical cross-sectional side view of the thermoelectric system 800 along line 8B-8B in FIG. 8A. As shown in FIGS. 8A and 8B, the thermoelectric system 800 comprises a first fluid chamber 820 (e.g., cold fluid chamber), a second fluid chamber 822 (e.g., hot fluid chamber) which is disposed within the first fluid chamber 820, with an air space 821 between the first and second fluid chambers 820 and 822, and a plurality of thermoelectric modules 810-1, 810-2, 810-3, and 810-4 disposed between the first fluid chamber 820 and the second fluid chamber 822. Each thermoelectric module 810-1, 810-2, 810-3, and 810-4 comprises a first side (e.g., cold side “C”) that is disposed within a respective opening of the first fluid chamber 820 to enable the first sides (C) of the thermoelectric modules 810-1, 810-2, 810-3, and 810-4 to be in direct contact with a thermal transfer fluid which flows in the first fluid chamber 820. In addition, each thermoelectric module 810-1, 810-2, 810-3, and 810-4 comprises a second side (e.g., hot side “H”) that is disposed within a respective opening of the second fluid chamber 822 to enable the second sides (H) of the thermoelectric modules 810-1, 810-2, 810-3, and 810-4 to be in direct contact with a thermal transfer fluid which flows in the second fluid chamber 822.

In the exemplary configuration shown in FIGS. 8A and 8B, each thermoelectric module 810-1, 810-2, 810-3, and 810-4 is configured to transfer thermal energy from the thermal transfer fluid flowing in the first fluid chamber 820 to the thermal transfer fluid flowing in the second fluid chamber 822, using techniques as discussed herein. Again, in some embodiments, each thermoelectric module 810-1, 810-2, 810-3, and 810-4 can be implemented using the exemplary architecture of the thermoelectric module 500 of FIG. 5A, or the exemplary architecture of the thermoelectric module 600 of FIG. 6A.

FIGS. 8C and 8D schematically illustrate a thermoelectric system 801, according to another exemplary embodiment of the disclosure. In particular, FIG. 8C is schematic end view of the thermoelectric system 801, and FIG. 8D is a schematical cross-sectional side view of the thermoelectric system 801 along line 8D-8D in FIG. 8C. The thermoelectric system 801 has an architecture which similar to that of the thermoelectric system 800 of FIGS. 8A and 8B, except that the thermoelectric system 801 further comprises a closed channel 823 that is disposed within a central region of the second fluid chamber 822. The closed channel 823 does not include thermal transfer fluid, but rather serves to divert the flow of thermal transfer fluid away from a center region of the second fluid chamber 822 to be in closer proximity to the hot sides H of the thermoelectric modules 810-1, 810-2, 810-3, and 810-4, to thereby improve the heat transfer from thermal transfer fluid which flows in the first fluid chamber 820 to the thermal transfer fluid that flows in the second fluid chamber 822, via the heat pumping operations of the thermoelectric modules 810-1, 810-2, 810-3, and 810-4.

FIGS. 8E and 8F schematically illustrate a thermoelectric system 802, according to another exemplary embodiment of the disclosure. In particular, FIG. 8E is schematic end view of the thermoelectric system 802, and FIG. 8F is a schematical cross-sectional side view of the thermoelectric system 802 along line 8F-8F in FIG. 8E. The thermoelectric system 802 has an architecture which similar to that of the thermoelectric system 800 of FIGS. 8A and 8B, except that the thermoelectric system 802 further comprises an electric heating element 825 that is disposed within a central region of the second fluid chamber 822. The electric heating element 825 can be implemented to provide a supplemental heat source to apply extra heating to the thermal fluid flowing the second fluid chamber 822 to bring the temperature to the desired level faster. The electric heating element 825 can also be used in situation where the BTU capacity of the thermoelectric system 802 is not enough under certain circumstances to reach a desired level.

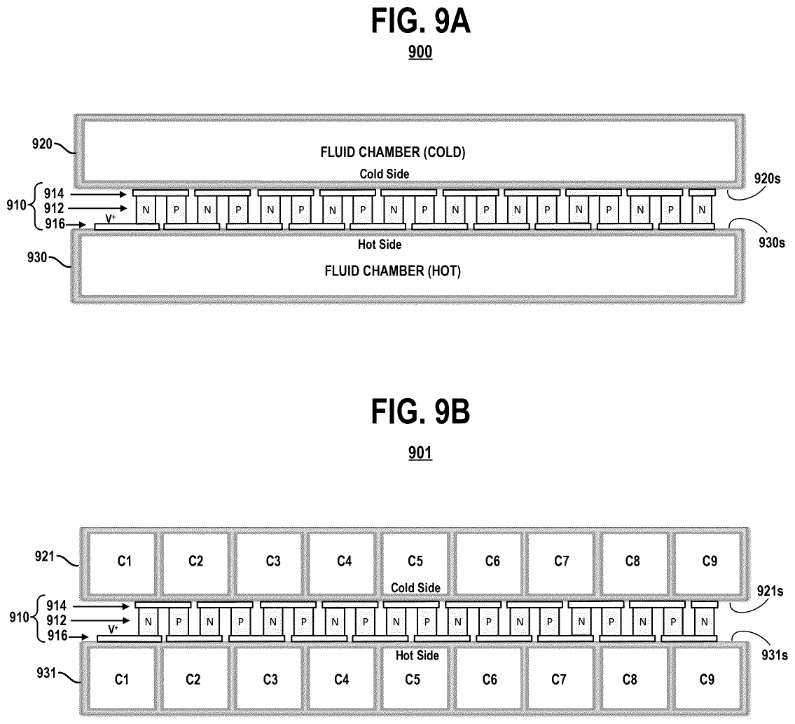

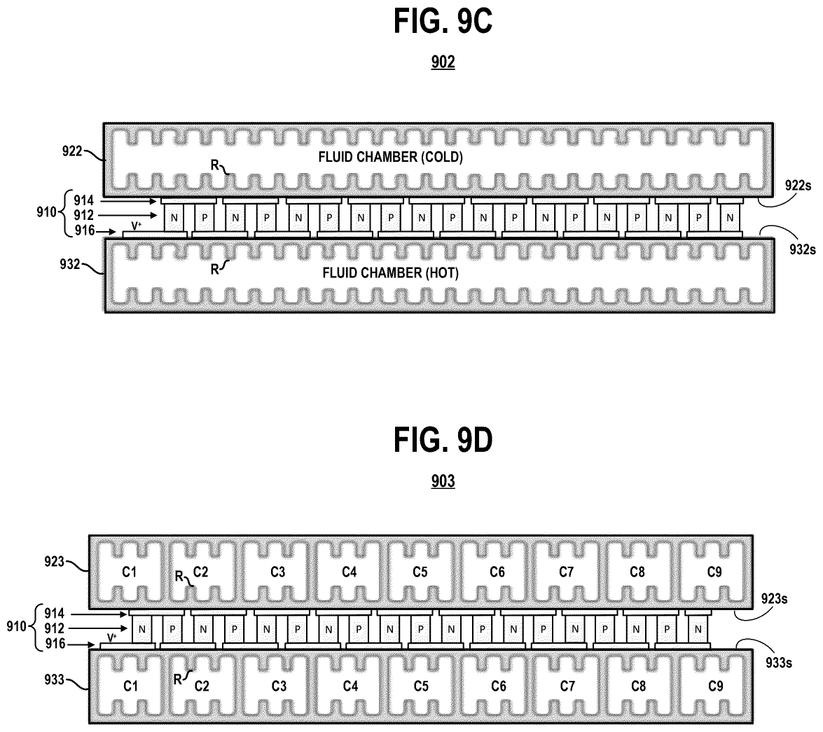

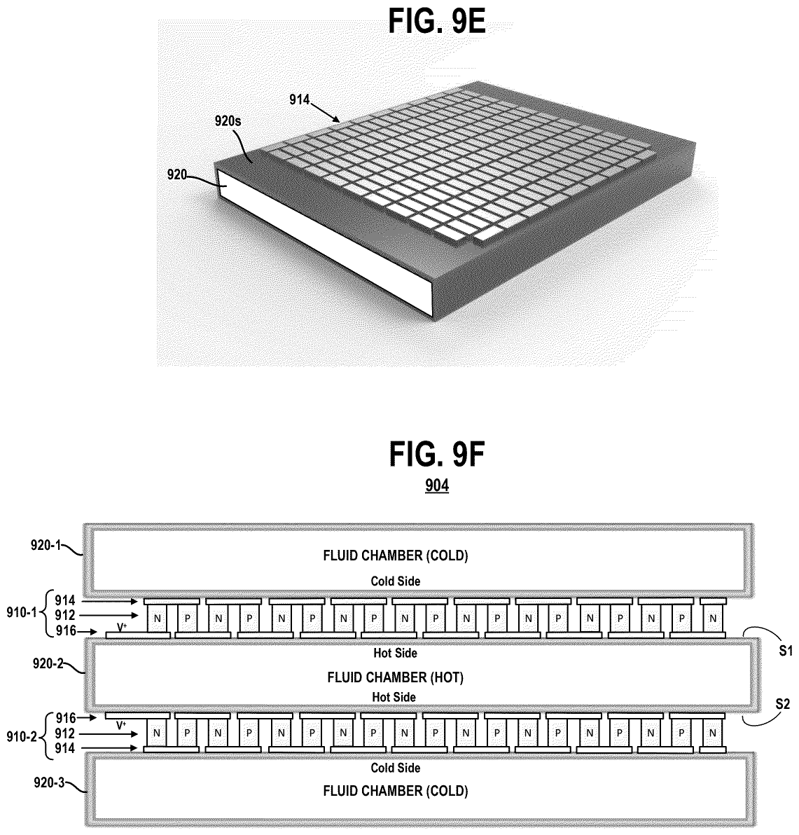

FIG. 9A schematically illustrates a thermoelectric system 900, according to another exemplary embodiment of the disclosure. The thermoelectric system 900 comprises a thermoelectric device 910, a first fluid chamber 920, and a second fluid chamber 930. The thermoelectric device 910 comprises an array of thermoelectric semiconductor pellets 912 disposed, between a first side 920s of the first fluid chamber 920, and a second side 930s of the second fluid chamber 930. The thermoelectric device 910 further comprises a first array of interconnect pads 914 disposed on an outer surface of the first side 920s of the first fluid chamber 920, and a second array of interconnect pads 916 disposed on an outer surface of the second side 930s of the second fluid chamber 930. Each thermoelectric semiconductor pellet of the array of thermoelectric semiconductor pellets 912 has (i) a first end which is connected to a given interconnect pad of the first array of interconnect pads 914 disposed on the outer surface of the first side 920s of the first fluid chamber 920, and (ii) a second end which is connected to a given interconnect pad of the second array of interconnect pads 916 disposed on the outer surface of the second side 930s of the second fluid chamber 930.

The thermoelectric system 900 comprises an exemplary architecture in which the first array of interconnect pads 914 are formed on the outer surface of the first side 920s of the first fluid chamber 920, and the second array of interconnect pads 916 are formed on the outer surface of the second side 930s of the second fluid chamber 930, and the thermoelectric semiconductor pellets are soldered to respective interconnect pads of the first and second array of interconnect pads 914 and 916 to form a serial chain of thermoelectric couples, as discussed above. FIG. 9E is a perspective view of an exemplary configuration of the first fluid chamber 920 having the first array of interconnect pads 914 formed on the outer surface of the first side 920s of the first fluid chamber 920, according to an exemplary embodiment of the disclosure

FIG. 9B schematically illustrates a thermoelectric system 901 according to another exemplary embodiment of the disclosure. The thermoelectric system 901 has an architecture which is similar to that of the thermoelectric system 900 of FIG. 9A, except that the thermoelectric system 901 comprises a first fluid chamber 921 and a second fluid chamber 931, which have a plurality of separate fluid chambers C1, C2, C3, C4, C5, C6, C7, C8, and C9 that are configured to evenly disperse heat transfer fluids, which flow in the first and second fluid chamber 921 and 931, into a plurality of parallel streams within the first and second fluid chambers 921 and 931. As in FIG. 9A, the first array of interconnect pads 914 is disposed on the outer surface of a first side 921s of the first fluid chamber 921, and the second array of interconnect pads 916 is disposed on the outer surface of a second side 931s of the second fluid chamber 931, and the thermoelectric semiconductor pellets 912 are soldered to respective interconnect pads of the first and second array of interconnect pads 914 and 916 to form a serial chain of thermoelectric couples, as discussed above.

FIG. 9C schematically illustrates a thermoelectric system 902 according to another exemplary embodiment of the disclosure. The thermoelectric system 902 has an architecture which is similar to that of the thermoelectric system 900 of FIG. 9A, except that the thermoelectric system 902 comprises a first fluid chamber 922 and a second fluid chamber 932, which have a plurality of vertical rib elements R (or ribbed extrusions) on inner surfaces of respective first and second sides 922s and 932s of the first and second fluid chambers 922 and 932. The ribbed extrusions R serve to increase a surface area of the inner surfaces of first and second sides 922s and 932s of the first and second fluid chambers 922 and 932 for better thermal transfer between the heat transfer fluids that flow in the first and second fluid chambers 922 and 932 and the hot and cold sides of the thermoelectric device 910. In addition, the ribbed extrusions R serve to reduce turbulence and help direct the flow of heat transfer fluid through the fluid chamber. As in FIG. 9A, the first array of interconnect pads 914 is disposed on the outer surface of a first side 922s of the first fluid chamber 922, and the second array of interconnect pads 916 is disposed on the outer surface of a second side 932s of the second fluid chamber 932, and the thermoelectric semiconductor pellets 912 are soldered to respective interconnect pads of the first and second array of interconnect pads 914 and 916 to form a serial chain of thermoelectric couples, as discussed above.

FIG. 9D schematically illustrates a thermoelectric system 903 according to another exemplary embodiment of the disclosure. The thermoelectric system 903 has an architecture which is similar to that of the thermoelectric systems 901 and 902 of FIGS. 9B and 9C wherein the thermoelectric system 903 comprises a first fluid chamber 923 and a second fluid chamber 933, which have a plurality of separate fluid channels C1, C2, C3, C4, C5, C6, C7, C8, and C9 to distribute the flow of thermal transfer fluid into parallel streams, as well as a plurality of ribbed extrusions R on inner surfaces of respective first and second sides 923s and 933s of the first and second fluid chambers 923 and 933 to provide, e.g., enhanced thermal transfer between the heat transfer fluids that flow in the first and second fluid chambers 922 and 932 and the hot and cold sides of the thermoelectric device 910.

In some embodiments, the first and second arrays of interconnect pads 914 and 916 (which are shown in each of the embodiments of FIGS. 9A-9D) are formed of copper, or other similar and suitable types of metal materials. Moreover, in some embodiments, the first and second fluid chambers shown in each of the embodiments of FIGS. 9A-9D can be formed of an extruded or injection-molded ceramic alloy material such as aluminum nitride, or any similar ceramic alloy material, which has a CTE (coefficient of thermal expansion) that is the same or similar to the metal material used to form the first and second arrays of interconnect pads 914 and 916, and which has a suitable hardness for structural integrity, and high thermal conductivity for good BTU pump performance.

In addition, while FIGS. 9A, 9B, 9C, and 9D schematically illustrate thermoelectric systems with a single thermoelectric device disposed between two thermal fluid chambers, it is to be noted that a thermoelectric system can be implemented with a plurality of thermal fluid chambers and thermoelectric devices in a stacked configuration, similar to the stacked architectures shown and discussed above in conjunction with FIGS. 7A and 7B. For example, FIG. 9F schematically illustrates a thermoelectric system, according to another exemplary embodiment of the disclosure, which comprise a stacked architecture of multiple thermal fluid chambers and thermoelectric devices. In particular, FIG. 9F schematically illustrates a thermoelectric system 903 which is implemented by stacking a plurality of thermoelectric modules 910-1 and 910-2 and a plurality of thermal fluid chambers 920-1, 920-2, and 920-3 in an alternating manner. In some embodiments, the thermoelectric modules 910-1 and 910-2 are nominally identical thermoelectric modules each comprising an array of thermoelectric pellets 912 and first and second arrays of interconnect pads 914 and 916. In this configuration, the second array of interconnect pads 916 of the thermoelectric module 910-1 would be formed on a first side S1 of the thermal fluid chamber 920-2, and the second array of interconnect pads 916 of the thermoelectric module 910-2 would be formed on a second side S2 of the thermal fluid chamber 920-2. While FIG. 9E shows three thermal fluid chambers and two thermoelectric modules, a stacked thermoelectric system can be fabricated with any suitable number of thermal fluid chambers and thermoelectric modules, similar to that shown in FIG. 7B, to achieve a desired level of BTU output.

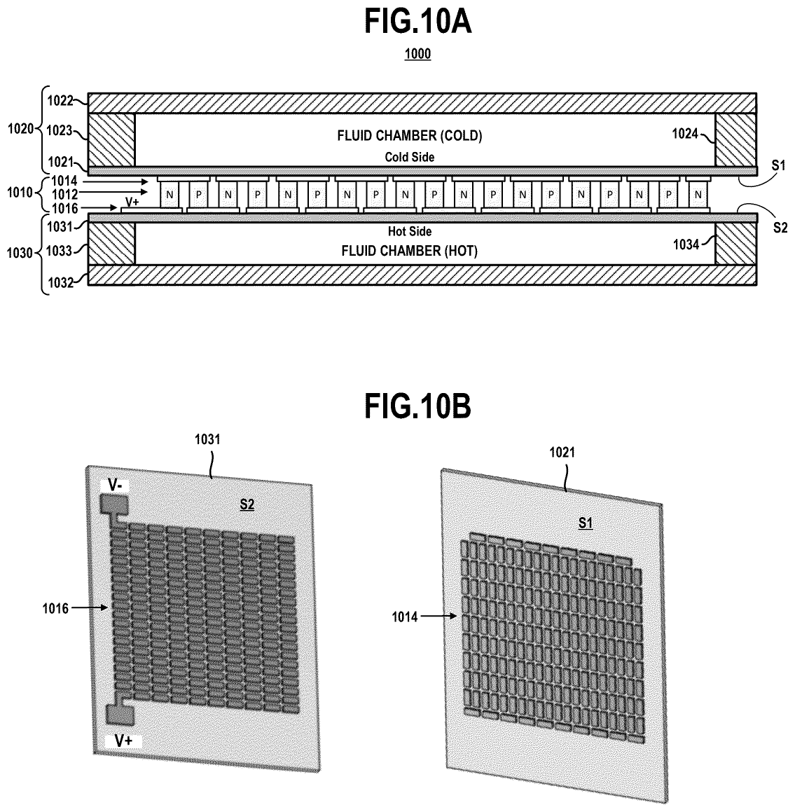

It is to be noted that while FIGS. 9A, 9B, 9C, 9D, and 9F schematically illustrate thermal fluid chambers as single integrated components that can be formed using extrusion or molding processes, in other embodiments, thermal fluid chambers can be fabricated using separate modular components that are separately fabricated and then assembled together to form thermal fluid chambers for use in constructing thermoelectric systems. For example, FIGS. 10A and 10B schematically illustrate a thermoelectric system 1000 according to another exemplary embodiment of the disclosure, which comprises thermal fluid chambers that are assembled using separate modular components. In particular, as shown in FIG. 10A, the thermoelectric system 1000 comprises a thermoelectric device 1010, a first fluid chamber 1020, and a second fluid chamber 1030. The thermoelectric device 1010 comprises an array of thermoelectric semiconductor pellets 1012, which are interconnected using a first array of interconnect pads 1014, and a second array of interconnect pads 1016.

The first fluid chamber 1020 comprises a first substrate 1021, a second substrate 1022, a first sidewall element 1023, and a second sidewall element 1024, which are assembled together to form the first fluid chamber 1020. Similarly, the second fluid chamber 1030 comprises a first substrate 1031, a second substrate 1032, a first sidewall element 1033, and a second sidewall element 1034, which are assembled together to form the second fluid chamber 1030. In some embodiments, the first substrate 1021 comprises a thin ceramic alloy substate, such as aluminum nitride, having a surface S1 on which the first array of interconnect pads 1014 are formed. Similarly, the second substrate 1031 comprises a thin ceramic alloy substate, such as aluminum nitride, having a surface S2 on which the second array of interconnect pads 1016 are formed. For example, FIG. 10B schematically illustrates an exemplary configuration of the first array of interconnect pads 1014 formed on the surface S1 of the first substrate 1021, as well as an exemplary configuration of the second array of interconnect pads 1016 formed on the surface S2 of the first substrate 1031.

The first substrates 1021 and 1031 are formed of a suitable ceramic alloy material, such as aluminum nitride, which provides the desired CTE (same or similar as the metal material used to form the first and second arrays of interconnect pads 1014 and 1016), and a thermal conductivity to enable a high rate and magnitude of thermal energy transfer between the cold and hot sides of the thermoelectric device 1010 and the thermal transfer fluids flowing in the first and second fluid chambers 1020 and 1030, to achieve good BTU pump performance. On the other hand, the second substrates 1022 and 1032, and the sidewall elements 1023, 1024, 1033, and 1034 can be formed of other types of materials (e.g., cheaper in cost, as compared to aluminum nitride), as such components are not used for thermal heat transfer. For example, the second substrates 1022 and 1032, and the sidewall elements 1023, 1024, 1033, and 1034 can be formed of polymer materials (e.g., acrylonitrile-butadiene-styrene copolymer (ABS) plastic, or other suitable engineering plastic materials which are rigid and heat resistant) or less expensive ceramic materials such as aluminum oxide, etc. The constituent components of the first and second fluid chambers 1020 and 1030 can be assembled together by gluing or epoxying the components together, or assembled using other suitable assembly techniques.

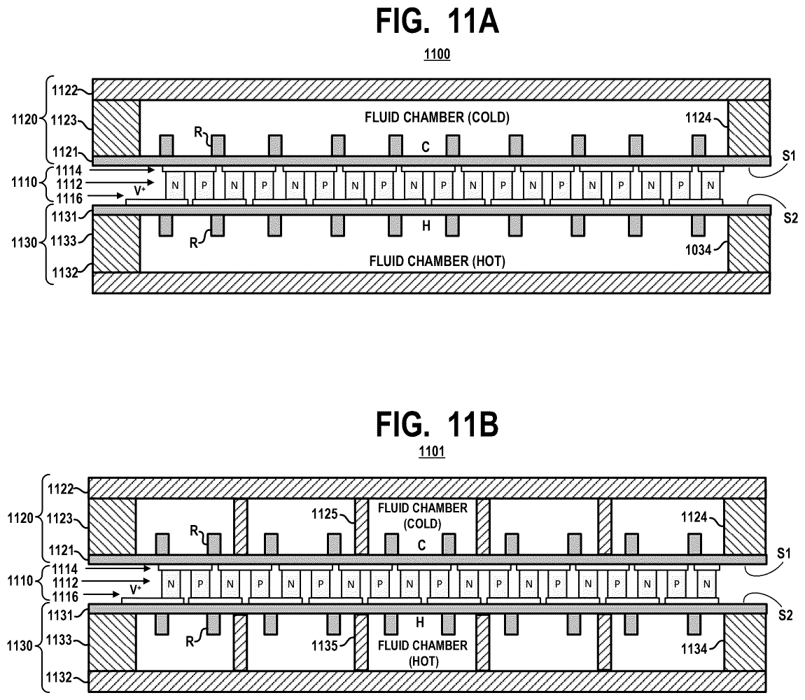

FIG. 11A schematically illustrates a thermoelectric system 1100 according to another exemplary embodiment of the disclosure, which comprises thermal fluid chambers that are assembled using separate modular components. In particular, as shown in FIG. 11A, the thermoelectric system 1100 comprises a thermoelectric device 1110, a first fluid chamber 1120, and a second fluid chamber 1130. The thermoelectric device 1110 comprises an array of thermoelectric semiconductor pellets 1112, which are interconnected using a first array of interconnect pads 1114, and a second array of interconnect pads 1116. The first fluid chamber 1120 comprises a first substrate 1121, a second substrate 1122, a first sidewall element 1123, and a second sidewall element 1124, which are assembled together to form the first fluid chamber 1120. Similarly, the second fluid chamber 1130 comprises a first substrate 1131, a second substrate 1132, a first sidewall element 1133, and a second sidewall element 1134, which are assembled together to form the second fluid chamber 1130. In some embodiments, the first substrate 1121 comprises a thin ceramic alloy substate, such as aluminum nitride, having a surface SI on which the first array of interconnect pads 1114 are formed. Similarly, the second substrate 1131 comprises a thin ceramic alloy substate, such as aluminum nitride, having a surface S2 on which the second array of interconnect pads 1116 are formed.

The thermoelectric system 1100 has an architecture which is similar to that of the thermoelectric system 1000 of FIG. 10A, except that each of the first planar substrates 1121 and 1131 shown in FIG. 11A have a plurality of vertical rib elements R (or ribbed extrusions) on inner surfaces thereof. As noted above, the ribbed extrusions R serve to increase a surface area of the inner surfaces of the first planar substrates 1121 and 1131 of the first and second fluid chambers 1120 and 1130 to achieve better thermal transfer between the heat transfer fluids that flow in the first and second fluid chambers 1120 and 1130 and the hot and cold sides of the thermoelectric device 1110.

Next, FIG. 11B schematically illustrates a thermoelectric system 1101 according to another exemplary embodiment of the disclosure, which comprises thermal fluid chambers that are assembled using separate modular components. The thermoelectric system 1101 of FIG. 11B has an architecture which is similar to that of the thermoelectric system 1100 of FIG. 11A, except that the first and second fluid chambers 1120 and 1130 further include respective inner wall elements 1125 and 1135 which are utilized to form a plurality of parallel flow channels within each of the first and second fluid chambers 1120 and 1130 to evenly distribute the flow of thermal transfer fluids, as discussed above. The ends of the inner wall elements 1125 and 1135 can be glued or epoxied to the inner surfaces of the first planar substrates 1121 and 1131 and to the second planar substrates 1122 and 1132 of the first and second fluid chambers 1120 and 1130.

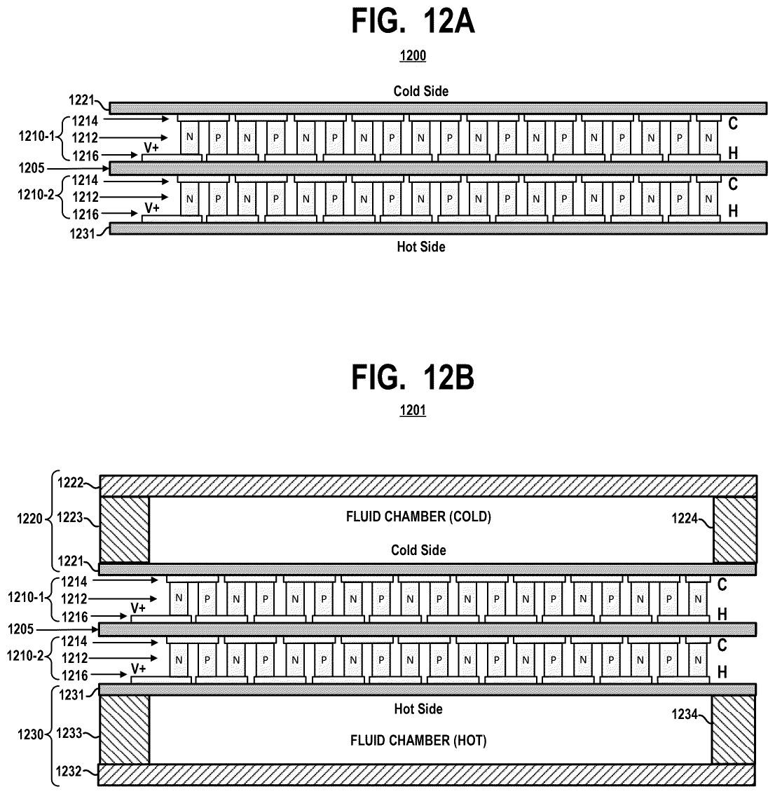

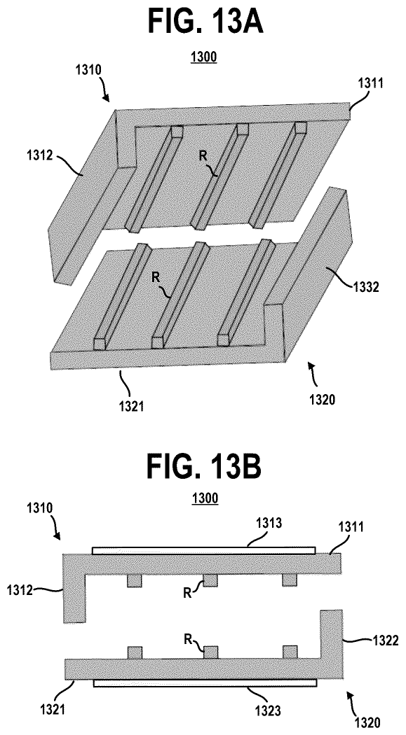

FIG. 12A schematically illustrates a thermoelectric module 1200, according to another exemplary embodiment of the disclosure. The thermoelectric module 1200 comprises a first thermoelectric device 1210-1, a second thermoelectric device 1210-2, and ceramic substrates 1221, 1231, and 1205. In some embodiments, the first and second thermoelectric devices 1210-1 and 1210-2 have nominally identical structures, each comprising an array of thermoelectric semiconductor pellets 1212, which are interconnected using a first array of interconnect pads 1214, and a second array of interconnect pads 1216. The thermoelectric module 1200 comprises a stacked configuration of the first and second thermoelectric devices 1210-1 and 1210-2, wherein the first thermoelectric device 1210-1 is disposed between the ceramic substrates 1221 and 1205, and the second thermoelectric device 1210-2 is disposed between the ceramic substrates 1231 and 1205. The ceramic substrate 1205 serves as central ceramic substrate that is shared by the first and second thermoelectric devices 1210-1 and 1210-2. For the first thermoelectric device 1210-1, the first array of interconnect pads 1214 are formed on a surface of the ceramic substrate 1221, and the second array of interconnect pads 1216 are formed on an upper surface of the central (common) ceramic substrate 1205. For the second thermoelectric device 1210-2, the first array of interconnect pads 1214 are formed on a bottom surface of the central (common) ceramic substrate 1205, and the second array of interconnect pads 1216 are formed on a surface of the ceramic substrate 1231. In some embodiments, the ceramic substrates 1221, 1231, and 1205 are formed of aluminum nitride, or other suitable ceramic alloy materials which have desired thermal and mechanical properties, as discussed above.

In an exemplary mode of operation, as schematically shown in FIG. 12A, the cold side C of the first thermoelectric device 1210-1 is in thermal contact with the ceramic substrate 1221, the hot side H of the first thermoelectric device 1210-1 is in thermal contact with the central ceramic substrate 1205, the cold side C of the second thermoelectric device 1210-2 is in thermal contact with the central ceramic substrate 1205, and the hot side H of the second thermoelectric device 1210-2 is in thermal contact with the ceramic substrate 1231. The stacked configuration shown in FIG. 12A provides an increase in the ΔT between the cold side and hot side of the thermoelectric module 1200, as compared to, e.g., a thermoelectric module having a single thermoelectric device (as shown in FIG. 10A, for example).

FIG. 12B schematically illustrates a thermoelectric system 1201 which can be implemented using the thermoelectric module 1200 of FIG. 12A, according to another exemplary embodiment of the disclosure. The thermoelectric system 1201 comprises a first fluid chamber 1220, and a second fluid chamber 1230, with the thermoelectric module 1200 of FIG. 12A disposed therebetween. Similar to the first and second fluid chambers 1020 and 1030 shown in FIG. 10A, the first and second fluid chambers 1220 and 1230 shown in FIG. 12B are comprised of an assembly of various modular components. For example, the first fluid chamber 1220 is comprised of the ceramic substrate 1221 of thermoelectric module 1200, as well as a second (cover) substrate 1222, and first and second sidewall elements 1223 and 1224, which are assembled together to form the first fluid chamber 1220. Similarly, the second fluid chamber 1230 is comprised of the ceramic substrate 1231 of thermoelectric module 1200, a second (cover) substrate 1232, and first and second sidewall elements 1233 and 1234, which are assembled together to form the second fluid chamber 1230. The cover substrates 1222 and 1232, and the sidewall elements 1223, 1224, 1233, and 1234, can be formed of polymer or ceramic materials, as desired for a given application.

FIGS. 13A and 13B schematically illustrate a thermal fluid chamber 1300 which can be fabricated using modular components, according to another exemplary embodiment of the disclosure. The thermal fluid chamber 1300 comprises a first modular component 1310 and a second modular component 1320 which can be bonded together to form a thermal fluid chamber 1300 for use in implementing a thermoelectric system. The first modular component 1310 comprises a first substrate 1311 and a first sidewall 1312, and the second modular component 1320 comprises a second substrate 1321 and a second sidewall 1322. The first substrate 1311 comprises a plurality of vertical rib elements R (or ribbed extrusions) on an inner surface thereof, and a metallization layer 1313 disposed on an outer surface thereof which is patterned to form an array of interconnect pads on which thermoelectric pellets are soldered. Similarly, the second substrate 1321 comprises a plurality of vertical rib elements R on an inner surface thereof, and a metallization layer 1323 disposed on an outer surface thereof which is patterned to form an array of interconnect pads on which thermoelectric pellets are soldered.

In some embodiments, the first and second modular components 1310 and 1320 are formed of a ceramic alloy material (such as aluminum nitride) and fabricated using, e.g., an extrusion process or molding process, or other suitable processes. The first and second modular components 1310 and 1320 are assembled together via epoxy or glue, etc., to form the thermal fluid chamber 1300, which can then be utilized as a common thermal fluid chamber that is shared by thermoelectric devices which are disposed on the outer surfaces of the first and second substrates 1311 and 1321, for a thermoelectric system having a stacked architecture, as discussed herein.

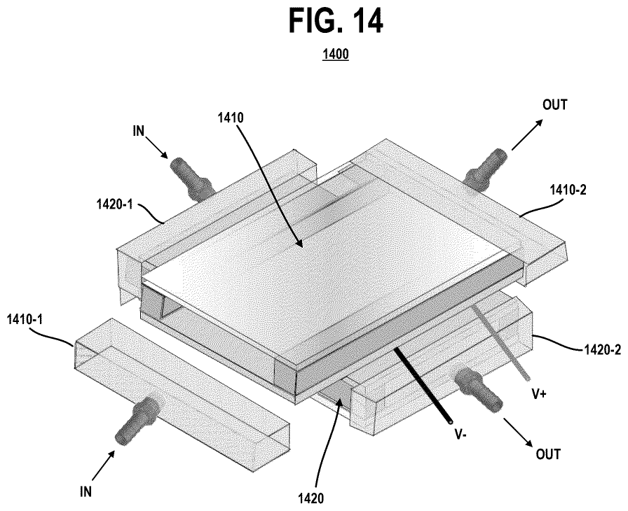

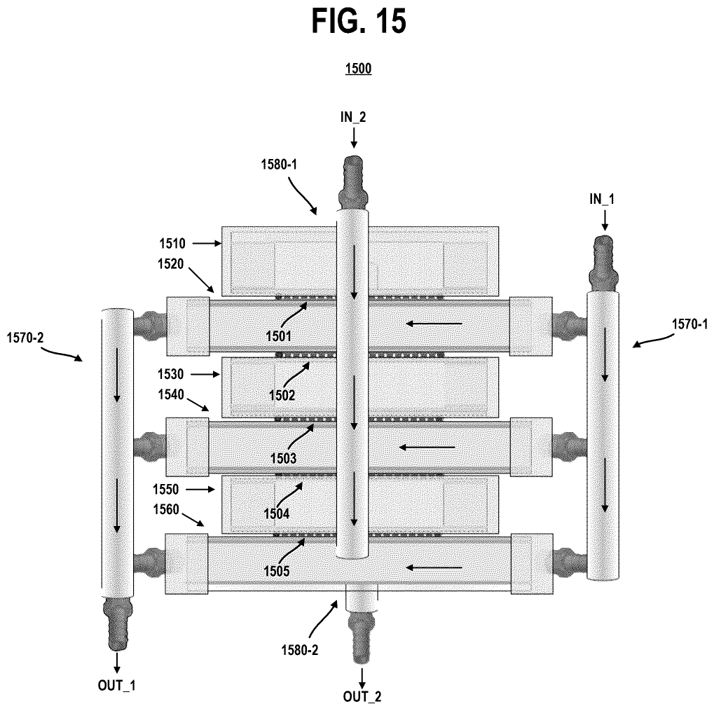

FIG. 14 schematically illustrates a thermoelectric system, according to another exemplary embodiment of the disclosure. In particular, FIG. 14 schematically illustrates a thermoelectric module 1400 which comprises a first fluid chamber 1410 and a second fluid chamber 1420 with a thermoelectric module disposed between the first and second fluid chambers 1410 and 1420. FIG. 14 illustrates an exemplary packaging structure in which the first fluid chamber 1410 and the second fluid chamber 1420 are arranged in a 90-degree orientation such that the flow of thermal transfer fluid in the first fluid chamber 1410 is orthogonal to the flow of thermal transfer fluid in the second fluid chamber 1420.

As schematically shown in FIG. 14, the first fluid chamber 1410 comprises an input manifold 1410-1 which is connected to one open end of the first fluid chamber 1410, and an output manifold 1410-2 which is connected to the other open end of the first fluid chamber 1410. Similarly, the second fluid chamber 1420 comprises an input manifold 1420-1 which is connected to one open end of the second fluid chamber 1420, and an output manifold 1420-2 which is connected to the other open end of the second fluid chamber 1420. In some embodiments, the input manifolds 1410-1 and 1420-1, and the output manifolds 1410-2 and 1420-2 can be designed as covers which slip over and are bonded to the input and output ends of the first and second fluid chambers 1410 and 1420. In other embodiments, the input manifolds 1410-1 and 1420-1, and the output manifolds 1410-2 and 1420-2 can be designed as plates which are bonded to the input and output ends of the first and second fluid chambers 1410 and 1420. The 90-degree orientation of the first and second fluid chambers 1410 and 1420 facilitate the connections of piping and fittings and allowing sufficient spacing between the first and second fluid chambers 1410 and 1420 to slide the input and output manifolds over the open ends of the first and second fluid chambers 1410 and 1420 without interference. This is particularly useful for constructing thermoelectric systems with more than two fluid chambers, such as shown in FIG. 15.

In particular, FIG. 15 schematically illustrates a thermoelectric module 1500 which comprises a stacked configuration which comprises a plurality of thermoelectric modules 1501 1502, 1503, 1504, and 1505, a plurality of thermal fluid chambers 1510, 1520, 1530, 1540, 1550, and 1560, a first input distribution manifold 1570-1, a first output collection manifold 1570-2, a second input distribution manifold 1580-1, and a second output collection manifold 1580-2. The thermoelectric module 1501 is disposed between the thermal fluid chambers 1510 and 1520. The thermoelectric module 1502 is disposed between the thermal fluid chambers 1520 and 1530. The thermoelectric module 1503 is disposed between the thermal fluid chambers 1530 and 1540. The thermoelectric module 1504 is disposed between the thermal fluid chambers 1540 and 1550. The thermoelectric module 1505 is disposed between the thermal fluid chambers 1550 and 1560.

FIG. 15 illustrates an exemplary configuration in which the thermal fluid chambers 1510, 1520, 1530, 1540, 1550, and 1560 are arranged in an alternating 90-degree orientation, where (i) the thermal fluid chambers 1520, 1540, and 1560 have input manifolds that are coupled to first input distribution manifold 1570-1, and output manifolds that are coupled to the first output collection manifold 1570-2, and where (ii) the thermal fluid chambers 1510, 1530, and 1550 have input manifolds that are coupled to second input distribution manifold 1580-1, and output manifolds that are coupled to the second output collection manifold 1550-2. With this configuration, thermal transfer fluid that is input (IN_1) to the first input distribution manifold 1570-1 is distributed into multiple parallel fluid flows through the thermal fluid chambers 1520, 1540, and 1560, and then collected by the first output collection manifold 1570-2, and output (OUT_1) into piping for transfer to a first coil and fan unit. Similarly, thermal transfer fluid that is input (IN_2) to the second input distribution manifold 1580-1 is distributed into multiple parallel fluid flows through the thermal fluid chambers 1510, 1530, and 1550, and then collected by the second output collection manifold 1560-2, and output (OUT_2) into piping for transfer to a second coil and fan unit.

The exemplary embodiments discussed above provide various exemplary architectures of thermoelectric modules in which the thermal paths between the ends of the thermoelectric semiconductor pellets and the thermal transfer fluid in the fluid chambers include supporting substrate layers (e.g., ceramic substrates) that are in direct contact with the thermal transfer fluids flowing in the thermal fluid chambers. In other embodiments, thermoelectric modules are constructed and packaged with thermal fluid chambers, wherein the thermoelectric modules comprise arrays of electrical interconnect pads (which electrically connect the thermoelectric semiconductor pellets) that are exposed on outer surfaces of the thermoelectric modules in direct contact with thermal transfer fluid that flows in the thermal fluid chambers. Such embodiments eliminate the thermal resistance of the ceramic substrates, resulting in thermoelectric modules with enhanced heat pumping capabilities.

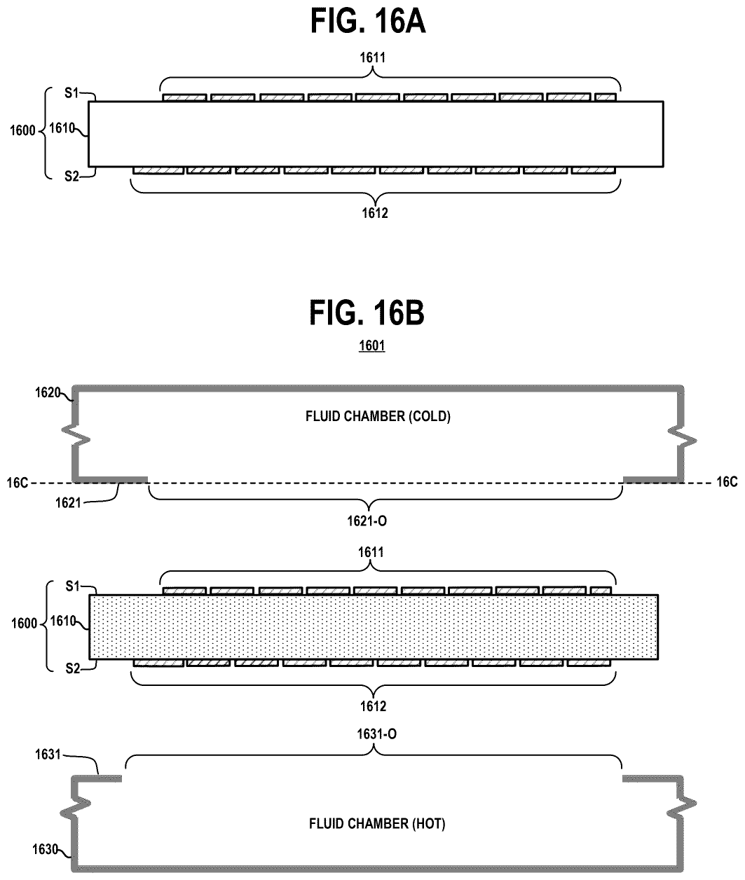

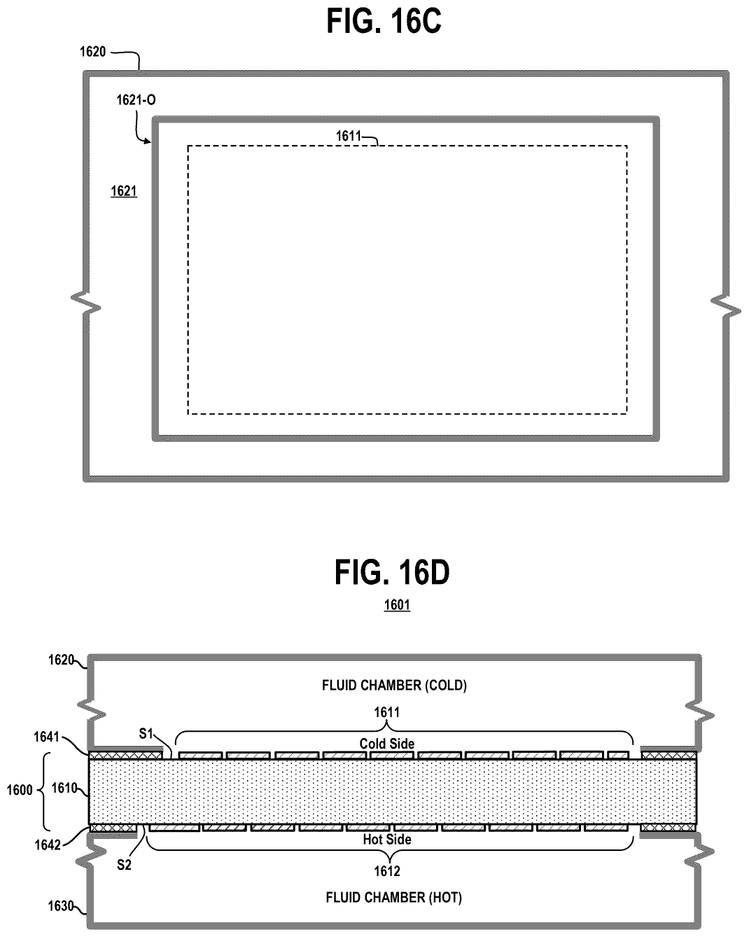

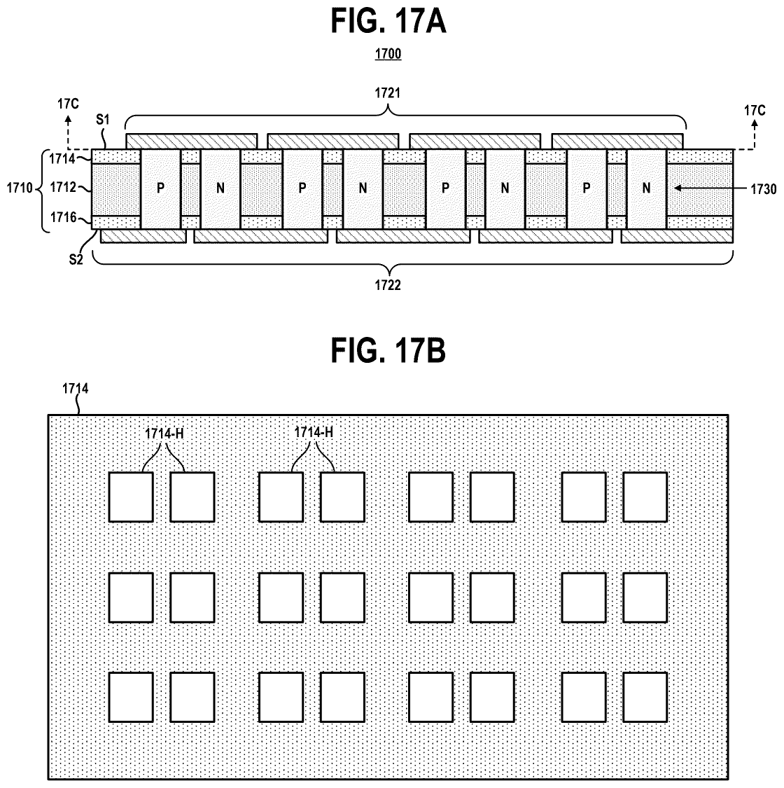

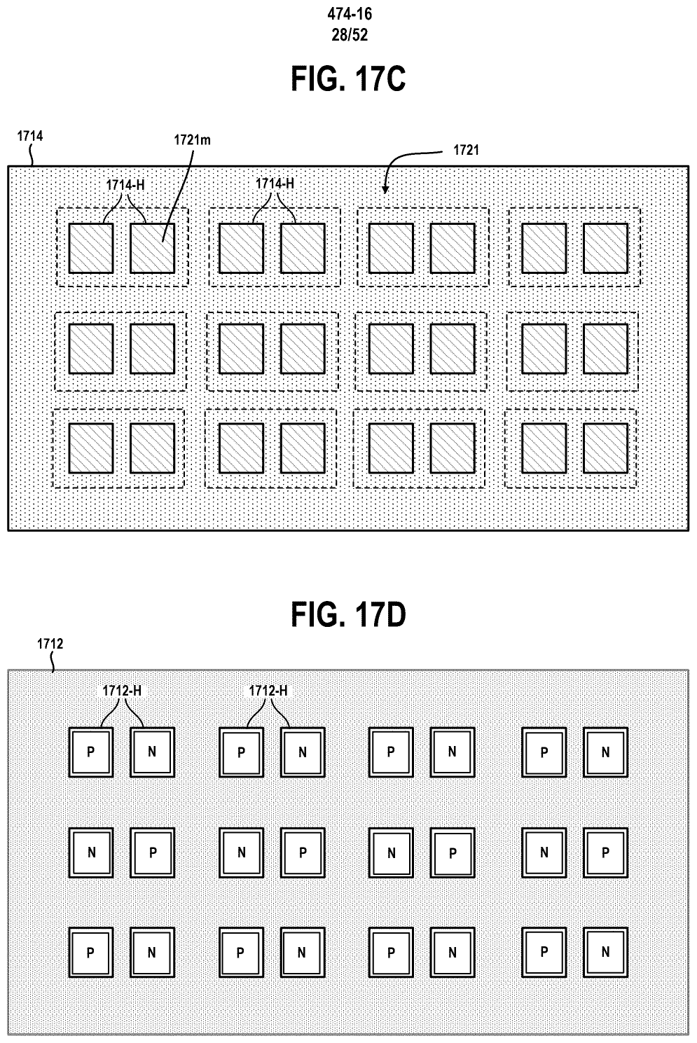

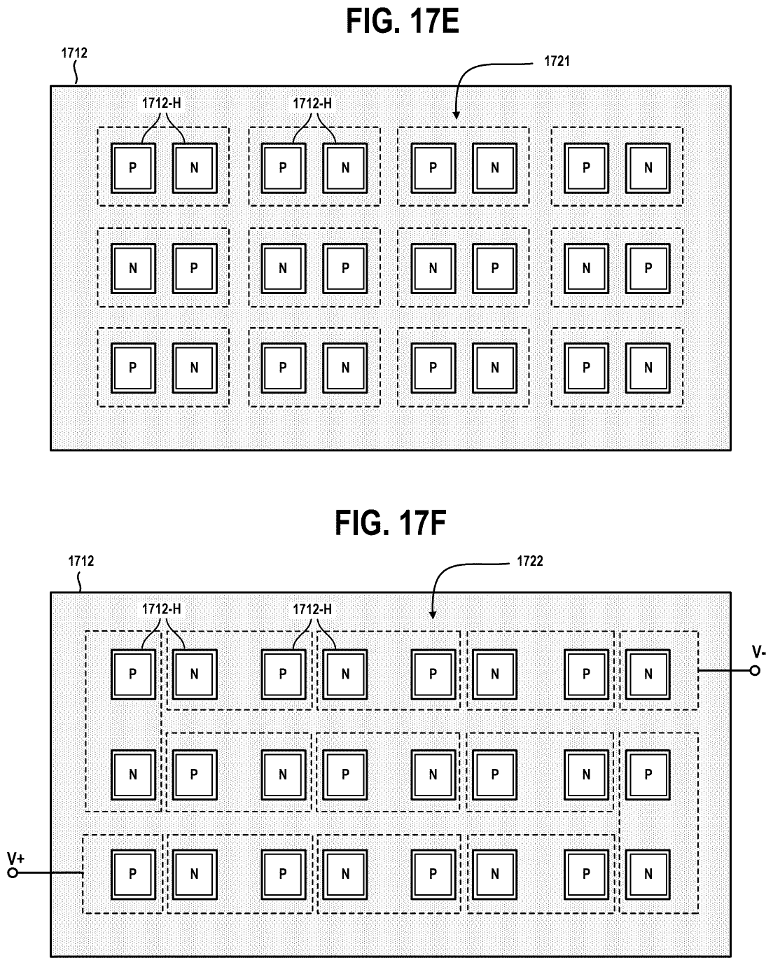

For example, FIG. 16A schematically illustrates a thermoelectric module 1600 according to an exemplary embodiment of the disclosure, where the thermoelectric module 1600 is designed to have metallic interconnect pads in direct contact with thermal transfer fluid that flows in thermal fluid chambers. In particular, the thermoelectric module 1600 comprises a support structure 1610 having a first outer side S1 and a second outer side S2 (opposite the first outer side S1), a first array of interconnect pads 1611 disposed on the first outer side S1 of the support structure 1610, and a second array of interconnect pads 1612 disposed on the second outer side S2 of the support structure 1610. The thermoelectric module 1600 further comprises a plurality of thermoelectric semiconductor pellets disposed within the support structure 1610 between the first and second outer sides S1 and S2, wherein each thermoelectric semiconductor pellet is connected to at least one interconnect pad of the first array of interconnect pads 1611 or the second array of interconnect pads 1612. It is to be noted that FIG. 16A is a high-level architectural illustration of a thermoelectric module which comprises electrical interconnect pads (for connecting thermoelectric pellets) that are externally disposed on the outer sides of the thermoelectric module for direct contact with thermal transfer fluid flowing in thermal fluid chambers, and that the thermoelectric module 1600 can be implemented using one of various exemplary thermoelectric module architectures, such as schematically illustrated and discussed in further detail below in conjunction with, e.g., FIGS. 17A-17F, 18, 19A, 19B, 19C, 20A, 20B, and 21A.

FIGS. 16B, 16C, and 16D schematically illustrate a thermoelectric system according to another exemplary embodiment of the disclosure, which is implemented by packaging the thermoelectric module 1600 of FIG. 16A with thermal fluid chambers. In particular, FIG. 16B is an exploded view of a thermoelectric system 1601 which comprises the thermoelectric module 1600 of FIG. 16A, a first thermal fluid chamber 1620, and a second thermal fluid chamber 1630. The first thermal fluid chamber 1620 comprises a first side 1621 having a first opening 1621-O, and the second thermal fluid chamber 1630 comprises a second side 1631 having a second opening 1631-0. The first opening 1621-0 has a footprint area which is greater than a footprint area of the first array of interconnect pads 1611, and the second opening 1631-O has a footprint area which is greater than a footprint area of the second array of interconnect pads 1612. For example, FIG. 16C is a schematic plan view of the first side 1621 of the first thermal fluid chamber 1620 along a plane which includes line 16C-16C shown in FIG. 16B. In some embodiments, as shown in FIG. 16C, the first opening 1621-O has a rectangular footprint which is larger than a rectangular footprint of an area of the first array of interconnect pads 1611, which is schematically illustrated by a dashed rectangular outline in FIG. 16C.

FIG. 16D schematically illustrates the assembled thermoelectric system 1601 where (i) the first side 1621 of the first thermal fluid chamber 1620 is bonded to the first outer side S1 of the thermoelectric module 1600 via a first adhesive layer 1641, with the first array of interconnect pads 1611 disposed within the first opening 1621-O of the first side 1621 of the first thermal fluid chamber 1620, and where (ii) the second side 1631 of the second thermal fluid chamber 1630 is bonded to the second outer side S2 of the thermoelectric module 1600 via a second adhesive layer 1642, with the second array of interconnect pads 1612 disposed within the second opening 1631-O of the second side 1631 of the second thermal fluid chamber 1630. The first and second adhesive layers 1641 and 1642 can be an epoxy adhesive, room-temperature-vulcanizing (RTV) sealant, such as RTV silicon, or any other suitable type of adhesive material. In some embodiments, gaskets can be used along with mechanical clamping mechanisms to fixedly couple the components together. The first and second fluid chambers 1620 and 1630 can be formed of polymer materials, which are formed by, e.g., injection molding, blow molding, etc., or assembled together via modulator components, as discussed above.

Next, FIG. 17A schematically illustrates a thermoelectric module 1700 according to another exemplary embodiment of the disclosure, where thermoelectric module 1700 is designed to have metallic interconnect pads in direct contact with thermal transfer fluid that flows in thermal fluid chambers. It is to be noted that the thermoelectric module 1700 has an architecture which is based on the high-level architecture of the thermoelectric module 1600 of FIG. 16A. In particular, the thermoelectric module 1700 comprises a support structure 1710 having a first outer side S1 and a second outer side S2 (opposite the first outer side S1), a first array of interconnect pads 1721 disposed on the first outer side S1 of the support structure 1710, and a second array of interconnect pads 1722 disposed on the second outer side S2 of the support structure 1710.

In addition, the thermoelectric module 1700 comprises an array of thermoelectric semiconductor pellets 1730 which are disposed within the support structure 1710 between the first and second outer sides S1 and S2, wherein each thermoelectric semiconductor pellet of the array of thermoelectric semiconductor pellets 1730 is connected to one interconnect pad of the first array of interconnect pads 1721 and to one interconnect pad of the second array of interconnect pads 1722. More specifically, each thermoelectric semiconductor pellet has (i) a first end which extends through corresponding openings (or through-holes) in the support structure 1710 and is connected to a given interconnect pad of the first array of interconnect pads 1721 disposed on the first outer side S1 of the support structure 1710, and (ii) a second end which extends through corresponding openings (or through-holes) in the support structure 1710 and is connected to a given interconnect pad of the second array of interconnect pads 1722 disposed on the second outer side S2 of the support structure 1710.

FIG. 17A illustrates an exemplary embodiment in which the support structure 1710 comprises a substrate 1712, a first metal bonding layer 1714 (or first buffer layer), and a second metal bonding layer 1716 (or second buffer layer). In some embodiments, the substrate 1712 comprises a polymer substrate. In some embodiments, the substrate 1712 comprises a ceramic substrate (e.g., aluminum oxide substrate). In some embodiments, the first and second metal bonding layers 1714 and 1716 each comprise a thin ceramic layer. For example, in some embodiments, the first and second metal bonding layers 1714 and 1716 are formed of a zirconium oxide material (e.g., zirconia). In other embodiments, the first and second metal bonding layers 1714 and 1716 are formed of a glass material. For example, the first and second metal bonding layers 1714 and 1716 can be Willow® glass laminate layers. The glass material that is used to that is utilized for the first and second metal bonding layers 1714 and 1716 should have low thermal conductivity and high insulative properties, and preferably a CTE that corresponds to the metallization of the interconnect pads disposed thereon. In the exemplary embodiment of FIG. 17A, the first outer side S1 of the support structure 1710 comprises an outer surface of the first metal bonding layer 1714 on which the first array of interconnect pads 1721 is disposed, and the second outer side S2 of the support structure 1710 comprises an outer surface of the second metal bonding layer 1716 on which the second array of interconnect pads 1722 is disposed.

FIGS. 17B, 17C, 17D, 17E, and 17F schematically illustrate plan views of various layers of the support structure 1710 of the thermoelectric module 1700 of FIG. 17A, according to an exemplary embodiment of the disclosure. For example, FIG. 17B is a schematic plan view of the first metal bonding layer 1714 (e.g., zirconium oxide ceramic layer) having an array of through-holes 1714-H formed therein, which corresponds to the desired layout of the array of thermoelectric semiconductor pellets 1730. The first and second metal bonding layers 1714 and 176 can be laminated on surfaces of the substrate 1712, and then etched to form the through-holes 1714-H of the first metal bonding layer 1714 as shown in FIG. 17B. A layer of metallic material (e.g., copper layer) is bonded to one side (outer surface) of the first metal bonding layer 1714 (covering the through-holes 1714-H), and then patterned using suitable techniques to form the first array of interconnect pads 1721. For example, FIG. 17C is a schematic plan view of the first metal bonding layer 1714 (e.g., zirconium oxide ceramic layer) along line 17C-17C in FIG. 17A, which shows the first array of interconnect pads 1721 (in dashed rectangular boxes) formed on the outer surface of the first metal bonding layer 1714, and interconnect pad metallization 1721m which is exposed through the through-holes 1714-H of the first metal bonding layer 1714. The thermoelectric semiconductor pellets are soldered to the exposed interconnect pad metallization 1721m of the first array of interconnect pads 1721 which are exposed through the through-holes 1714-H. It is to be noted that the second metal bonding layer 1716 (e.g., zirconium oxide ceramic layer) has a pattern of through-holes which corresponds to the pattern of through-holes 1714-H as the first metal bonding layer 1714, but with a different arrangement of metal interconnect pads.

Next, FIG. 17D is a schematic plan view of the substrate layer 1712 (e.g., polymer substrate, or ceramic substrate) having an array of through-holes 1712-H which corresponds the array of through-holes 1714-H of first metal bonding layer 1714 (as well as a corresponding array of through-holes of the second metal bonding layer 1716). In addition, FIG. 17D schematically illustrates the array of thermoelectric semiconductor pellets 1730 (e.g., thermoelectric couples of P-type and N-type thermoelectric pellets) disposed within corresponding through-holes 1712-H that are formed through the substrate 1712. In some embodiments, as schematically shown in FIG. 17D, the through-holes 1712-H that are formed through the substrate 1712 (as well as the corresponding through-holes formed in the first and second metal bonding layers 1714 and 1716) have a cross-sectional area which is larger than the cross-sectional area of the thermoelectric semiconductor pellets 1730. This is to ensure that the thermoelectric semiconductor pellets 1730 can be readily inserted in the through-holes during fabrication, and to mechanically and thermally isolate the sidewalls of the thermoelectric semiconductor pellets 1730 from contacting the substrate 712 and the first and second metal bonding layers 1714 and 1716 by providing a small air gap between the sidewalls of the thermoelectric semiconductor pellets 1730 and the perimeter edges of the through-holes which are formed in the substrate 712 and in the first and second metal bonding layers 1714 and 1716.

Next, similar to FIG. 17C, the exemplary illustrations in FIGS. 17E and 17F are schematic plan views of the substrate layer 1712 (e.g., polymer substrate, or ceramic substrate) having the array of through-holes 1712-H and the array of thermoelectric semiconductor pellets 1730 (e.g., thermoelectric couples of P-type and N-type thermoelectric pellets) disposed within the corresponding through-holes 1712-H. FIG. 17E further illustrates an exemplary layout and arrangement of the first array of interconnect pads 1721 (shown in dashed rectangular boxes) formed on the first metal bonding layer 1714, and FIG. 17F further illustrates an exemplary layout and arrangement of the second array of interconnect pads 1722 (shown in dashed rectangular boxes) formed on the second metal bonding layer 1716 (including a first power V⁺ pad, and a second power V⁻ pad). FIGS. 17E and 17F illustrate an exemplary layout and arrangement of the first and second arrays of interconnect pads 1721 and 1722 to electrically connect the plurality of thermoelectric couples of the array of thermoelectric semiconductor pellets 1730 in series between a first power V⁺ pad, and a second power V-pad. It is to be noted that for case of illustration and discussion, FIGS. 17A-17F illustrate an exemplary embodiment of the thermoelectric module 1700 in which the array of thermoelectric semiconductor pellets 1730 comprises twenty-four (24) thermoelectric semiconductor pellets (or 12 thermoelectric couples), but the thermoelectric module 1700 can be implemented with 100 or more thermoelectric semiconductor pellets such as shown, for example, in FIGS. 3A and 3B.

The thermoelectric module 1700 can be packaged together with thermal fluid chambers to form a thermoelectric system similar to the thermoelectric system 1601 shown and discussed above in conjunction with FIG. 16D, where the thermoelectric module 1600 in FIG. 16D is replaced with the thermoelectric module 1700 of FIG. 17A. In this instance, the thermoelectric module 1700 would be disposed between the first and second fluid chambers 1620 and 1630 with the first side 1621 of the first thermal fluid chamber 1620 bonded to the first outer side S1 of the thermoelectric module 1700 via the first adhesive layer 1641, with the first array of interconnect pads 1721 disposed within the first opening 1621-O of the first side 1621 of the first thermal fluid chamber 1620, and where the second side 1631 of the second thermal fluid chamber 1630 would be bonded to the second outer side S2 of the thermoelectric module 1700 via the second adhesive layer 1742, with the second array of interconnect pads 1722 disposed within the second opening 1631-O of the second side 1631 of the second thermal fluid chamber 1630.

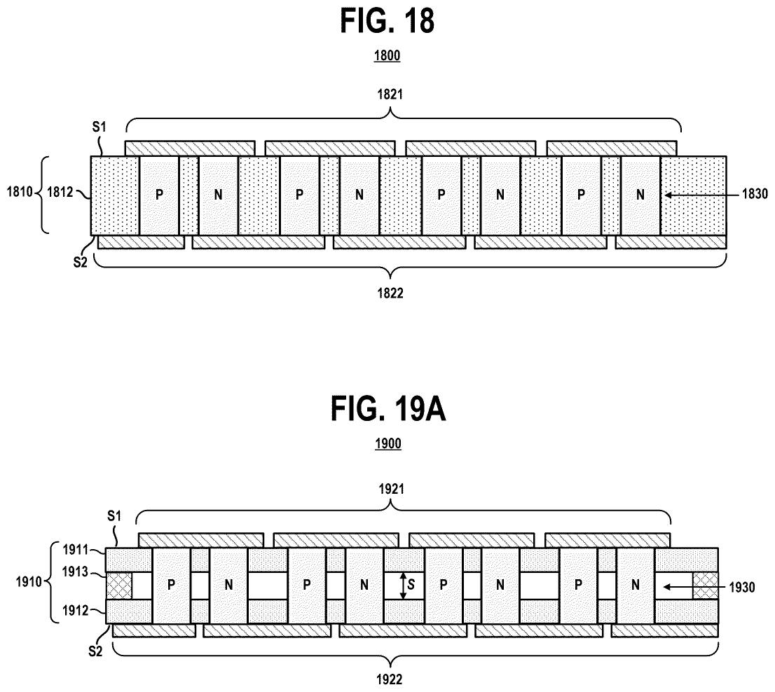

Next, FIG. 18 schematically illustrates a thermoelectric module 1800 according to another exemplary embodiment of the disclosure, where the thermoelectric module 1800 is designed to have metallic interconnect pads in direct contact with thermal transfer fluid that flows in thermal fluid chambers. It is to be noted that the thermoelectric module 1800 has an architecture which is based on the high-level architecture of the thermoelectric module 1600 of FIG. 16A. In particular, the thermoelectric module 1800 comprises a support structure 1810 having a first outer side S1 and a second outer side S2 (opposite the first outer side S1), a first array of interconnect pads 1821 disposed on the first outer side S1 of the support structure 1810, and a second array of interconnect pads 1822 disposed on the second outer side S2 of the support structure 1810.

In addition, the thermoelectric module 1800 comprises an array of thermoelectric semiconductor pellets 1830 which are disposed within the support structure 1810 between the first and second outer sides S1 and S2, wherein each thermoelectric semiconductor pellet of the array of thermoelectric semiconductor pellets 1830 is connected to one interconnect pad of the first array of interconnect pads 1821 and to one interconnect pad of the second array of interconnect pads 1822. More specifically, each thermoelectric semiconductor pellet has (i) a first end which extends through a corresponding opening (or through-hole) in the support structure 1810 and is connected to a given interconnect pad of the first array of interconnect pads 1821 disposed on the first outer side S1 of the support structure 1810, and (ii) a second end which extends through the corresponding opening (or through-hole) in the support structure 1810 and is connected to a given interconnect pad of the second array of interconnect pads 1822 disposed on the second outer side S2 of the support structure 1810.

FIG. 18 illustrates an exemplary embodiment in which the support structure 1810 comprises a substrate 1812 (e.g., ceramic substrate) having a plurality of through-holes formed through the substrate 1812 with corresponding openings exposed on the first and second outer sides S1 and S2 of the substrate 1812. Each thermoelectric semiconductor pellet of the array thermoelectric semiconductor pellets 1830 is disposed within a given through-hole in the substrate 1812, with the ends thereof soldered to corresponding metallic interconnect pads of the first and second arrays interconnect pads 1821 and 1822. In the exemplary embodiment of FIG. 18, the first outer side S1 of the support structure 1810 comprises first (upper) surface of the substrate 1812 (e.g., ceramic substrate) on which the first array of interconnect pads 1821 is disposed, and the second outer side S2 of the support structure 1810 comprises a second (bottom) surface of the substrate 1812 on which the second array of interconnect pads 1822 is disposed. FIG. 18 illustrates an exemplary embodiment in which the first and second arrays of interconnect pads 1821 and 1821 can be bonded to the surfaces of the substrate 1812 (e.g., ceramic substrate) without the use of buffer layers, e.g., the first and second metal bonding layers 1714 and 1716 of the thermoelectric module 1700 shown in FIG. 17A. The thermoelectric module 1800 can be packaged together with thermal fluid chambers to form a thermoelectric system similar to the thermoelectric system 1601 shown and discussed above in conjunction with FIG. 16D, where the thermoelectric module 1600 in FIG. 16D is replaced with the thermoelectric module 1800 of FIG. 18.

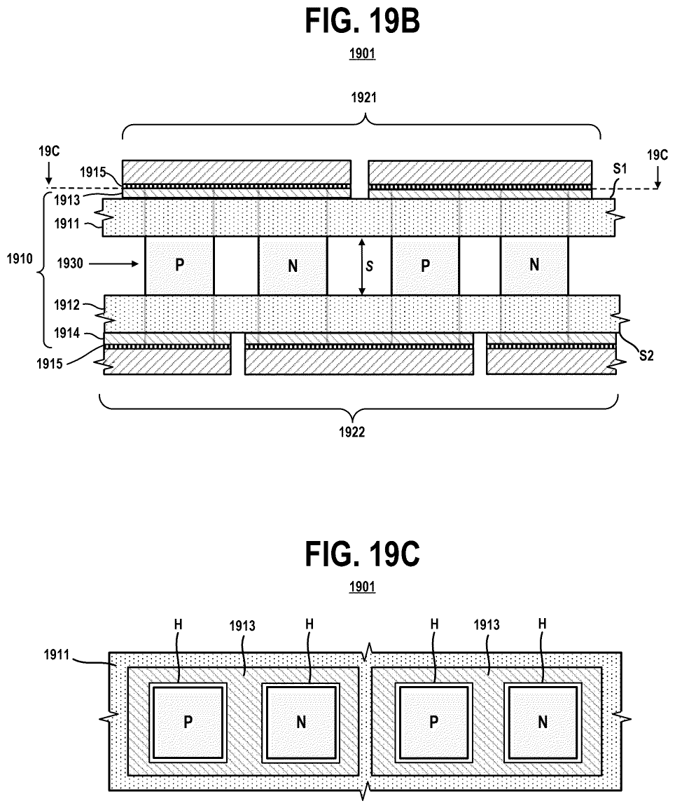

Next, FIG. 19A schematically illustrates a thermoelectric module 1900 according to another exemplary embodiment of the disclosure, where the thermoelectric module 1900 is designed to have metallic interconnect pads in direct contact with thermal transfer fluid that flows in thermal fluid chambers. It is to be noted that the thermoelectric module 1900 has an architecture which is based on the high-level architecture of the thermoelectric module 1600 of FIG. 16A. In particular, the thermoelectric module 1900 comprises a support structure 1910 having a first outer side S1 and a second outer side S2 (opposite the first outer side S1), a first array of interconnect pads 1921 disposed on the first outer side S1 of the support structure 1910, and a second array of interconnect pads 1922 disposed on the second outer side S2 of the support structure 1910.

In addition, the thermoelectric module 1900 comprises an array of thermoelectric semiconductor pellets 1930 which are disposed within the support structure 1910 between the first and second outer sides S1 and S2, wherein each thermoelectric semiconductor pellet of the array of thermoelectric semiconductor pellets 1930 is connected to one interconnect pad of the first array of interconnect pads 1921 and to one interconnect pad of the second array of interconnect pads 1922. More specifically, each thermoelectric semiconductor pellet has (i) a first end which extends through corresponding openings (or through-holes) in the support structure 1910 and is connected to a given interconnect pad of the first array of interconnect pads 1921 disposed on the first outer side S1 of the support structure 1910, and (ii) a second end which extends through corresponding openings (or through-holes) in the support structure 1910 and is connected to a given interconnect pad of the second array of interconnect pads 1922 disposed on the second outer side S2 of the support structure 1910.

FIG. 19A illustrates an exemplary embodiment in which the support structure 1910 comprises a first substrate 1911, and a second substrate 1912, which have inner surfaces that are separated by an air space S. In some embodiments, the first and second substrates 1911 and 1912 comprise polymer substrates. For example, in some embodiments, the first and second substrates 1911 and 1912 comprise FR4 printed circuit boards. In other embodiments, the first and second substrates 1911 and 1912 comprise ceramic substrates (e.g., aluminum oxide substrates). In the exemplary embodiment of FIG. 19A, the first outer side S1 of the support structure 1910 comprises an outer surface of the first substrate 1911 on which the first array of interconnect pads 1921 is disposed, and the second outer side S2 of the support structure 1910 comprises an outer surface of the second substrate 1912 on which the second array of interconnect pads 1922 is disposed. In some embodiments, a sealant layer 1913 (e.g., RTV silicon) is applied around an outer perimeter portion of the air space S to prevent exposure of the inner region of the thermoelectric module 1900 to external elements (e.g., dust, moisture, etc.). The thermoelectric module 1900 can be packaged together with thermal fluid chambers to form a thermoelectric system similar to the thermoelectric system 1601 shown and discussed above in conjunction with FIG. 16D, where the thermoelectric module 1600 in FIG. 16D is replaced with the thermoelectric module 1900 of FIG. 19A.

Similar to the various layers of the support structure 1710 shown in FIGS. 17A-17F, the first and second substrates 1911 and 1912 comprise corresponding arrays of through-holes which are formed in the first and second substrates 1911 and 1912, and which are configured to insertably receive end portions of the thermoelectric semiconductor pellets 1930 to thereby solder the end portions of the thermoelectric pellets 1930 to the exposed metallization of the interconnect pads of the first and second arrays of interconnect pads 1921 and 1922. It is to be noted that as compared to the exemplary embodiments of the support structures 1710 and 1810 shown in FIGS. 17A and 18, the exemplary structural configuration of the support structure 1910 shown in FIG. 19A comprise an air space S (or air gap) within a central region of the support structure 1910 to provide enhanced thermal isolation between the thermoelectric semiconductor pellets 1930. In particular, the air space S provides air gaps between adjacent thermoelectric semiconductor pellets to provide thermal resistance to heat flow and reduce the amount of heat transfer between adjacent thermoelectric semiconductor pellets via convection.

Next, FIGS. 19B and 19C schematically illustrate a thermoelectric module 1901 according to another exemplary embodiment of the disclosure, where the thermoelectric module 1901 is designed to have metallic interconnect pads in direct contact with thermal transfer fluid that flows in thermal fluid chambers. FIG. 19B is a schematic cross-sectional view of the thermoelectric module 1901, and FIG. 19C is a schematic plan view of the thermoelectric module 1901 along line 19C-19C of FIG. 19B. The thermoelectric module 1901 is similar in architecture to the thermoelectric module 1900 of FIG. 19A, except that the thermoelectric module 1901 further comprises a plurality of first metallic frames 1913 that are patterned on a surface of the first substrate 1911, and a plurality of second metallic frames 1914 that are patterned on a surface of the second substrate 1912. More specifically, in embodiments wherein the first and second substrates 1911 and 1912 comprise FR4 printed circuit boards, the first metallic frames 1913 can be fabricated by patterning a first metal laminate layer (e.g., laminate copper layer) on the surface of the first substrate 1911 to form the first metallic frames 1913, and the second metallic frames 1914 can be fabricated by patterning a second metal laminate layer (e.g., laminate copper layer) on the surface of the second substrate 1912 to form the second metallic frames 1914.

In addition, a plurality of through-holes are formed through the first substrate 1911 and the first metallic frames 1913 to insertably receive first end portions of the thermoelectric pellets 1930. Similarly, a plurality of through-holes are formed through the second substrate 1912 and the second metallic frames 1914 to insertably receive second end portions of the thermoelectric pellets 1930. For example, as schematically shown in FIG. 19C, a plurality of through-holes H are formed through the first substrate 1911 and the first metallic frames 1913. The first metallic frames 1913 are formed to surround respective thermoelectric couples (N-P pairs) of the thermoelectric pellets 1930.

As schematically shown in FIG. 19B, the interconnect pads of the first array of interconnect pads 1921 are soldered (via solder material 1915) to corresponding metallic frames of the plurality of first metallic frames 1913 and to the first end portions of the thermoelectric pellets 1930, which extend through corresponding through-holes H that are formed in the first substrate 1911 and the first metallic frames 1913. Similarly, the interconnect pads of the second array of interconnect pads 1922 are soldered (via solder material 1915) to corresponding metallic frames of the plurality of second metallic frames 1914 and to second end portions of the thermoelectric pellets 1930, which extend through corresponding through-holes H that are formed in the second substrate 1912 and the second metallic frames 1914.

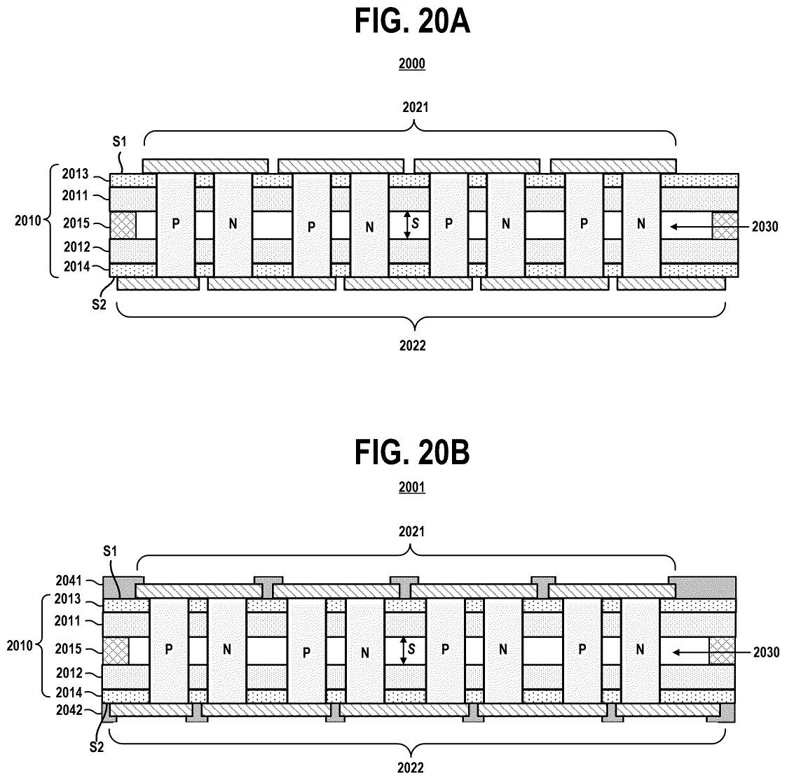

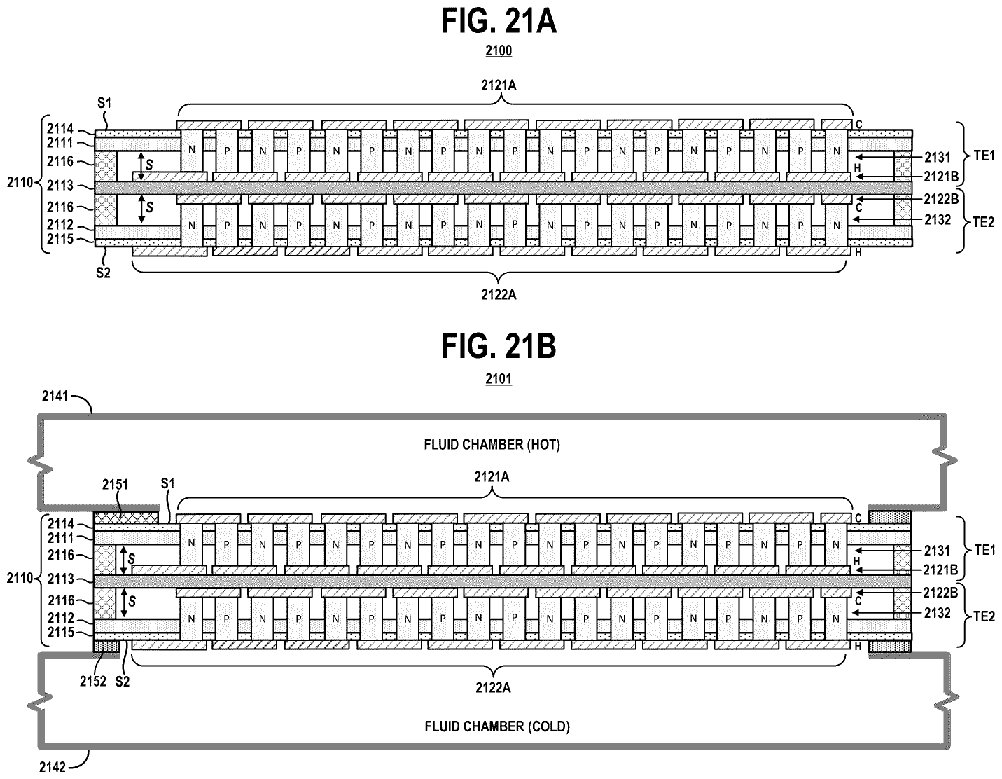

Next, FIG. 20A schematically illustrates a thermoelectric module 2000 according to another exemplary embodiment of the disclosure, where the thermoelectric module 2000 is designed to have metallic interconnect pads in direct contact with thermal transfer fluid that flows in thermal fluid chambers. It is to be noted that the thermoelectric module 2000 has an architecture which is based on the high-level architecture of the thermoelectric module 1600 of FIG. 16A. In particular, the thermoelectric module 2000 comprises a support structure 2010 having a first outer side S1 and a second outer side S2 (opposite the first outer side S1), a first array of interconnect pads 2021 disposed on the first outer side S1 of the support structure 2010, and a second array of interconnect pads 2022 disposed on the second outer side S2 of the support structure 2010.

In addition, the thermoelectric module 2000 comprises an array of thermoelectric semiconductor pellets 2030 which are disposed within the support structure 2010 between the first and second outer sides S1 and S2, wherein each thermoelectric semiconductor pellet of the array of thermoelectric semiconductor pellets 2030 is connected to one interconnect pad of the first array of interconnect pads 2021 and to one interconnect pad of the second array of interconnect pads 2022. More specifically, each thermoelectric semiconductor pellet has (i) a first end which extends through corresponding openings (or through-holes) in the support structure 2010 and is connected to a given interconnect pad of the first array of interconnect pads 2021 disposed on the first outer side S1 of the support structure 2010, and (ii) a second end which extends through corresponding openings (or through-holes) in the support structure 2010 and is connected to a given interconnect pad of the second array of interconnect pads 2022 disposed on the second outer side S2 of the support structure 2010.

FIG. 20A illustrates an exemplary embodiment in which the support structure 2010 has an architecture similar to that of the support structure 1910 of FIG. 19A. For example, the support structure 2010 comprises a first substrate 2011 and a second substrate 2012, which have inner surfaces that are separated by an air space S. In some embodiments, the first and second substrates 2011 and 2012 comprise polymer substrates (e.g., FR4 printed circuit boards), while in other embodiments, the first and second substrates 2011 and 2012 comprise ceramic substrates (e.g., aluminum oxide substrates). The support structure 2010 further comprises a first metal bonding layer 2013 (or first buffer layer) which is laminated on the first substrate 2011, and a second metal bonding layer 2014 (or second buffer layer) which is laminated on the second substrate 2012.

In some embodiments, the first and second metal bonding layers 2013 and 2014 each comprise a thin ceramic layer. For example, in some embodiments, the first and second metal bonding layers 2013 and 2014 are formed of a zirconium oxide material (e.g., zirconia). In other embodiments, the first and second metal bonding layers 2013 and 2014 are formed of a glass material. For example, the first and second metal bonding layers 2013 and 2014 can be Willow® glass laminate layers. In some embodiments, a sealant layer 2015 (e.g., RTV silicon) is applied around an outer perimeter portion of the air space S to prevent exposure of the inner region of the thermoelectric module 2000 to external elements (e.g., dust, moisture, etc.).

Similar to the various layers of the support structure 1710 shown in FIGS. 17A-17F, the first and second substrates 2011 and 2012, and the first and second metal bonding layers 2013 and 2014 comprise corresponding arrays of through-holes formed therein, and which are configured to insertably receive end portions of the thermoelectric semiconductor pellets 2030 to thereby solder the end portions of the thermoelectric pellets 2030 to the exposed metallization of the interconnect pads of the first and second arrays of interconnect pads 2021 and 2022. Again, the air space S (or air gap) within a central region of the support structure 2010 provides enhanced thermal isolation between the thermoelectric semiconductor pellets 2030 by providing thermal resistance to heat flow through the air gaps and thereby reduce the amount of heat transfer between adjacent thermoelectric semiconductor pellets 2030 via convection. The air space S serves to reduce the build-up of heat within the thermoelectric module 2000. The thermoelectric module 2000 can be packaged together with thermal fluid chambers to form a thermoelectric system similar to the thermoelectric system 1601 shown and discussed above in conjunction with FIG. 16D, where the thermoelectric module 1600 in FIG. 16D is replaced with the thermoelectric module 2000 of FIG. 20A.

Next, FIG. 20B schematically illustrates a thermoelectric module 2001 according to another exemplary embodiment of the disclosure, where the thermoelectric module 2001 is designed to have metallic interconnect pads in direct contact with thermal transfer fluid that flows in thermal fluid chambers. It is to be noted that the thermoelectric module 2001 has an architecture which is based on the high-level architecture of the thermoelectric module 1600 of FIG. 16A, and which is similar to the thermoelectric module 2000 of FIG. 20A. In particular, the thermoelectric module 2001 comprises the same or similar architecture of the support structure 2010 as shown and discussed above in conjunction with FIG. 20A, where the support structure 2010 has the first array of interconnect pads 2021 disposed on the first outer side S1 of the support structure 2010, and the second array of interconnect pads 2022 disposed on the second outer side S2 of the support structure 2010.

FIG. 20B illustrates an exemplary embodiment in which the thermoelectric module 2001 further comprises a first conformal layer 2041 formed on the first outer surface S1 thereof, and a second conformal layer 2042 formed on the second outer surface S2 thereof. The first conformal layer 2041 comprises a first conformal layer of sealant material which is deposited to form seals that are configured to seal perimeter edges of the interconnect pads of the first array of interconnect pads 2021. Similarly, the second conformal layer 2042 comprises a second conformal layer of sealant material which is deposited to form seals that are configured to seal perimeter edges of the interconnect pads of the second array of interconnect pads 2022. The first and second conformal layers 2041 and 2042 of sealant material are implemented to ensure that heat transfer fluid does not seep into and degrade the bonding interface between the bottoms of the metallic interconnect pads and the outer surfaces S1 and S2 of the thermoelectric module 2001.

In some embodiments, as schematically illustrated in FIGS. 20B, the first and second conformal layers 2041 and 2042 of sealant material are formed to cover the sides of the metallic interconnect pads and a very small region on the upper perimeter surface of the metallic interconnect pads, while allowing the upper surfaces of the metallic interconnect pads to be in direct contact with thermal transfer fluids that flow in thermal fluid chambers packaged with the thermoelectric module 2001. The first and second conformal layers 2041 and 2042 of sealant material can be formed by utilizing a mask layer which covers the metallic interconnect pads while exposing perimeter regions of the metallic interconnect pads and the first and second surfaces S1 and S2, and then conformally depositing a layer of sealant material to conformally cover the exposed perimeter edges of the metallic interconnect pads and exposed surfaces S1 and S2 with sealing material. It is to be noted that while not specifically shown in FIGS. 16A, 17A, 18, 19A, and 19B, the thermoelectric modules 1600, 1700, 1800, 1900, 1901 can be constructed with first and second conformal layers on the first and second outer surfaces S1 and S2 thereof to seal the perimeter edges of the interconnect pads of the first and second arrays of interconnect pads.

The first and second conformal layers 2041 and 2042 can be formed of a sealant material which has properties that are suitable for the given application. For example, the sealant material should be, for example, (i) be hydrophobic (if the heat transfer fluid is a water-based fluid), (ii) thermally conductive (optionally), (iii) electrically insulative, (iv) capable of adhering to the materials of the interconnect pad metallization (e.g., copper), and the metal bonding layers (e.g., ceramic or glass), (v) CTE compatible with the CTEs of the materials of the interconnect pad metallization and the metal bonding layers, and (vi) have a wide temperature range of operation (e.g., −20° F. to +500° F.). For example, in some embodiments, the first and second conformal layers 2041 and 2042 can be formed of materials including, but are not limited to, a urethane thin film coating (which can be sprayed on using a mask), a silicon material, a urethane silicon material, a thermoplastic rubber (TPR) material, a thermoplastic elastomer (TPE) material (mix of polymers and rubber with high elasticity, which can be mixed proportionally to provide varied flexibility), etc. The conformal coating materials should be absorption resistant and corrosion resistant to the type of thermal transfer fluid that is used. In addition, the conformal coating materials should have high-heat resistance so that the conformal coating layers are not heat damaged as a result of soldering, UV curing, heat curing, during fabrication of the thermoelectric modules and associated thermoelectric systems, etc.

Next, FIG. 21A schematically illustrates a thermoelectric module 2100 according to another exemplary embodiment of the disclosure, where the thermoelectric module 2100 is designed to have metallic interconnect pads in direct contact with thermal transfer fluid that flows in thermal fluid chambers. It is to be noted that the thermoelectric module 2100 has an architecture which is based on the high-level architecture of the thermoelectric module 1600 of FIG. 16A. In particular, the thermoelectric module 2100 comprises a support structure 2110 having a first outer side S1 and a second outer side S2 (opposite the first outer side S1), a first array of interconnect pads 2121A disposed on the first outer side S1 of the support structure 2010, and a second array of interconnect pads 2122A disposed on the second outer side S2 of the support structure 2110. The thermoelectric module 2100 comprises a first array of thermoelectric semiconductor pellets 2131 and a second array of thermoelectric pellets 2132, which are disposed within the support structure 2110 between the first and second outer sides S1 and S2, wherein each thermoelectric semiconductor pellet of the first and second arrays of thermoelectric semiconductor pellets 2131 and 2132 is connected to at least one interconnect pad of the first array of interconnect pads 2121A or the second array of interconnect pads 2122A.

The thermoelectric module 2100 further comprises a third array of interconnect pads 2121B, and a fourth array of interconnect pads 2122B. The thermoelectric module 2100 comprises a stacked configuration multiple thermoelectric modules including a first thermoelectric module TE1 and a second thermoelectric module TE2. The first thermoelectric module TE1 comprises the first and third arrays of interconnect pads 2121A and 2121B, and the first array of thermoelectric semiconductor pellets 2131, which comprises a plurality of thermoelectric couples that are connected in series by the first and third arrays of interconnect pads 2121A and 2121B. The second thermoelectric module TE2 comprises the second and fourth arrays of interconnect pads 2122A and 2122B, and the second array of thermoelectric semiconductor pellets 2132, which comprises a plurality of thermoelectric couples that are connected in series by the second and fourth arrays of interconnect pads 2122A and 2122B.

In addition, FIG. 21A illustrates an exemplary embodiment in which the support structure 2110 comprises a first substrate 2111, a second substrate 2112, a third substrate 2113, a first metal bonding layer 2114, and a second metal bonding layer 2115. The third substrate 2113 comprises a central (common) substrate which comprises the third array of interconnect pads 2121B formed on first surface thereof, and the fourth array of interconnect pads 2122B formed on a second surface, opposite the first surface. In some embodiments, the third substrate 2113 comprises a ceramic substrate (e.g., aluminum nitride) which has good thermal conductivity to enable heat transfer between the first and second thermoelectric modules TE1 and TE2.

The first and second substrates 2111 and 2112 have inner surfaces that are separated from the respective first and second surfaces of the third substrate 2113 by respective air spaces S. In some embodiments, the first and second substrates 2111 and 2112 comprise polymer substrates (e.g., FR4 printed circuit boards), while in other embodiments, the first and second substrates 2111 and 2112 comprise ceramic substrates (e.g., aluminum oxide substrates). The first metal bonding layer 2114 (or first buffer layer) is laminated on the first substrate 2111, and the second metal bonding layer 2115 (or second buffer layer) is laminated on the second substrate 2112. In some embodiments, the first and second metal bonding layers 2114 and 2115 each comprise a thin ceramic layer. For example, in some embodiments, the first and second metal bonding layers 2114 and 2115 are formed of a zirconium oxide material (e.g., zirconia). In other embodiments, the first and second metal bonding layers 2114 and 2115 are formed of a glass material. For example, the first and second metal bonding layers 2114 and 2115 can be Willow® glass laminate layers. Moreover, some embodiments, sealant layers 2016 (e.g., RTV silicon) can be applied around outer perimeter portions of the air spaces S to prevent exposure of the inner regions of the thermoelectric module 2100 to external elements (e.g., dust, moisture, etc.).

Similar to the various layers of the support structure 1710 shown in FIGS. 17A-17F, the first and second substrates 2111 and 2112, and the first and second metal bonding layers 2114 and 2115 comprise corresponding arrays of through-holes formed therein, which are configured to insertably receive end portions of the thermoelectric semiconductor pellets of the respective first and second arrays of thermoelectric pellets 2131 and 2132 to thereby solder the end portions of the thermoelectric pellets to the exposed metallization of the interconnect pads of the first and second arrays of interconnect pads 2121A and 2122A. Again, the air spaces S (or air gaps) within the support structure 2110 serve to thermally isolate the thermoelectric semiconductor pellets in the respective first and second arrays of thermoelectric semiconductor pellets 2131 and 2132 (provide thermal resistance to heat flow through the air gaps) and thereby reduce the amount of heat transfer between adjacent thermoelectric semiconductor pellets and, reduce the build-up of heat within the thermoelectric module 2100.

The thermoelectric module 2100 can be packaged together with thermal fluid chambers to form a thermoelectric system 2101, such as shown in FIG. 21B. In particular, as schematically shown in FIG. 21B, the thermoelectric module 2100 is disposed between first and second fluid chambers 2141 and 2142, wherein a first side of the first thermal fluid chamber 2141 bonded to the first outer side S1 of the thermoelectric module 2100 via an first adhesive layer 2151, with the first array of interconnect pads 2121A disposed within an opening in the first side of the first thermal fluid chamber 2141, and wherein a second side of the second thermal fluid chamber 2142 is bonded to the second outer side S2 of the thermoelectric module 2100 via a second adhesive layer 2152, with the second array of interconnect pads 2122A disposed within a second opening of the second side of the second thermal fluid chamber 2142. Again, it is to be noted that while not specifically shown in FIGS. 21A and 21B, the thermoelectric module 2100 can be constructed with first and second conformal layers on the first and second outer surfaces S1 and S1 thereof to seal the perimeter edges of the interconnect pads of the first and second arrays of interconnect pads 2121A and 2122A.

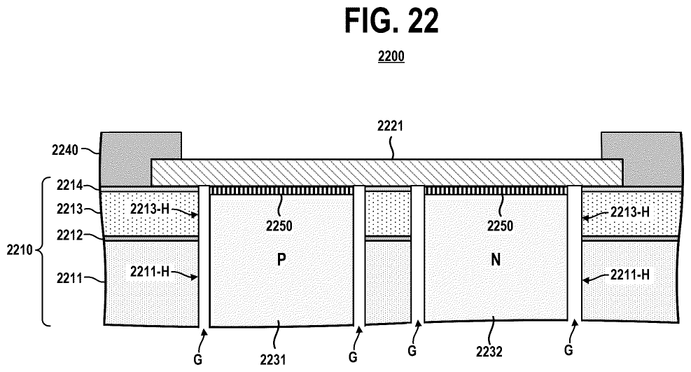

FIG. 22 schematically illustrates a thermoelectric module, according to another exemplary embodiment of the disclosure. In particular, FIG. 22 schematically illustrates a thermoelectric module 2200 which has an architecture similar to that of the thermoelectric module 2021 of FIG. 20B. For case of illustration, FIG. 22 illustrates a portion of the thermoelectric module 2200 to illustrate structural details of a support structure 2210 comprising a first substrate 2211, a first adhesive layer 2212, a first metal bonding layer 2213, a second adhesive layer 2214, a metallic interconnect pad 2221, a thermoelectric couple comprising a first thermoelectric semiconductor pellet 2231 (P-type thermoelectric pellet) and a second thermoelectric semiconductor pellet 2232 (N-type thermoelectric pellet), a conformal layer 2240 of sealant material, and solder layers 2250.

As noted above, the first substrate 2221 can be a polymer substrate such as, e.g., an ABS substrate, a FR4 printed circuit board, or other types of substrates formed of plastic or polymer materials having properties that are suitable for given application (e.g., desired temperature tolerance, CTE, rigidity, and hydrophobic properties, etc.), and which provide a suitable support substrate backbone for the thermoelectric semiconductor pellets and thermal fluid chambers. In addition, the first metal bonding layer 2213 can be a ceramic substrate or a glass substrate, as described above. The first substrate 2211 comprises an array of through-holes 2211-H formed therein, and the first metal bonding layer 2213 comprises a corresponding array of through-holes 2213-H formed therein, wherein the arrays of through-holes 2211-H and 2213-H are aligned to each other.

As schematically illustrated in FIG. 22, the first thermoelectric semiconductor pellet 2231 (P-type thermoelectric pellet) and the second thermoelectric semiconductor pellet 2232 (N-type thermoelectric pellet) are disposed within respective through-holes of the arrays of through-holes 2211-H and 2213-H, wherein an upper ends of the first and second thermoelectric semiconductor pellets 2231 and 2232 are electrically connected, via the solder layers 2250, to an inner surface regions of the metallic interconnect pad 2221 which are exposed by the through-holes.

In some embodiments, as schematically illustrated in FIG. 22, the sizes of the through-holes 2211-H and 2213-H and the sizes of the first and second thermoelectric semiconductor pellets 2231 and 2232 are dimensionally configured to ensure that air gaps G are present between the sidewalls of the first and second thermoelectric semiconductor pellets 2231 and 2232 and the through-hole sidewalls of the first substrate 2211 and the first metal bonding layer 2213. Again, as noted above, the air gaps G serve to thermally insulate the sidewalls of the first and second thermoelectric semiconductor pellets 2231 and 2232 from the through-hole sidewalls of the first substrate 2211 and the first metal bonding layer 2213, and thereby provide high thermal resistance (or low thermal conductivity) therebetween, as compared to a structural configuration in which the through-hole sidewalls of the first substrate 2211 and the first metal bonding layer 2213 would be in physical contact with the sidewalls of the first and second thermoelectric semiconductor pellets 2231 and 2232. In this regard, the air gaps G prevent or minimize heat transfer from the first and second thermoelectric semiconductor pellets 2231 and 2232 to the first substrate 2211 and the metal bonding layer 2213.

In some embodiments, the second adhesive layer 2214 is utilized to bond a layer of metallization (e.g., layer of copper metal) to a surface of the first metal bonding layer 2213 which already has the array of through-holes 2213-H formed therein. In this regard, the metallization layer (e.g., copper layer) is laminated on a first surface of the first metal bonding layer 2213 via the second adhesive layer 2214, and covering the through-holes 2213-H. The laminated metallization layer is then patterned by any suitable process, e.g., chemical etching or laser cutting, etc., to form an array of interconnect pads including the metal interconnect pad 2221 on the surface of the first metal bonding layer 2213.

Further, in some embodiments, the first adhesive layer 2212 is utilized to bond the first metal bonding layer 2113 and the first substrate 2221 together, with the array of through-holes 2213-H of the first metal bonding layer 2213 aligned to the array of through-holes 2211-H of the first substrate 2211. In this regard, in some embodiments, the first metal bonding layer 2113 with the interconnect pad metallization is separately fabricated, and then laminated on a surface of the first substrate layer 2211. While not specifically shown in FIG. 22, similar to the exemplary architecture shown in FIG. 20B, the support structure 2210 comprises a second substrate (separated by the first substrate 2211 by an air space S) and a second metal bonding layer with metal interconnect pads, which are constructed and bonded/laminated to each other using adhesive layers as discussed above, with bottom ends of first and second thermoelectric semiconductor pellets 2231 and 2232 disposed in corresponding though-holes of the second substrate and the second metal bonding layer and soldered to inner exposed surfaces of metal interconnect pads disposed on the second metal bonding layer.

Moreover, as schematically shown in FIG. 22, the conformal layer 2240 surrounds and covers the outer perimeter region of the metal interconnect pad 2221 to prevent leaching and infiltration of thermal transfer fluid underneath the metal interconnect pad 2221, which could result in damaging or degrading the performance of the thermoelectric module. For example, the leaching of thermal transfer fluid underneath the metal interconnect pad 2221 can result in, e.g., (i) delamination of the metal interconnect pad 2221, (ii) contamination/corrosion of the solder connections 2250 between the thermoelectric semiconductor pellets 2231 and 2232 and the metal interconnect pad 2221, (iii) electrical shorts between thermoelectric semiconductor pellets of adjacent thermoelectric couples, (iv) leaching of thermal transfer fluid through the air gaps G into the inner air space S of the thermoelectric module, which can degrade the heat pumping capability of the thermoelectric module, etc.

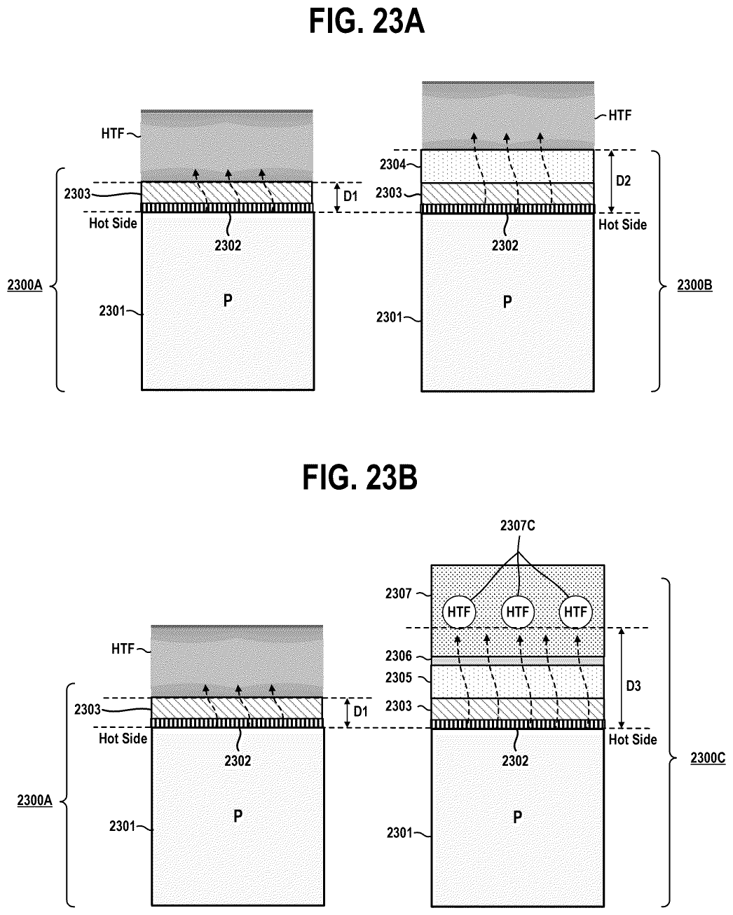

FIG. 23A schematically illustrates heat transfer characteristics of thermoelectric modules, according to exemplary embodiments of the disclosure. In particular, FIG. 23A schematically illustrates a heat transfer characteristic of a thermoelectric module 2300A which comprises a thermoelectric semiconductor pellet 2301, a solder layer 2302, and a metallic interconnect pad 2303 that is in direct contact with heat transfer fluid (denoted HTF) flowing in, e.g., a cold fluid chamber. The thermoelectric module 2300A has an architecture which is based, for example, on that of any of the exemplary thermoelectric modules 1600, 1700, 1800, 1900, and 2000 (as shown in FIGS. 16A, 17, 18, 19, and 20A). In addition, FIG. 23A schematically illustrates a heat transfer characteristic of a thermoelectric module 2300B which comprises the thermoelectric pellet 2301, the solder layer 2302, and the metallic interconnect pad 2303, as well as a ceramic layer 2304 that is direct contact with heat transfer fluid HTF flowing in, e.g., a cold fluid chamber. The thermoelectric module 2300B has an architecture which is based, for example, on that of any of the exemplary thermoelectric modules 500, 600, 900, and 901 (as shown in FIGS. 5A, 6A, 9A, and 9B).

As schematically illustrated in FIG. 23A, for the thermoelectric module 2300A, the heat flux (as illustrated by wavy arrows) flows from a hot side of the thermoelectric semiconductor pellet 2301 to the HTF through a thermal path of distance D1, which includes of the thickness of the solder layer 2302 and the thickness of the metal interconnect pad 2303. On the other hand, for the thermoelectric module 2300B, the heat flux (as illustrated by wavy arrows) flows from the hot side of the thermoelectric semiconductor pellet 2301 to the HTF through a thermal path of distance D2 (where D2>D1), which includes of the thicknesses of the solder layer 2302 and the metal interconnect pad 2303, as well as the thickness of the ceramic layer 2304. In this regard, as compared to the thermoelectric module 2300B, by eliminating the ceramic layer 2304 in the thermal path, the thermoelectric module 2300A significantly reduces the distance (D1<D2) of the thermal path through which the thermal energy has to move from the end of the thermoelectric semiconductor pellet 2301 to reach the HTF, which leads to an increase in the magnitude and rate of heat transfer from the thermoelectric module 2300A to the HTF.

Indeed, the enhanced thermal performance of the architecture of the thermoelectric module 2300A as compared to the architecture of the thermoelectric module 2300B is achieved despite the high thermal conductivities of the metal interconnect pad 2303 and the ceramic layer 2304. Indeed, when made of copper, the metal (copper) interconnect pad 2303 has a high thermal conductivity κ of about

$$400 \frac{W}{m \cdot K} .$$

Moreover, when made of, e.g., aluminum nitride, the ceramic (AlN) layer 2340 has a high thermal conductivity κ of about

$$170 \frac{W}{m \cdot K} .$$

However, given the longer thermal path D2, and the lower “effective” thermal conductivity κ_{Eff} of the copper interconnect pad 2303 and the ceramic layer 2304 combined, the thermoelectric module 2300B exhibits a lower thermal conductance and lower heat flux in the thermal path from the end of the thermoelectric semiconductor pellet 2301 to the heated HTF (through the layers 2303 and 2304), as compared to the thermoelectric module 2300A which eliminates the ceramic layer 2304.

Another issue associated with the architecture of the thermoelectric module 2300B is that the ceramic substrate 2304 is thermally conductive, which in the exemplary embodiment of FIG. 3C, for example, allows thermal energy to flow in a reverse direction from the heated HTF through the ceramic substrate 2304 where heat is dissipated into the air space between the ceramic substates (within the thermoelectric pellet chamber). This reverse flow of heat flux leads increases the heating in the air space, and thus increases the heating of the thermoelectric semiconductor pellets, which reduces the heat pumping performance of the thermoelectric module 2300B. On the other hand, since the architecture of the thermoelectric module 2300A implements support structures that are comprised of low thermal conductivity polymer substrates, and (in some embodiments) low thermal conductivity ceramic or glass substrates (metal bonding layers), such support structures do not allow thermal energy to flow in a reverse direction from the heated HTF through the support structure substrates into the air spaces within the thermoelectric module and cause additional heating of the thermoelectric semiconductor pellets. In this regard, the architecture of the thermoelectric module 2300A can maintain maximum heat pumping performance over a wide range of operating conditions.

FIG. 23B schematically illustrates heat transfer characteristics of a conventional thermoelectric module 2300C. Similar to the exemplary thermoelectric module 2300A, the thermoelectric module 2300C comprises the thermoelectric pellet 2301, the solder layer 2302, and the metallic interconnect pad 2303. The conventional thermoelectric module 2300C further comprises a ceramic substrate layer 2305, a thermal interface material (TIM) layer 2306, and an aluminum water block 2307. The aluminum water block 2307 comprises a plurality of water channels 2307C formed therein through which HTF (water) flows.

As schematically illustrated in FIG. 23B, with the conventional thermoelectric module 2300C, the heat flux (as illustrated by wavy arrows) flows from a hot side of the thermoelectric semiconductor pellet 2301 to the water channels 2307C through a thermal path of distance D3, which includes of the thickness of the solder layer 2302, the thickness of the metal interconnect pad 2303, the thickness of the ceramic substrate 2305, the thickness of the TIM layer 2306, and a thickness of the aluminum water block 2307 between a bottom surface of the aluminum water block 2307 and the water which flows in the water channels 2307C. In this regard, as compared to the novel thermoelectric module 2300A shown in FIG. 23B, the conventional thermoelectric module 2300C comprises a significantly larger amount of thermal resistance in the path from the upper surface of the thermoelectric pellet 2301 to thermal fluid (water) flowing in the water channels 2307C. For example, depending on the material used, the conventional thermoelectric module 2300C can have around 27× (or more) of thermal resistance along the thermal path (distance D3) as compared to the thermal resistance (distance D1) of the novel thermoelectric module 2300A. Moreover, as compared to the conventional thermoelectric module 2300C, the novel thermoelectric module 2300A has a significantly larger volume of thermal heat transfer fluid to, e.g., remove heat at a much higher heat transfer rate, as compared to the small amount of water that flows in the narrow water channels 2307C of the aluminum water block 2307.

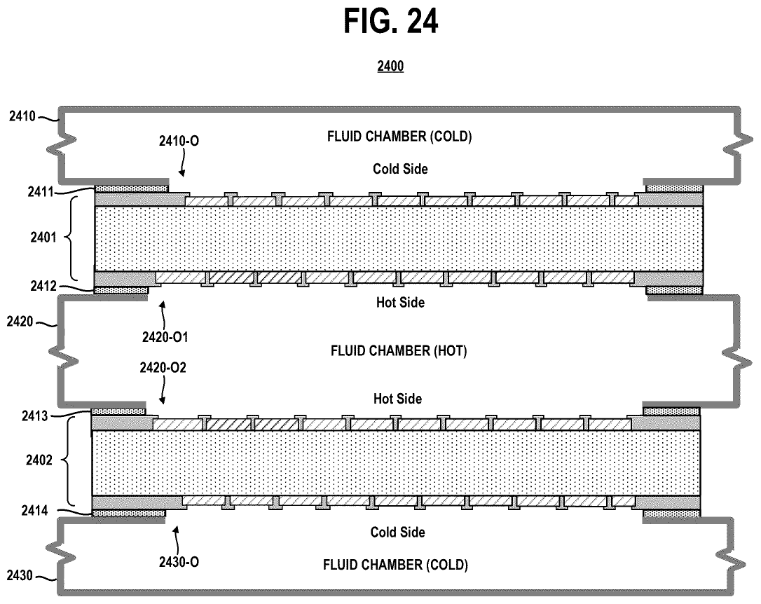

FIG. 24 schematically illustrates a thermoelectric system according to another exemplary embodiment of the disclosure, which is implemented by stacking a plurality of thermoelectric modules and thermal fluid chambers. In particular, FIG. 24 schematically illustrates a thermoelectric system 2400 which is implemented by stacking a plurality of thermoelectric modules (including a first thermoelectric module 2401 and a second thermoelectric module 2402), and a plurality of fluid chambers (including a first fluid chamber 2410, a second fluid chamber 2420, and a third fluid chamber 2430), in an alternating manner. In some embodiments, the first and second thermoelectric modules 2401 and 2402 are nominally identical thermoelectric modules, each comprising arrays of interconnect pads (for connecting thermoelectric pellets) that are externally disposed on the outer sides of the thermoelectric modules for direct contact with thermal transfer fluid flowing in the fluid chambers 2410, 2420, and 2430. In some embodiments, the first and second thermoelectric modules 2401 and 2402 can be implemented using any one of the exemplary thermoelectric module architectures as shown and discussed above, for example, in conjunction with FIGS. 16A, 17A-17F, 18, 19A, 19B, 19C, 20A, 20B, and 21A.

In some embodiments, as shown in FIG. 24, the first and third fluid chambers 2410 and 2430 are configured as cold fluid chambers that are part of the same closed loop system which circulates cooled thermal transfer fluid through the first and third fluid chambers 2410 and 2430, while the second fluid chamber 2420 is configured as a hot fluid chamber which is part of a closed loop system that circulates heated thermal transfer fluid. The first fluid chamber 2410 is bonded to a first surface of the first thermoelectric module 2401 via an adhesive layer 2411, with a first array of interconnect pads on a cold side of the first thermoelectric module 2401 exposed through an opening 2410-O in a surface of the first fluid chamber 2410. The second fluid chamber 2420 is bonded to a second surface of the first thermoelectric module 2401 via an adhesive layer 2412, with a second array of interconnect pads on a hot side of the first thermoelectric module 2401 exposed through a first opening 2420-O1 in a first surface of the second fluid chamber 2420. In addition, the second fluid chamber 2420 is bonded to a first surface of the second thermoelectric module 2402 via an adhesive layer 2413, with a first array of interconnect pads on a hot side of the second thermoelectric module 2402 exposed through a second opening 2420-O2 in a second surface of the second fluid chamber 2420. The third fluid chamber 2430 is bonded to a second surface of the second thermoelectric module 2402 via an adhesive layer 2414, with a second array of interconnect pads on a cold side of the second thermoelectric module 2402 exposed through an opening 2430-O in a surface of the third fluid chamber 2310.

Again, it is to be noted that while FIG. 24 schematically illustrates an exemplary architecture of a thermoelectric system which implements two thermoelectric modules in a stacked configuration with three fluid chambers, the number of thermoelectric modules (n) and fluid chambers (n+1) can be increased (e.g., n=10 or greater) to achieve even larger BTU outputs (e.g., 20K BTUs or more), as desired, to meet the requirements of different refrigeration systems or air conditioning systems that are used for larger homes or buildings. Indeed, by alternating the orientation of each consecutive thermoelectric module (hot/cold-cold/hot, etc.), the number of thermoelectric modules in the stacked configuration can be relatively large to achieve greater magnitudes of total BTU output with each added thermoelectric module, without diminishing returns.

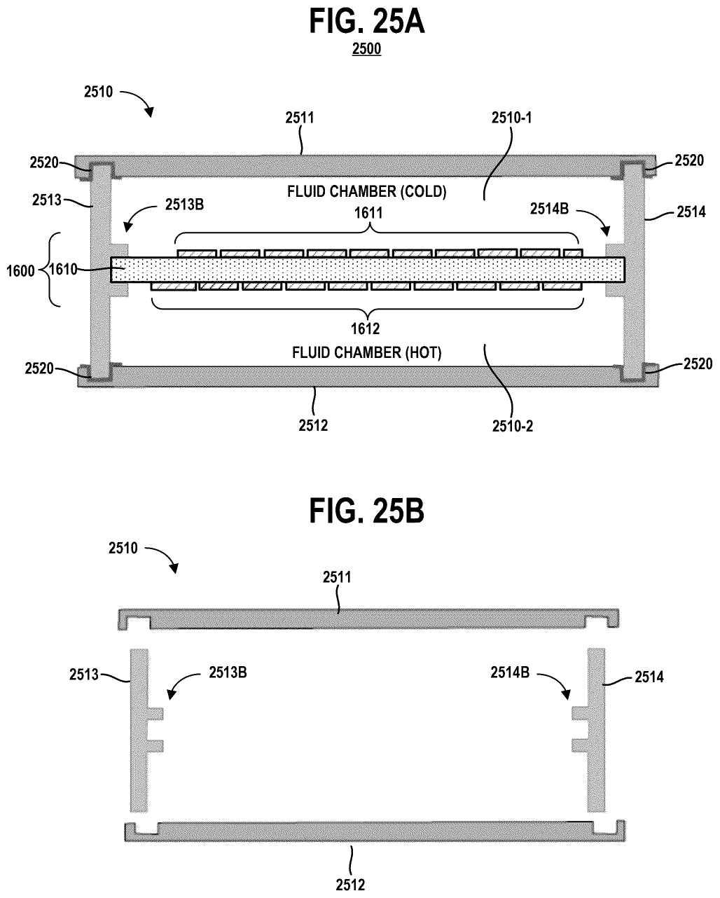

FIGS. 25A and 25B schematically illustrate a thermoelectric system, according to another exemplary embodiment of the disclosure. In particular, FIG. 25A schematically illustrates a thermoelectric system 2500 which comprises an assembly of the exemplary thermoelectric module 1600 of FIG. 16A and a fluid chamber assembly 2510 that is constructed using a plurality of modular components. FIG. 25B is an exploded view of various of modular components that are utilized to construct the fluid chamber assembly 2510. The modular components of the fluid chamber assembly 2510 comprises a first (top) side element 2511, a second (bottom) side element 2512, and a plurality of sidewall elements 2513 and 2514. The sidewall elements 2513 and 2514 comprises respective bracket elements 2513B and 2514B which are configured to insertably receive end portions of the support structure 1610 of the thermoelectric module 1600 and fixedly secure the support structure 1610 within the elements 2513B and 2514B using, e.g., the same RTV sealant that is used to seal the outer perimeter region of the support structure 1610 of the thermoelectric module 1600, as discussed above.

The thermoelectric system 2500 is assembled by bonding the various modular components together using an adhesive material 2520 (e.g., epoxy material). In the assembled configuration as schematically shown in FIG. 25A, the fluid chamber assembly 2510 comprises a first fluid chamber 2510-1 (e.g., cold) and a second fluid chamber 2510-2 (e.g., hot), wherein the first array of interconnect pads 1611 of the thermoelectric module 1600 is exposed to thermal transfer fluid that flows in the first fluid chamber 2510-1, and wherein the second array of interconnect pads 1612 of the thermoelectric module 1600 is exposed to thermal transfer fluid that flows in the second fluid chamber 2510-2. While not specifically shown in FIGS. 25A and 25B, the fluid chamber assembly 2510 further comprises modular input and output manifold covers that would, e.g., couple to the other sides of the thermoelectric module 1600 to complete the fluid chamber assembly 2510 with separate fluid chambers and respective input and output manifolds.

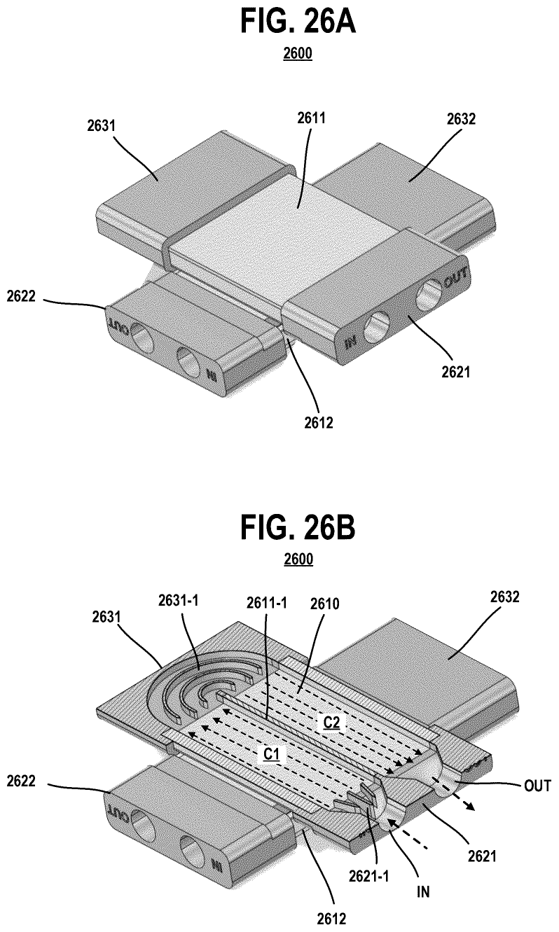

FIGS. 26A and 26B illustrate perspective views of a thermoelectric system, according to another exemplary embodiment of the disclosure. In particular, FIGS. 26A and 26B illustrate a thermoelectric system 2600 comprising a thermoelectric module 2610, a first fluid chamber 2611, a second fluid chamber 2612, a first fluid input/output manifold 2621, a second fluid input/output manifold 2622, a first reverse flow manifold 2631, and a second reverse flow manifold 2632. The thermoelectric module 2610 is disposed between the first fluid chamber 2611 and the second fluid chamber 2612, with first and second surfaces of the thermoelectric module 2610 exposed to, and in direct contact with, thermal transfer fluids that flow within the first and second fluid chambers 2611 and 2612.

FIG. 26B illustrates inner channel configurations of the first fluid chamber 2611, the first input/output manifold 2621, and the first reverse flow manifold 2631, according to an exemplary embodiment. The first fluid chamber 2611 comprises a central fin 2611-1 (or wall) which defines a two separate flow channels including a first flow channel C1 and a second flow channel C2. The first input/output manifold 2621 comprises an input port IN, and output port OUT, and a plurality of fluid dispersing fins 2621-1 disposed between the input port IN and the first flow channel C1. The first reverse flow manifold 2631 comprises a plurality of concentric semi-circular fins 2631-1. While not specifically shown, it is to be noted that the second fluid chamber 2612, the second input/output manifold 2622, and the second reverse flow manifold 2632, have the same inner channel configurations as the first fluid chamber 2611, the first input/output manifold 2621, and the first reverse flow manifold 2631, respectively. FIGS. 26A and 26B illustrate an exemplary packaging structure in which the first fluid chamber 2611 and the second fluid chamber 2622 are arranged in a 90-degree orientation in relation to each other such that the flow of thermal transfer fluid in the first fluid chamber 2611 is orthogonal to the flow of thermal transfer fluid in the second fluid chamber 2612.

It is to be noted that the thermoelectric module 2610 can be implemented using any of the exemplary thermoelectric module architectures as disclosed herein. For thermoelectric modules having arrays of interconnect pads disposed on the outer sides of the thermoelectric module in direct contact with heat transfer fluid, the arrays of interconnect pads can be designed to provide sufficient spacing to provide surface area for bonding the central fin 2611-1 element to the outer side of the thermoelectric module 2610.

As schematically illustrated in FIG. 26B, thermal transfer fluid enters the input port IN of the first input/output manifold 2621, and flows through a plurality of dispersing channels defined by the fluid dispersing fins 2621-1 such that the input fluid flow is evenly dispersed within the first fluid channel C1. The fluid flows to end of the first channel C1 wherein the fluid enters the reverse flow manifold 2631, and is circulated around channels defined by the semi-circular fins 2631-1, and then input to the second flow channel C2 where the fluid flows along the second flow channel C2 and is collected and output from the output port OUT. In this configuration, the fluid flow in the first and second channels C1 and C2 is parallel, but in opposite directions.

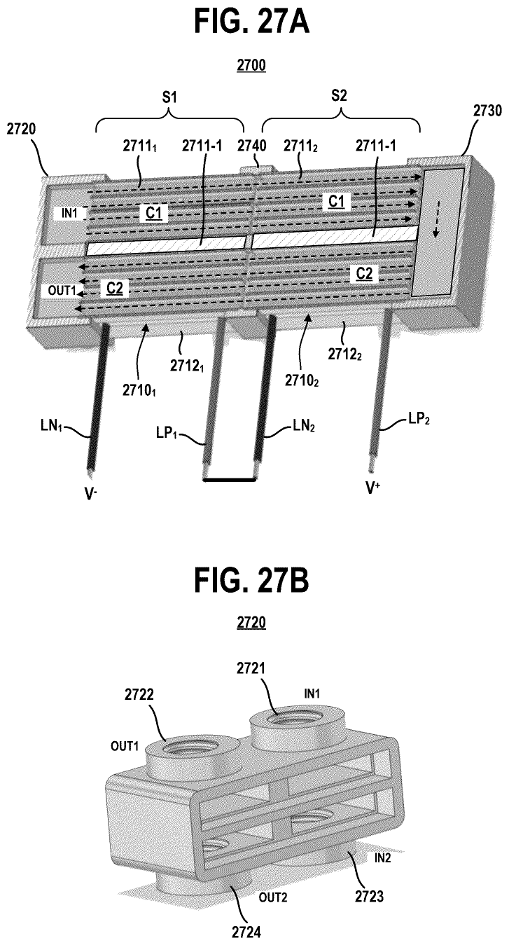

Next, FIGS. 27A and 27B illustrate perspective views of a thermoelectric system, according to another exemplary embodiment of the disclosure. In particular, FIG. 27A illustrates a thermoelectric system 2700 comprising a plurality of thermoelectric (TE) sections, including a first TE section S1, and a second TE section S2. The first TE section S1 comprises a first thermoelectric module 2710₁ disposed between a first fluid chamber 2711₁ and a second fluid chamber 2712₁. Similarly, the second TE section S2 comprises a second thermoelectric module 2710₂ disposed between a first fluid chamber 2711₂ and a second fluid chamber 2712₂. In some embodiments, the first and second TE sections S1 and S2 are nominally identical in architecture. The thermoelectric system 2700 further comprises a fluid input/output manifold 2720, a reverse flow manifold 2730, and a coupling manifold 2740.

FIG. 27A illustrates an exemplary embodiment in which the thermoelectric system 2700 comprises an array of thermoelectric modules (e.g., the first thermoelectric module 2710₁ and the second thermoelectric module 2710₂) which are electrically connected in series. In particular, the first thermoelectric module 2710₁ comprises a positive lead wire LP₁ and a negative lead wire LN₁, and an array of thermoelectric couples that are serially connected to and between the positive and negative lead wires LP₁ and LN₁. Similarly, the second thermoelectric module 2710₂ comprises a positive lead wire LP₂ and a negative lead wire LN₂, and an array of thermoelectric couples that are serially connected to and between the positive and negative lead wires LP₂ and LN₂. FIG. 27A illustrates an exemplary embodiment in which the first thermoelectric module 2710₁ and the second thermoelectric module 2710₂ are electrically connected in series by connecting the positive lead wire LP₁ of the first thermoelectric module 2710₁ to the negative lead wire LN₂ of the second thermoelectric module 2710₂. It is to be noted that the first and second thermoelectric modules 2710₁ and can be implemented using any of the exemplary thermoelectric module architectures as disclosed herein.

The coupling manifold 2740 is configured to (i) serially couple the first (upper) fluid chambers 2711₁ and 2711₂ and to (ii) serially couple the second (lower) fluid chambers 2712₁ and 2712₂. FIG. 27A illustrates inner channel configurations of the first fluid chambers 2711₁ and 2711₂, the input/output manifold 2720, and the reverse flow manifold 2730, according to an exemplary embodiment. The first fluid chambers 2711₁ and 2711₂ each comprise a central fin 2711-1 (or wall) which defines a two separate flow channels including a first flow channel C1 and a second flow channel C2. The first flow channels C1 in the first and second TE sections S1 and S2 are fluidly coupled to each other via the coupling manifold 2740, and the second flow channels C2 in the first and second TE sections S1 and S2 are fluidly coupled to each other via the coupling manifold 2740. Furthermore, in some embodiments, the first flow channel C1 and a second flow channel C2 each comprise a plurality of fins that define separate and parallel flow subchannels within the first and second flow channels C1 and C2, which serve to evenly disperse a heat transfer fluid that flows in the first fluid chambers 2711₁ and 2711₂ into a plurality of parallel streams. While not specifically shown, it is to be noted that the second fluid chambers 2712₁ and 2712₂ have the same inner channel configurations as the first fluid chambers 2711₁ and 2711₂.

As illustrated in FIGS. 27A and 27B, the input/output manifold 2720 comprises a first input port 2721 (IN1), a first output port 2722 (OUT1), a second input port 2723 (IN2), and a second output port 2724 (OUT2). In this exemplary configuration, thermal transfer fluid enters the first input port 2721 (IN1) and flows through the first flow channels C1 of the first (upper) fluid chambers 2711₁ and 2711₂ and then through an upper channel of the reverse flow manifold 2730, wherein the fluid flow is reversed and flows back through the second flow channels C2, and then output from the first output port 2722 (OUT1). In this configuration, the fluid flow in the first and second channels C1 and C2 of the first (upper) fluid chambers 2711₁ and 2711₂ is parallel, but in opposite directions. Similarly, thermal transfer fluid enters the second input port 2723 (IN2) and flows through first flow channels C1 of the second (lower) fluid chambers 2712₁ and 2712₂ and then through a lower channel of the reverse flow manifold 2730, wherein the fluid flow is reversed and flows back through second flow channels C2 of the second (lower) fluid chambers 2712₁ and 2712₂, and then output from the second output port 2724 (OUT2).

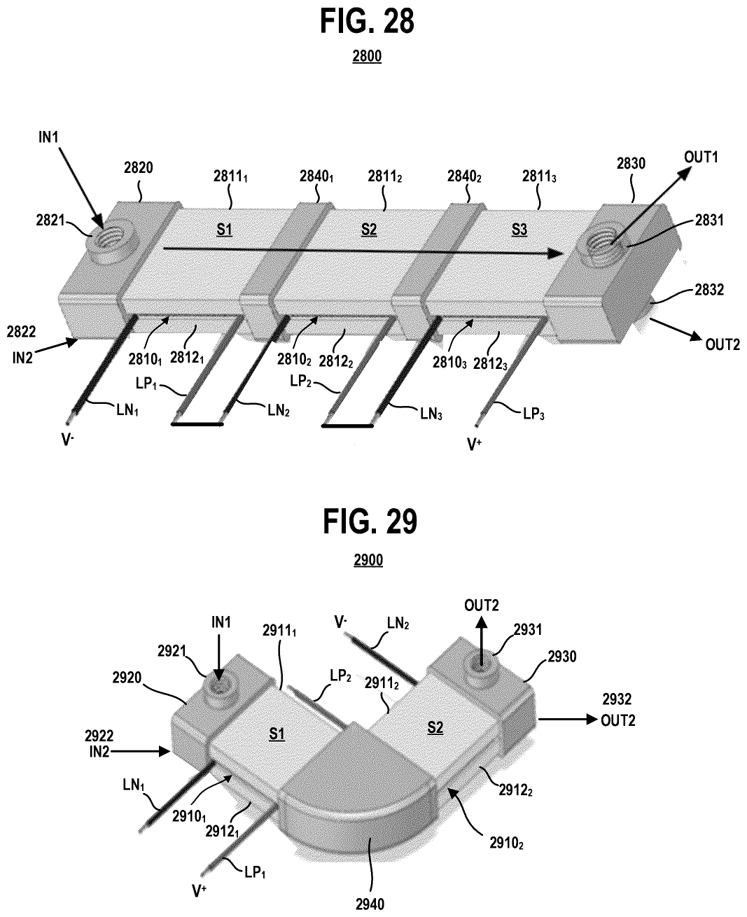

Next, FIG. 28 is a perspective view of a thermoelectric system, according to another exemplary embodiment of the disclosure. In particular, FIG. 28 illustrates a thermoelectric system 2800 comprising a first TE section S1, a second TE section S2, and a third TE section S3. The first TE section S1 comprises a first thermoelectric module 2810₁ disposed between first and second chambers 2811₁ and 2812₁. The second TE section S2 comprises a second thermoelectric module 2810₂ disposed between first and second fluid chambers 2811₂ and 2812₂. The third TE section S3 comprises a third thermoelectric module 2810₃ disposed between first and second fluid chambers 2811₃ and 2812₃. In some embodiments, the first, second, and third TE sections S1, S2, and S3 are nominally identical in architecture. The thermoelectric system 2800 further comprises a fluid input manifold 2820, a fluid output manifold 2830, a first coupling manifold 2840₁, and a second coupling manifold 2840₂.

The first thermoelectric module 2810₁ comprises a positive lead wire LP₁ and a negative lead wire LN₁, and an array of thermoelectric couples that are serially connected to and between the positive and negative lead wires LP₁ and LN₁. The second thermoelectric module 2810₂ comprises a positive lead wire LP₂ and a negative lead wire LN₂, and an array of thermoelectric couples that are serially connected to and between the positive and negative lead wires LP₂ and LN₂. The third thermoelectric module 2810₃ comprises a positive lead wire LP₃ and a negative lead wire LN₃, and an array of thermoelectric couples that are serially connected to and between the positive and negative lead wires LP₃ and LN₃. FIG. 28 illustrates an exemplary embodiment in which the first, second, and third thermoelectric modules 2810₁, 2810₂, and 2810₃ are electrically connected in series by connecting the positive lead wire LP₁ of the first thermoelectric module 2810₁ to the negative lead wire LN₂ of the second thermoelectric module 2810₂, and connecting the positive lead wire LP₂ of the second thermoelectric module 2810₂ to the negative lead wire LN₃ of the third thermoelectric module 2810₃. It is to be noted that the first, second, and third thermoelectric modules 2810₁, 2810₂, and 2810₃ can be implemented using any of the exemplary thermoelectric module architectures as disclosed herein.

The first and second coupling manifolds 2840₁ and 2840₂ are configured to (i) serially couple the first (upper) fluid chambers 2811₁, 2811₂, and 2811₃, and to (ii) serially couple the second (lower) fluid chambers 2812₁, 2812₂, and 2812₃, of the first, second and third TE sections S1, S2, and S3, of the thermoelectric system 2800. It is to be noted that the first (upper) fluid chambers 2811₁, 2811₂, and 2811₃, and the second (lower) fluid chambers 2812₁, 2812₂, and 2812₃, can be constructed to have single flow channels, or multiple parallel flow channel, or other configurations of flow channels as discussed above.

The input manifold 2820 comprises a first input port 2821 (IN1) and a second input port 2822 (IN2). The output manifold 2830 comprises a first output port 2831 (OUT1), and a second output port 2832 (OUT2). In this exemplary configuration, thermal transfer fluid enters the first input port 2821 (IN1) of the input manifold 2820, then flows through the first (upper) fluid chambers 2811₁, 2811₂, and 2811₃, and then is output from the first output port 2831 (OUT1) of the output manifold 2830. Similarly, thermal transfer fluid enters the second input port 2822 (IN2) of the input manifold 2820, then flows through the second (lower) fluid chambers 2812₁, 2812₂, and 2812₃, and then is output from the second output port 2832 (OUT2) of the output manifold 2830.

Next, FIG. 29 is a perspective view of a thermoelectric system, according to another exemplary embodiment of the disclosure. In particular, FIG. 29 illustrates a thermoelectric system 2900 comprising a first TE section S1, and a second TE section S2. The first TE section S1 comprises a first thermoelectric module 2910₁ disposed between first and second chambers 2911₁ and 2912₁. The second TE section S2 comprises a second thermoelectric module 2910₂ disposed between first and second fluid chambers 2911₂ and 2912₂. In some embodiments, the first and second TE sections S1 and S2 are nominally identical in architecture. The thermoelectric system 2900 further comprises a fluid input manifold 2920, a fluid output manifold 2930, and a 90-degree coupling manifold 2940.

The first thermoelectric module 2910₁ comprises a positive lead wire LP₁ and a negative lead wire LN₁, and an array of thermoelectric couples that are serially connected to and between the positive and negative lead wires LP₁ and LN₁. The second thermoelectric module 2910₂ comprises a positive lead wire LP₂ and a negative lead wire LN₂, and an array of thermoelectric couples that are serially connected to and between the positive and negative lead wires LP₂ and LN₂. The first and second thermoelectric modules 2910₁ and 2910₂ can be electrically connected in series by connecting the negative lead wire LN₁ of the first thermoelectric module 2910₁ to the positive lead wire LP₂ of the second thermoelectric module 2910₂. It is to be noted that the first and second thermoelectric modules 2910₁ and 2910₂ can be implemented using any of the exemplary thermoelectric module architectures as disclosed herein.

The 90-degree coupling manifold 2940 is configured to (i) serially couple the first (upper) fluid chambers 2911₁ and 2911₂, and to (ii) serially couple the second (lower) fluid chambers 2912₁ and 2912₂, of the first and second TE sections S1 and S2 of the thermoelectric system 2900. It is to be noted that the first (upper) fluid chambers 2911₁ and 2911₂, and the second (lower) fluid chambers 2912₁ and 2912₂ can be constructed to have single flow channels, or multiple parallel flow channel, or other configurations of flow channels as discussed above. The 90-degree coupling manifold 2940 facilitates the construction of a thermoelectric system with multiple TE sections coupled to together in different shapes and configurations to enable the installation of a thermoelectric system in various equipment enclosures and products.

The input manifold 2920 comprises a first input port 2921 (IN1) and a second input port 2922 (IN2). The output manifold 2930 comprises a first output port 2931 (OUT1), and a second output port 2932 (OUT2). The 90-degree coupling manifold 2940 comprises (i) a first (upper) flow channel which couples the first (upper) fluid chambers 2911₁ and 2911₂ of the first and second TE sections S1 and S2, and (ii) a second (lower) flow channel which couples the second (lower) fluid chambers 2912₁ and 2912₂ of the first and second TE sections S1 and S2. In this exemplary configuration, thermal transfer fluid enters the first input port 2921 (IN1) of the input manifold 2920, then flows through the first (upper) fluid chamber 2911₁, the first (upper) flow channel of the 90-degree coupling manifold 2490, and the first (upper) fluid chamber 2911₂, and then is output from the first output port 2931 (OUT1) of the output manifold 2930. Similarly, thermal transfer fluid enters the second input port 2922 (IN2) of the input manifold 2920, then flows through the second (lower) fluid chamber 2912₁, the second (lower) flow channel of the 90-degree coupling manifold 2490, and the second (lower) fluid chamber 2912₂, and then output from the second output port 2932 (OUT2) of the output manifold 2930.

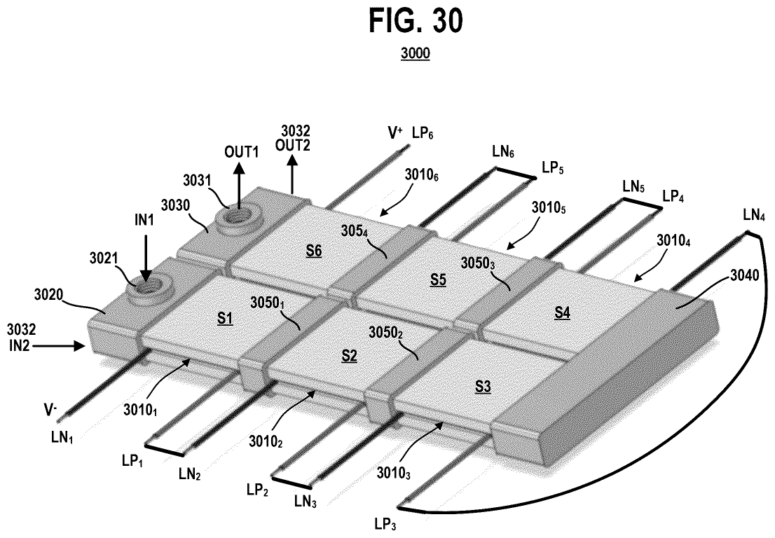

Next, FIG. 30 is a perspective view of a thermoelectric system, according to another exemplary embodiment of the disclosure. In particular, FIG. 30 illustrates a thermoelectric system 3000 comprising a first TE section S1, a second TE section S2, a third TE section S3, a fourth TE section S4, a fifth TE section S5, and a sixth TE section S6. Similar to the exemplary embodiments shown in FIGS. 27A, 28, and 29, each TE section S1, S2, S3, S4, S5, and S6 comprises a respective thermoelectric module 3010₁, 3010₂, 3010₃, 3010₄, 3010₅, and 3010₆, which is disposed between first and second fluid chambers (not specifically labeled in FIG. 30). In some embodiments, the TE sections S1-S6 are nominally identical in architecture. The thermoelectric system 3000 further comprises a fluid input manifold 3020, a fluid output manifold 3030, a reverse flow manifold 3040, and a plurality of coupling manifolds 3050₁, 3050₂, 3050₃, and 3050₄.

FIG. 30 illustrates an exemplary embodiment in which the thermoelectric system 3000 comprises a serial array of thermoelectric modules. In particular, the thermoelectric modules 3010₁, 3010₂, 3010₃, 3010₄, 3010₅, and 3010₆ comprise respective positive lead wires LP₁, LP₂, LP₃, LP₄, LP₅, and LP₆, and respective negative lead wires LN₁, LN₂, LN₃, LN₄, LN₅, and LN₆, which can be connected as shown in FIG. 30 to electrically connect the thermoelectric modules 3010₁, 3010₂, 3010₃, 3010₄, 3010₅, and 3010₆ in series with, e.g., an operating voltage applied across LP₆ and LN₁.

As with the exemplary embodiments discussed above, the coupling manifolds 3050₁, 3050₂, 3050₃, and 3050₄ and the reverse flow manifold 3040 are configured to (i) serially couple the first (upper) fluid chambers of the TE sections S1-S6 to provide fluid flow path from a first input port 3021 (IN1) of the input manifold 3020 to a first output port 3031 (OUT1) of the output manifold 3030, and to (ii) serially couple the second (lower) fluid chambers of the TE sections S1-S6 to provide fluid flow path from a second input port 3032 (IN2) of the input manifold 3020 to a second output port 3032 (OUT2) of the output manifold 3030. FIG. 30 illustrates an exemplary embodiment in which the TE sections S1-S6 are fluidly coupled in series, but where the TE sections S1-S3 collectively provide a first linear TE section of the thermoelectric system 3000, and the TE sections S4-S6 collectively provide a second linear TE section of the thermoelectric system 3000, wherein the first linear TE section (S1-S3) and the second linear TE section (S4-S6) are disposed adjacent and parallel to each other, to provide a more compact arrangement of the TE sections S1-S6. In this configuration, the reverse flow manifold 3040 serves as a coupling manifold to couple the first linear TE section (S1-S3) and the second linear TE section (S4-S6) and to direct the fluid flow from the first linear TE section (S1-S3) to the second linear TE section (S4-S6).

It is to be noted that FIGS. 27A, 27B, 28, 29, and 30 illustrate exemplary embodiments of thermoelectric systems which can be implemented using modular components to construct a thermoelectric system comprising any desired arrangement, configuration, and number of TE sections(S) of thermoelectric modules. In particular, the TE sections can be modular components, which are designed to have a nominally identical architecture comprising a thermoelectric module disposed between upper and lower fluid chambers. In addition, the fluid input and output manifolds, the reverse flow manifolds, and the coupling manifolds as shown in FIGS. 27A, 27B, 28, 29, and 30 can be modular components that are configured to interface with the upper and lower fluid chambers of the modular TE sections. The component modularity allows a desired thermoelectric system (planar configuration) to be constructed for a given application. The exemplary planar configurations and arrangements of modular components of the thermoelectric systems as shown in FIGS. 27A, 27B, 28, 29, and 30 (as compared to stacked thermoelectric systems) can be particularly useful for applications with limited space, e.g., incorporating planar thermoelectric systems in dashboards of a motor vehicle to implement an AC system for the motor vehicle, etc.

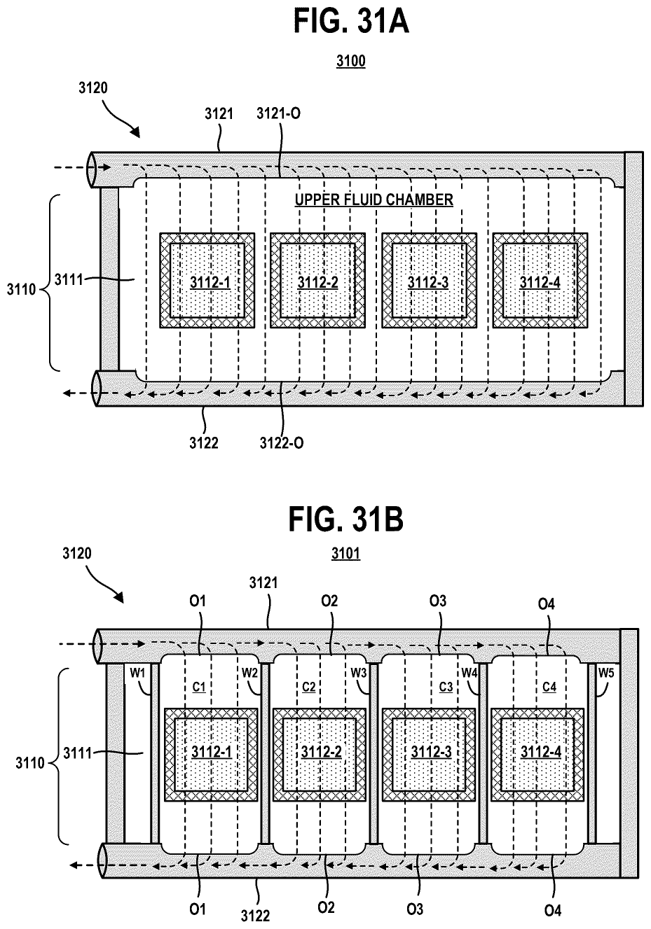

Next, FIG. 31A schematically illustrates a thermoelectric system, according to another exemplary embodiment of the disclosure. In particular, FIG. 31A is a schematic plan view of a thermoelectric system 3100 which comprises a thermoelectric module 3110, a first (upper) fluid chamber 3120, a second (lower) fluid chamber (not specifically illustrated), a fluid input manifold 3121, and a fluid output manifold 3122. FIG. 31A illustrates an exemplary embodiment of the thermoelectric module 3110 having an architecture that is based at least in part on the architecture of thermoelectric module 500 of FIG. 5A. The thermoelectric module 3110 comprises a first polymer substrate 3111 (e.g., first FR4 printed circuit board), and a second polymer substrate (not specifically shown), and a plurality of thermoelectric devices 3112-1, 3112-2, 3112-3, and 3112-4 which are arranged in series, and each having a first (upper) ceramic substrate exposed within the first (upper) fluid chamber 3120 through sealed cutouts in the first polymer substrate 3111, as well as a second (lower) ceramic substrate exposed within the second (lower) fluid chamber through sealed cutouts in the second polymer substrate (e.g., second FR4 printed circuit board).

FIG. 31A schematically illustrates an exemplary embodiment in which the fluid input manifold 3121, and the fluid output manifold 3122 of the first (upper) fluid chamber 3120 extend in the direction that is parallel with the direction of the series arrangement of the thermoelectric devices 3112-1, 3112-2, 3112-3, and 3112-4. The input manifold 3121 comprises an opening 3121-0 which is configured to supply heat transfer fluid from the input manifold 3121 into the upper fluid chamber 3120 to each of the thermoelectric device 3112-1, 3112-2, 3112-3, and 3112-4, in parallel. The output manifold 3122 comprises an opening 3122-0 which is configured to receive the heat transfer fluid which flows through the upper fluid chamber 3120, and output the heat transfer fluid from the upper fluid chamber 3120. In this configuration, the supply of heat transfer fluid in parallel, to each individual thermoelectric device 3112-1, 3112-2, 3112-3, and 3112-4 results in a more optimal and equal Δt for each individual thermoelectric device 3112-1, 3112-2, 3112-3, and 3112-4. This is in contrast to a configuration in which the thermal fluid flows in the same direction (e.g., left to right) as the series arrangement of the thermoelectric devices 3112-1, 3112-2, 3112-3, and 3112-4, where the Δt from the first thermoelectric device 3112-1 would change the temperature of the thermal fluid and each consecutive thermoelectric device would not get the full benefit of the initial fluid temperature with the maximum Δt. Such configuration could reduce the efficiency and overall BTU output.

FIG. 31B schematically illustrates a thermoelectric system, according to another exemplary embodiment of the disclosure. In particular, FIG. 31B is a schematic plan view of a thermoelectric system 3101 which is similar to the thermoelectric system 3100 of FIG. 31A, but with a slightly modified architecture of the fluid input manifold 3121, the fluid output manifold 3122, the first (upper) fluid chamber 3120, and the second (lower) fluid chamber (not specifically illustrated). For example, similar to the thermoelectric system 3100 FIG. 31A, the fluid input manifold 3121, and the fluid output manifold 3122 of the first (upper) fluid chamber 3120 extend in the direction that is parallel with the direction of the series arrangement of the thermoelectric devices 3112-1, 3112-2, 3112-3, and 3112-4. However, the input manifold 3121 and the output manifold 3122 each comprise a plurality of corresponding openings O1, O2, O3, and O4, and a plurality of separate fluid chambers C1, C2, C3, and C4 (defined by chamber walls W1, W2, W3, W4, and W5), which are configured to evenly disperse a heat transfer fluid that flows into the first (upper) fluid chamber 3120 into a plurality of parallel streams.

In particular, as schematically illustrated in FIG. 31B, the corresponding openings O1 of the input and output manifolds 3121 and 3122 allow heat transfer fluid to flow through the first fluid chamber C1 of the first (upper) fluid chamber 3120. The corresponding openings O2 of the input and output manifolds 3121 and 3122 allow heat transfer fluid to flow through the second fluid chamber C2 of the first (upper) fluid chamber 3120. The corresponding openings O3 of the input and output manifolds 3121 and 3122 allow heat transfer fluid to flow through the third fluid chamber C3 of the first (upper) fluid chamber 3120. The corresponding openings O4 of the input and output manifolds 3121 and 3122 allow heat transfer fluid to flow through the fourth fluid chamber C4 of the first (upper) fluid chamber 3120. While not specifically shown, the second (lower) fluid chamber and corresponding input and output manifolds would have the same configuration as the first (upper) fluid chamber 3120, to provide hot and cold fluid chambers. Again, the exemplary fluid chamber configuration shown in FIG. 31B is designed to allow heat transfer fluid to flow equally, and in parallel, to each individual thermoelectric device 3112-1, 3112-2, 3112-3, and 3112-4 such that each thermoelectric device 3112-1, 3112-2, 3112-3, and 3112-4 receives the same or substantially the same input fluid temperature and flow to allow equal thermal transfer from each thermoelectric device 3112-1, 3112-2, 3112-3, and 3112-4.

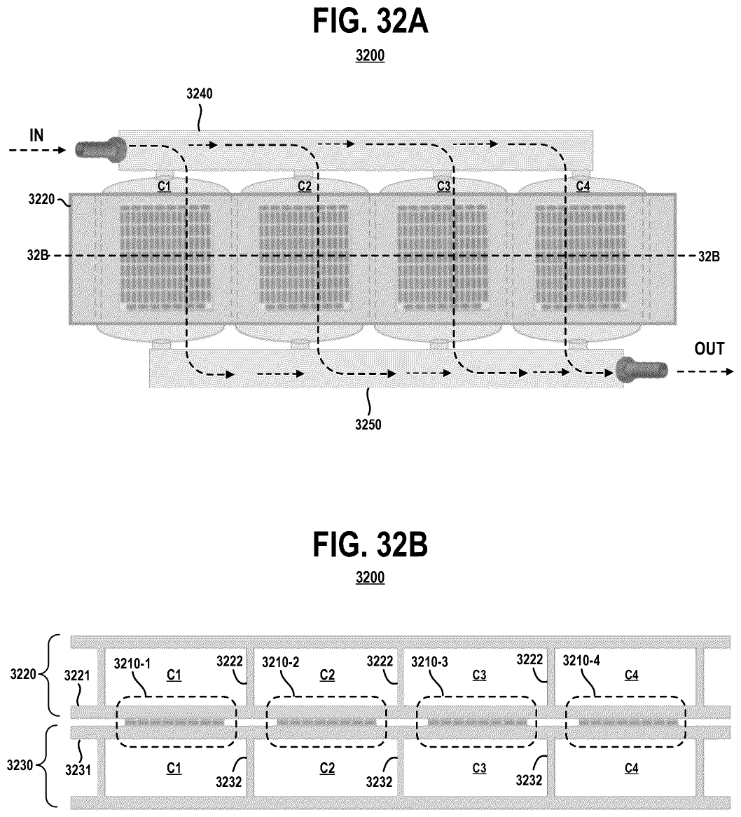

FIGS. 32A and 32B schematically illustrate a thermoelectric system, according to another exemplary embodiment of the disclosure. In particular, FIG. 32A is a schematic plan view of a thermoelectric system 3200, and FIG. 32B is a schematic cross-sectional side view of the thermoelectric system 3200 along line 32B-32B in FIG. 32A. The thermoelectric module 3200 comprises a plurality of thermoelectric devices 3210-1, 3210-2, 3210-3, and 3210-4, a first (upper) fluid chamber 3220, a second (lower) fluid chamber 3230, an input manifold 3240, and an output manifold 3250. The input manifold 3240 and the output manifold 3250 are coupled to the first (upper) fluid chamber 3220. While not specifically shown, the thermoelectric system 3200 further comprises a second input manifold and second output manifold which are coupled to the second (lower) fluid chamber 3230.

The thermoelectric devices 3210-1, 3210-2, 3210-3, and 3210-4 are disposed between the first and second fluid chambers 32320 and 3230. In some embodiments, the thermoelectric devices 3210-1, 3210-2, 3210-3, and 3210-4 have an architecture that is based at least in part on the architecture of thermoelectric devices as shown and discussed above, for example, in conjunction with FIG. 9A-9B, 10A, 10B, 11A, 11B, or 12A, and 12B. For example, each thermoelectric device 3210-1, 3210-2, 3210-3, and 3210-4 comprises an array of thermoelectric semiconductor pellets disposed, between a first side 3221 of the first fluid chamber 3220, and a second side 3231 of the second fluid chamber 3230, as well as a first array of interconnect pads disposed on an outer surface of the first side 3221 of the first fluid chamber 3220, and a second array of interconnect pads disposed on an outer surface of the second side 3231 of the second fluid chamber 3230. The thermoelectric devices 3210-1, 3210-2, 3210-3, and 3210-4 can be electrically connected in series by conductive traces that are formed on the outer surface of the first side 3221 of the first fluid chamber 3220 and/or the outer surface of the second side 3231 of the second fluid chamber 3320.

Moreover, as schematically illustrated in FIGS. 32A and 32B, the first fluid chamber 3220 comprises a plurality of separate fluid chambers C1, C2, C3, and C4 defined by inner chamber walls 3222 and, similarly, the second fluid chamber 3230 comprises a plurality of separate fluid chambers C1, C2, C3, and C4 defined by inner chamber walls 3232. The first and second fluid chambers 3220 and 3230 are nominally identical in architecture such that the fluid chambers C1, C2, C3, and C4 of the first fluid chamber 3220 are aligned with the fluid chambers C1, C2, C3, and C4 of the second fluid chamber 3230. Moreover, the thermoelectric devices 3210-1, 3210-2, 3210-3, and 3210-4 are aligned with the fluid chambers C1, C2, C3, and C4, respectively, of the respective first and second fluid chambers 3220 and 3230.

The fluid input manifold 3240 and the fluid output manifold 3250 are coupled to the first (upper) fluid chamber 3220, and extend in a direction that is parallel with the direction of the series arrangement of the thermoelectric devices 3210-1, 3210-2, 3210-3, and 3210-4. The input manifold 3240 comprises a plurality of fluid supply ports which are coupled to the separate fluid chambers C1, C2, C3, and C4, and configured to supply heat transfer fluid from the input manifold 3240 into each of the separate fluid chambers C1, C2, C3, and C4 of the first (upper) fluid chamber 3220 equally, and in parallel. The output manifold 3250 comprises a plurality of fluid output ports which are coupled to the separate fluid chambers C1, C2, C3, and C4, and configured to receive the heat transfer fluid which flows through and out from the separate fluid chambers C1, C2, C3, and C4 of the first (upper) fluid chamber 3220. While not specifically shown, the input and output manifolds coupled to the second (lower) fluid chamber 3230 would have the same configuration of fluid supply ports and fluid output ports coupled to respective ones of the separate fluid chambers C1, C2, C3, and C4 of the second (lower) fluid chamber 3230. Similar to the exemplary embodiments discussed above for FIGS. 31A and 31B, the exemplary parallel flow configuration shown in FIGS. 32A and 32B is designed to supply heat transfer fluid equally, and in parallel, to each of the thermoelectric devices 3210-1, 3210-2, 3210-3, and 3210-4 to achieve an optimal and equal Δt for each individual thermoelectric device 3210-1, 3210-2, 3210-3, and 3210-4.

FIG. 33A schematically illustrates a thermoelectric heating and cooling system, according to an exemplary embodiment of the disclosure. In particular, FIG. 33A schematically illustrates a thermoelectric heating and cooling system 3300 which comprises a thermoelectric system 3310. The thermoelectric system 3310 comprises a plurality of individual thermoelectric systems including a first thermoelectric system 3310-1 and a second thermoelectric system 3310-2. In some embodiments, the first and second thermoelectric systems 3310-1 and 3310-2 are nominally identical in architecture and include a first fluid chamber 3320 (e.g., hot chamber), a second fluid chamber 3330 (e.g., cold chamber), and a thermoelectric module 3340 disposed between the first and second fluid chambers 3320 and 3330. It is to be noted that the first and second thermoelectric systems 3310-1 and 3310-2 are generically illustrated in FIG. 33A and can be implemented using any of the exemplary thermoelectric system architectures as disclosed herein.

The thermoelectric heating and cooling system 3300 further comprises a first input distribution manifold 3350, a first output collection manifold 3351, a second input distribution manifold 3360, a second output collection manifold 3360, a first pump 3370, a second pump 3371, a first fan and coil unit 3380, and a second fan and coil unit 3381. The thermoelectric heating and cooling system 3300 comprises a first closed loop system to circulate a thermal transfer fluid which flows in the first fluid chambers 3320, wherein the first closed loop system comprises the first fluid chambers 3320, the first input distribution manifold 3350, the first output collection manifold 3351, the first pump 3370, and a first coil assembly of the first fan and coil unit 3380. The thermoelectric heating and cooling system 3300 comprises a second closed loop system to circulate a thermal transfer fluid which flows in the second fluid chambers 3330, wherein the second closed loop system comprises the second fluid chambers 3330, the second input distribution manifold 3360, the second output collection manifold 3361, the second pump 3371, and a second coil assembly of the second fan and coil unit 3381. In an exemplary embodiment, the first fan and coil unit 3380 is configured to blow air through a coil into an external environment, while the second fan and coil unit 3381 is configured to blow cooled air or heated air into an internal environment which is temperature-regulated by operation of the thermoelectric heating and cooling system 3300, depending on the mode of operation (e.g., cooling mode or heating mode) of the thermoelectric heating and cooling system 3300.

For example, in an exemplary cooling mode of operation of the thermoelectric heating and cooling system 3300, the thermoelectric modules 3340 of the thermoelectric system 3310 are operated with a proper voltage bias such that (i) the hot sides of the thermoelectric modules 3340 thermally interface with the first fluid chambers 3320, and (ii) the cold sides of the thermoelectric modules 3340 thermally interface with the second fluid chambers 3330. In the cooling mode of operation, the first pump 3370 operates to pump thermal transfer fluid in the first closed loop system, which flows through the first fluid chambers 3320 of the first and second thermoelectric systems 3310-1 and 3310-2, where the thermal transfer fluid absorbs heat from the thermoelectric modules 3340. The heated thermal transfer fluid, which flows out from the first fluid chambers 3320, is pumped through the coil assembly of the first fan and coil unit 3380, where the fan pushes (or pulls) external air through the coil to cause thermal energy (heat) to be transferred from the heated thermal transfer fluid to the external environment (and thereby cool down the heated thermal transfer fluid).

Moreover, in the cooling mode of operation, the second pump 3371 operates to pump thermal transfer fluid in the second closed loop system, which flows through the second fluid chambers 3330 of the first and second thermoelectric systems 3310-1 and 3310-2, where heat is absorbed from the thermal transfer fluid (i.e., the thermal transfer fluid is cooled) by the thermoelectric modules 3340. The cooled thermal transfer fluid, which flows out from the second fluid chambers 3330, is pumped through the coil assembly of the second fan and coil unit 3381, where the fan pushes (or pulls) internal air (return air from the temperature-regulated internal environment) over the coil to cool down the internal air as it passes over the coil, where the cooled air is circulated back into the temperature-regulated internal environment. Although not specifically shown in FIG. 33A, the air flow generated by operation of the second fan and coil unit 3381 is blown into a supply plenum, which connects to one or more air ducts which distribute the cooled air into the temperature-regulated internal environment.

On the other hand, in an exemplary heating mode of operation of the thermoelectric heating and cooling system 3300, the thermoelectric modules 3340 of the thermoelectric system 3310 are operated with a proper voltage bias such that (i) the cold sides of the thermoelectric modules 3340 thermally interface with the first fluid chambers 3320, and (ii) the hot sides of the thermoelectric modules 3340 thermally interface with the second fluid chambers 3330. In the heating mode of operation, the first pump 3370 operates to pump thermal transfer fluid in the first closed loop system, which flows through the first fluid chambers 3320 of the first and second thermoelectric systems 3310-1 and 3310-2, where the thermal transfer fluid is cooled by the thermoelectric modules 3340. The cooled thermal transfer fluid, which flows out from the first fluid chambers 3320, is pumped through the coil assembly of the first fan and coil unit 3380, where the fan pushes (or pulls) external air over the coil to cause thermal energy (heat) to be transferred from the external environment to the cooled thermal transfer fluid and, thereby increase the temperature of the cooled thermal transfer fluid.

In instances where the external air is higher in temperature than the cooled thermal transfer fluid flowing through the coil assembly of the first fan and coil unit 3380, the cooled thermal transfer fluid will increase in temperature. However, in instances where the external air is lower in temperature than the cooled thermal transfer fluid flowing through the coil assembly of the first fan and coil unit 3380, an auxiliary heating system (e.g., electrical heating coil) of the first fan and coil unit 3380 can be activated to cause warmer air to be pushed (or pulled) over the coil assembly to increase the temperature of the cooled thermal transfer fluid before it flows back to the first fluid chambers 3320.

Moreover, in the heating mode of operation, the second pump 3371 operates to pump thermal transfer fluid in the second closed loop system, which flows through the second fluid chambers 3330 of the first and second thermoelectric systems 3310-1 and 3310-2, where the thermal transfer fluid absorbs heat (i.e., the thermal transfer fluid is heated) by the hot sides of the thermoelectric modules 3340. The heated thermal transfer fluid, which flows out from the second fluid chambers 3330, is pumped through the coil assembly of the second fan and coil unit 3381, where the fan pushes (or pulls) internal air (return air from the temperature-regulated internal environment) over the coil to heat up the internal air as is passes over the coil, which heated air is circulated back into the temperature-regulated internal environment.

Next, FIG. 33B schematically illustrates a thermoelectric heating and cooling system, according to another exemplary embodiment of the disclosure. In particular, FIG. 33B schematically illustrates a thermoelectric heating and cooling system 3301 which is similar to the thermoelectric heating and cooling system 3300 of FIG. 33A, except that the thermoelectric heating and cooling system 3301 comprises a thermoelectric system 3311 which comprises a stacked configuration of a plurality thermal fluid chambers 3321, 3322, 3323, 3324, and 3325, and a plurality of thermoelectric modules 3341, 3342, 3343, and 3344. The thermoelectric module 3341 is disposed between the thermal fluid chambers 3321 and 3322. The thermoelectric module 3342 is disposed between the thermal fluid chambers 3322 and 3323. The thermoelectric module 3343 is disposed between the thermal fluid chambers 3323 and 3324. The thermoelectric module 3344 is disposed between the thermal fluid chambers 3324 and 3325. The exemplary thermoelectric heating and cooling system 3301 can be configured to operate in a cooling mode or heating mode in the same manner as discussed above in conjunction with FIG. 33A.

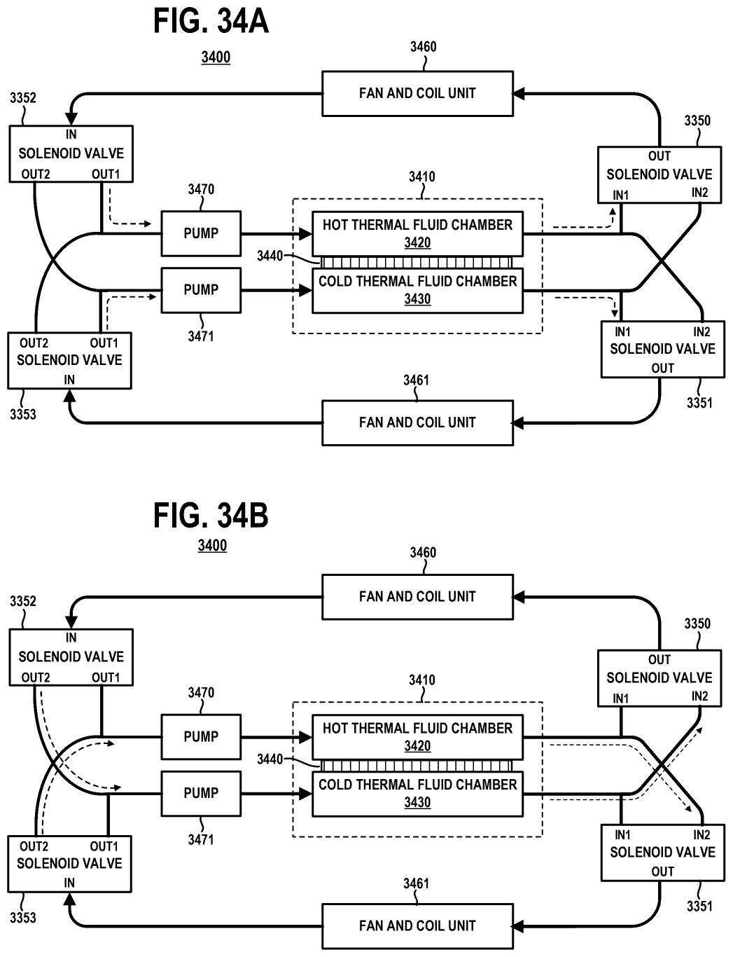

FIGS. 34A and 34B schematically illustrate a thermoelectric heating and cooling system, according to another exemplary embodiment of the disclosure. In particular, FIG. 34A schematically illustrates an exemplary configuration of a thermoelectric heating and cooling system 3400 to operate in a first mode (e.g., cooling mode), and FIG. 34B schematically illustrates an exemplary configuration of the thermoelectric heating and cooling system 3400 to operate in a second mode (e.g., heating mode). As explained in detail below, the thermoelectric heating and cooling system 3400 is configured to switch between cooling and heating operating modes by changing the flow of cooled and heated thermal transfer fluids through different coil and fan units, as compared to other exemplary embodiments of thermoelectric heating and cooling systems as discussed herein where switching between cooling and heating operating modes is achieved by changing the polarity of the DC voltage applied to thermoelectric modules to switch the hot and cold sides of the thermoelectric modules.

The thermoelectric heating and cooling system 3400 comprises a thermoelectric system 3410. For case of illustration, the thermoelectric system 3410 is depicted as comprising a first (hot) thermal fluid chamber 3420, a second (cold) thermal fluid chamber 3420, and a thermoelectric module 3440 disposed between the first and second fluid chambers 3420 and 3430. It is to be noted, however, that the thermoelectric system 3410 can be implemented using any of the exemplary thermoelectric system architectures as disclosed herein. The thermoelectric heating and cooling system 3400 further comprises a first solenoid valve 3350, a second solenoid valve 3351, a third solenoid valve 3352, a fourth solenoid valve 3353, a first fan and coil unit 3460, a second fan and coil unit 3461, a first pump 3470, and a second pump 3371.

The first solenoid valve 3350 comprises a first input port IN1 that is coupled (via piping) to an output port of the first (hot) thermal fluid chamber 3420, a second input port IN2 that is coupled (via piping) to an output port of the second (cold) thermal fluid chamber 3430, and an output port OUT that is coupled (via piping) to an input of a coil assembly of the first fan and coil unit 3460. The second solenoid valve 3351 comprises a first input port IN1 that is coupled (via piping) to an output port of the second (cold) thermal fluid chamber 3430, a second input port IN2 that is coupled (via piping) to an output port of the first (hot) thermal fluid chamber 3420, and an output port OUT that is coupled (via piping) to an input of a coil assembly of the second fan and coil unit 3461. The third solenoid valve 3352 comprises an input port IN that is coupled (via piping) to an output of the coil assembly of the first fan and coil unit 3460, a first output port OUT1 that is coupled (via piping) to an input port of the first pump 3470, and a second output port OUT2 that is coupled (via piping) to an input port of the second pump 3471. The fourth solenoid valve 3353 comprises an input port IN that is coupled (via piping) to an output of the coil assembly of the second fan and coil unit 3461, a first output port OUT1 that is coupled (via piping) to the input port of the second pump 3471, and a second output port OUT2 that is coupled (via piping) to the input port of the first pump 3470.

In an exemplary embodiment, the first fan and coil unit 3460 is configured to blow external ambient air through the coil assembly of the first fan and coil unit 3460, while the second fan and coil unit 3461 is configured to blow cooled air or heated air into an internal environment which is temperature-regulated by operation of the thermoelectric heating and cooling system 3400, depending on the mode of operation (e.g., cooling mode or heating mode) of the thermoelectric heating and cooling system 3400. The external ambient air can be any source of air which is external to the internal environment that is temperature-regulated by operation of the thermoelectric heating and cooling system 3400. In both operating modes (heating and cooling), the thermoelectric module 3440 is operated with a same control voltage polarity such that a hot side of the thermoelectric module 3440 is in contact with thermal transfer fluid in the first (hot) thermal fluid chamber 3420, and a cold side of the thermoelectric module 3440 is in contact with thermal transfer fluid in the second (cold) thermal fluid chamber 3430. The switching between the cooling and heating operating modes the thermoelectric heating and cooling system 3400 is achieved by operatively configuring the four solenoid valves 3350-3353 to change the flow of heated and cooled thermal fluids through the first and second fan and coil units 3460 and 3461.

In particular, FIG. 34A schematically illustrates an exemplary cooling mode of operation of the thermoelectric heating and cooling system 3400 based on a first configuration of the four solenoid valves 3350, 3351, 3352, and 3353. In particular, as shown in FIG. 34A, the first and second solenoid valves 3350 and 3351 are operatively configured to connect the respective first input ports IN1 to the respective output ports OUT, and the third and fourth solenoid valves 3352 and 3353 are operatively configured to connect the respective input ports IN1 to the respective first output ports OUT1. In this configuration, the thermoelectric heating and cooling 3400 comprises (i) a first closed loop system which comprises the first (hot) thermal fluid chamber 3420, the first and third solenoid valves 3350 and 3352, the coil assembly of the first fan and coil unit 3460, and the first pump 3470, wherein the first pump 3470 circulates hot thermal transfer in the first closed loop which flows through the first fan and coil unit 3460, and (ii) a second closed loop system which comprises the second (cold) thermal fluid chamber 3430, the second and fourth solenoid valves 3351 and 3353, the coil assembly of the second fan and coil unit 3461, and the second pump 3471, wherein the second pump 3471 circulates cold thermal transfer in the second closed loop which flows through the second fan and coil unit 3461, to generate cooled air which is supplied into the temperature-regulated environment.

On the other hand, FIG. 34B schematically illustrates an exemplary heating mode of operation of the thermoelectric heating and cooling system 3400 based on a second configuration of the four solenoid valves 3350, 3351, 3352, and 3353. In particular, as shown in FIG. 34B, the first and second solenoid valves 3350 and 3351 are operatively configured to connect the respective second input ports IN2 to the respective output ports OUT, and the third and fourth solenoid valves 3352 and 3353 are operatively configured to connect the respective input ports IN1 to the respective second output ports OUT2. In this configuration, the thermoelectric heating and cooling 3400 comprises (i) a first closed loop system which comprises the second (cold) thermal fluid chamber 3430, the first and third solenoid valves 3350 and 3352, the coil assembly of the first fan and coil unit 3460, and the first pump 3470, wherein the first pump 3470 circulates cold thermal transfer in the first closed loop which flows through the first fan and coil unit 3460, and (ii) a second closed loop system which comprises the first (hot) thermal fluid chamber 3420, the second and fourth solenoid valves 3351 and 3353, the coil assembly of the second fan and coil unit 3461, and the second pump 3471, wherein the second pump 3471 circulates hot thermal transfer in the second closed loop which flows through the second fan and coil unit 3461, to generate heated air which is supplied into the temperature-regulated environment.

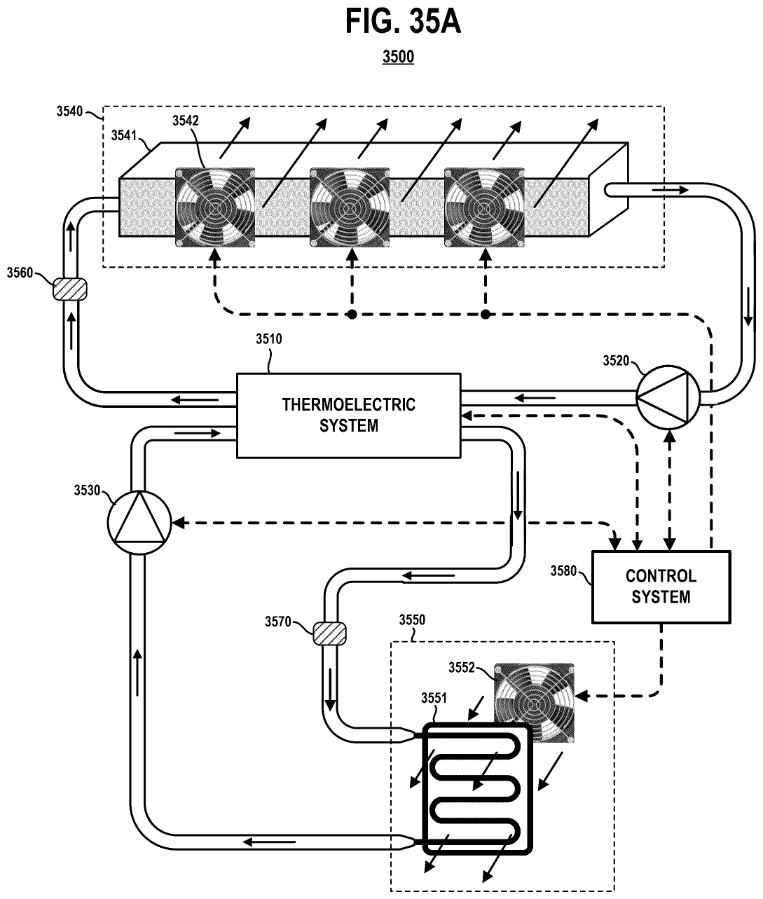

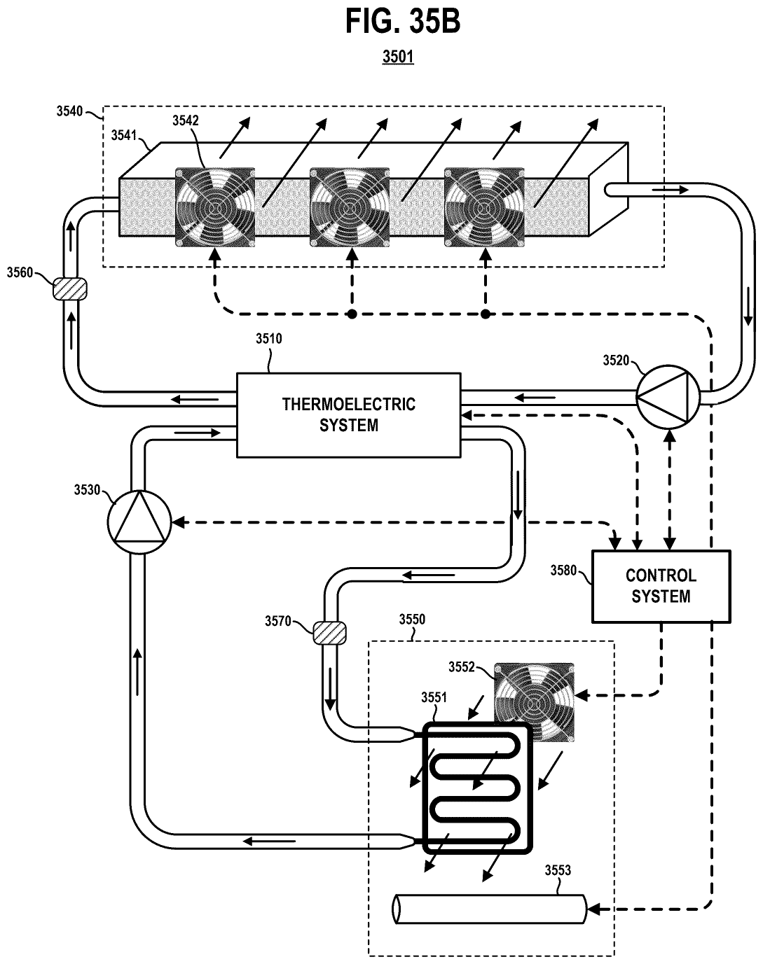

FIG. 35A schematically illustrates a thermoelectric heating and cooling system, according to another exemplary embodiment of the disclosure. In particular, FIG. 35B schematically illustrates a thermoelectric heating and cooling system 3500 which can be implemented in a residential or commercial building. The thermoelectric heating and cooling system 3500 comprises a thermoelectric system 3510, a first pump 3520, a second pump 3530, a first fan and coil unit 3540, a second fan and coil unit 3550, first and second thermal fluid fill ports 3560 and 3560, and a control system 3580. The thermoelectric system 3510 can be implemented using any of the exemplary thermoelectric system configurations as described herein depending on the desired BTU capacity. The first fan and coil unit 3540 comprises a coil assembly 3541 and one or more blower fans 3542. The second fan and coil unit 3550 comprises a coil assembly 3551 and a blower fan 3552. The coil assemblies 3541 and 3551 can be implemented using any suitable tube and fin heat exchanger configuration. In an exemplary embodiment, the one or more blower fans 3542 of the fan and coil unit 3540 are configured to blow external ambient air through the coil assembly 3541 of the first fan and coil unit 3460, while the blower face 3552 of the second fan and coil unit 3550 is configured to blow cooled air or heated air into an internal environment which is temperature-regulated by operation of the thermoelectric heating and cooling system 3500, depending on the mode of operation (e.g., cooling mode or heating mode) of the thermoelectric heating and cooling system 3500.

The thermoelectric heating and cooling system 3500 comprises a first closed loop system which comprises the coil assembly 3541 of the first fan and coil unit 3540, the first pump 3520, and one more thermal fluid chambers of the thermoelectric system 3510. The first thermal fluid fill port 3560 is utilized to fill the first closed loop system with thermal fluid. The thermoelectric heating and cooling system 3500 comprises a second closed loop system which comprises the coil assembly 3551 of the second fan and coil unit 3550, the second pump 3530, and one more thermal fluid chambers of the thermoelectric system 3510. The second thermal fluid fill port 3570 is utilized to fill the second closed loop system with thermal fluid.

The control system 3580 is configured to control the operation of the thermoelectric heating and cooling system 3500. For example, the control system 3580 controls the turning ON and OFF of the first and second pumps 3520 and 3530, and controllably adjusting the operating speeds of the first and second pumps 3520 and 3530, to thereby control the flow rate of thermal fluid in the first and second closed loop systems. Further, the control system 3580 controls the turning ON and OFF of the blower fans 3542 and 3552, and controllably adjusting the operating speeds of the of the blower fans 3542 and 3552, to thereby control the magnitude/rate of heat exchange provided by operation of the first and second fan and coil units 3540 and 3550. In addition, the control system 3580 controls the operating DC voltage (magnitude and polarity) that is applied to the thermometric module(s) of the thermoelectric system 3510 to control the cooling and heating modes of operation of the thermoelectric heating and cooling system 3500.

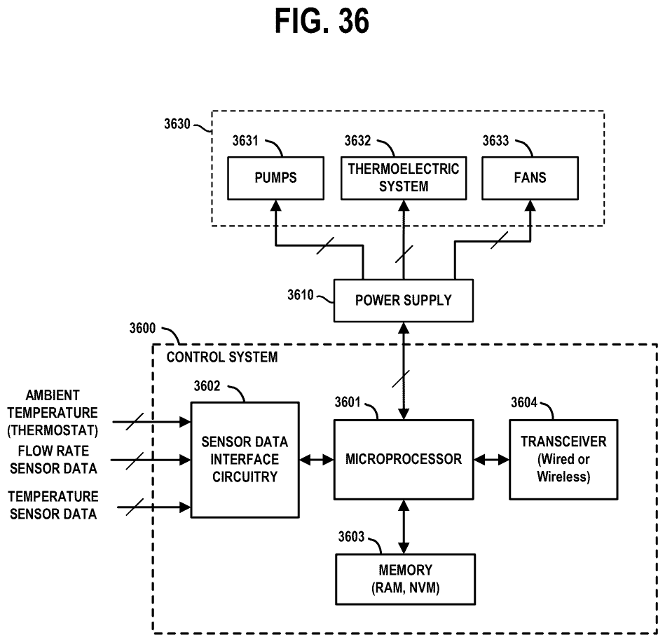

As noted above, in some embodiments, the thermoelectric system 3510 comprises (i) a plurality of integrated temperature sensors to monitor the temperature of the thermals fluids flowing into and out of the thermal fluid chambers of the thermoelectric system 3510, and/or monitor the temperature of the thermoelectric devices or components (e.g., semiconductor thermoelectric pellets, supporting substrates, etc.) of the thermoelectric system 3510 and/or (ii) a plurality of fluid flow rate sensors to monitor the flow rate of the thermals fluids flowing into and out of the thermal fluid chambers of the thermoelectric system 3510. In some embodiments, the thermoelectric heating and cooling system 3500 implements temperature sensors and flow rate sensors that disposed at certain points in line with the first and second closed loop systems to monitor the temperatures and flow rates of thermal fluids flowing into and out of the fluid chambers of the thermoelectric system 3510. The temperature and flow rate sensor data is utilized by the control system 3580 to controllably adjust operating parameters and operating conditions of the thermoelectric heating and cooling system 3500 based at least in part on the temperature and flow rate sensor data. An exemplary embodiment of the control system 3580 will be discussed in further detail below in conjunction with FIG. 36.

The thermoelectric heating and cooling system 3500 can be configured to operate in a cooling mode wherein (i) the thermoelectric system 3510 is operatively configured to cool down thermal fluid flowing in the second closed loop system by pumping heat from the thermal fluid flowing in the second closed loop system to the thermal fluid flowing in the first closed loop system, (ii) the second pump 3530 circulates the cooled thermal fluid in the second closed loop system, (iii) the second fan and coil unit 3550 blows cooled air into the internal environment which is temperature-regulated by operation of the thermoelectric heating and cooling system 3500, and (iv) the first fan and coil unit 3540 blows external ambient air through the coil assembly 3541 to cool down the heated thermal fluid flowing in first closed loop system. On the other hand, the thermoelectric heating and cooling system 3500 can be configured to operate in a heating mode wherein (i) the thermoelectric system 3510 is operatively configured to heat up thermal fluid flowing in the second closed loop system by pumping heat from the thermal fluid flowing in the first closed loop system, (ii) the second pump 3530 circulates the heated thermal fluid in the second closed loop system, (iii) the second fan and coil unit 3550 blows heated air into the internal environment which is temperature-regulated by operation of the thermoelectric heating and cooling system 3500, and (iv) the first fan and coil unit 3540 blows external ambient air through the coil assembly 3541 to heat up the cold thermal fluid flowing in first closed loop system.

FIG. 35B schematically illustrates a thermoelectric heating and cooling system, according to another exemplary embodiment of the disclosure. In particular, FIG. 35B schematically illustrates a thermoelectric heating and cooling system 3501 which is similar to the thermoelectric heating and cooling system 3500 of FIG. 35A, except that the thermoelectric heating and cooling system 3501 further implements an auxiliary heating unit 3553 (e.g., electrical heating element) in conjunction with the second fan and coil unit 3550, where the auxiliary heating unit 3553 can be utilized when the thermoelectric heating and cooling system 3501 operating in a heating mode.

For example, when the thermoelectric heating and cooling system 3501 is initially turned ON to operate in a heating mode, the auxiliary heating unit 3553 can be activated by the control system 3580 to provide “instant” hot air that is blown (via the second fan and coil unit 3550) into the internal, temperature-regulated environment, until such time that the heated thermal fluid flowing in the second closed loop (e.g., flowing in the coil assembly 3551 of the second fan and coil unit 3550) is heated to a target temperature by operation of the thermoelectric system 3510. The auxiliary heating unit 3553 can be deactivated when the heated thermal fluid flowing in the second closed loop reaches the target temperature. In other embodiments, the auxiliary heating unit 3553 can remain activated to provide some level of heat to supplement the heat drawn from the coil assembly 3551 of the second fan and coil unit 3550, when a higher temperature set point (via a thermostat setting) is desired.

In other embodiments, while not specifically shown in FIG. 35A or 35B, an auxiliary heating unit (electrical heating element) can be implemented in conjunction with the first fan and coil unit 3540, where the auxiliary heating unit is disposed between the blower fan(s) 3542 and the coil assembly 3541 of the first fan and coil unit 3540. In such embodiments, when the thermoelectric heating and cooling system 3500 or 3501 is operating in a heating mode, the auxiliary heating unit can be activated to heat the external air that is blown through the coil assembly 3541 to heat up the cold thermal fluid flowing in the coil assembly 3541 and thereby enable the thermoelectric system 3510 to operate more efficiently. Moreover, in certain instances, when the thermoelectric heating and cooling system 3500 or 3501 is operating in a heating mode, if the external air that is blown through the coil assembly 3541 is colder (lower in temperature) than the cold thermal fluid flowing through the coil assembly 3541, the heating capacity of the auxiliary heating unit can be increased to sufficiently raise the temperature of the cold thermal fluid flowing in the first closed loop before returning back to the thermoelectric module 3510 to thereby enable the thermoelectric system 3510 to operate properly and efficiently.

FIG. 36 schematically illustrates a system for controlling a thermoelectric heating and cooling system, according to an exemplary embodiment of the disclosure. In particular, FIG. 36 schematically illustrates a control system 3600, a power supply system 3610, and a thermoelectric heating and cooling system 3630 comprising various components such as pumps 3631 (which circulate thermal fluids in first and second closed loop systems), a thermoelectric system 3632, and fans 3633 (of coil and fan units). The thermoelectric heating and cooling system 3630 of FIG. 36 generically represents any of the exemplary thermoelectric heating and cooling systems described herein such as shown, for example, in FIGS. 33A, 33B, 34, 35A, 35B, 37. In some embodiments, the control system 3600 comprises a microprocessor 3601 (or some other type of hardware processor device or devices such as a microcontroller, an application specific integrated circuit (ASIC), a field programmable gate array (FPGA), a central processing unit (CPU), etc.) which is configured to execute software routines and/or control logic, control processes, etc., to intelligently control operations of the thermoelectric heating and cooling system 3630.

The control system 3600 further comprises sensor data interface circuitry 3602, memory 3603, and an optional transceiver 3604. The memory 3603 comprises volatile random-access memory (RAM) and non-volatile memory (NVM), such as Flash memory, to store calibration data, operational data, and executable code, etc., which is utilized by the microprocessor 3601 to intelligently control operations of the thermoelectric heating and cooling system 3630. The sensor data interface circuitry 3602 is configured to receive sensor data from various sensors or remote control modules (temperature sensors, thermal fluid flow rate sensor data, thermostat device, etc.) which are implemented to monitor operating conditions of the thermoelectric heating and cooling system 3630, and convert the sensor data into digital data which is processed by the microprocessor 3601 to perform respective control functions.

For example, sensor data interface circuitry 3602 is coupled to a thermostat device which is disposed within a temperature-regulated environment (e.g., building, refrigeration system, etc.). Depending on the given application, the thermostat device is utilized by an individual to, e.g., set an operating mode (heating or cooling mode) of the thermoelectric heating and cooling system 3630 and to specify a target temperature setpoint to maintain the temperature-regulated environment at or near the specified setpoint. In addition, the thermostat device comprises a temperature sensor to monitor the temperature within the temperature-regulated environment, and transmit the temperature information to the control system 3600. The sensor data interface circuitry 3602 is configured to receive control signals and sensor data from the thermostat, and convert the control signals and sensor data into digital information that is processed by the microprocessor 3601.

In addition, the sensor data interface circuitry 3602 is coupled to one or more flow sensors that are implemented within components of the thermoelectric heating and cooling system 3630 to monitor flow rates of thermal fluids that are circulated in the closed loop systems thereof. For example, as noted above, in some embodiments, the thermoelectric system 3632 comprises integrated flow sensors that are configured to monitor the flow rates of the thermal fluids that enter and/or exit the thermal fluid chambers of the thermoelectric system 3632. Moreover, in other embodiments, separate flow sensors can be incorporated within other components to monitor the flow rates of the thermal fluids that enter and/or exit the thermal fluid chambers of the thermoelectric system 3632, or otherwise monitor the flow rates of the thermal fluids (hot and cold thermal fluids) which are circulated in the closed loop systems of the thermoelectric heating and cooling system 3630. The sensor data interface circuitry 3602 is configured to receive the flow rate sensor data from the various flow sensors, and convert the flow rate sensor data into digital information that is processed by the microprocessor 3601.

Moreover, the sensor data interface circuitry 3602 is coupled to one or more temperature sensors that are implemented in the thermoelectric heating and cooling system 3630 to monitor the temperatures of the thermal fluids that are circulated in the closed loop systems thereof. For example, as noted above, in some embodiments, the thermoelectric system 3632 comprises integrated temperature sensors that are configured to monitor the temperature of the thermal fluids that enter and/or exit the thermal fluid chambers of the thermoelectric system 3632. Moreover, in other embodiments, separate temperature sensors can be incorporated within other components to monitor the temperatures of the thermal fluids which enter and/or exit the thermal fluid chambers of the thermoelectric system 3632, or otherwise monitor the temperatures of the thermal fluids (hot and cold thermal fluids) which are circulated in the closed loop systems of the thermoelectric heating and cooling system 3630. In addition, as noted above, the temperature sensor data can be obtained from temperature sensors (e.g., thermocouples or thermistors, etc.) that are integrated within thermoelectric devices or thermometric modules to monitor the temperature of various components (e.g., substrates, semiconductor thermoelectric pellets, etc.) of such thermoelectric devices or thermometric modules. The sensor data interface circuitry 3602 is configured to receive the temperature data from the various temperature sensors, and convert the temperature sensor data into digital information that is processed by the microprocessor 3601.

The microprocessor 3601 is configured to process the digital data that is generated and output from the sensor data interface circuitry 3602 to control the operations of the thermoelectric heating and cooling system 3630, based on the monitored sensor data, remote control signals, etc., received by the control system 3600 from the various flow and temperature sensors, and thermostat device. In particular, in some embodiments, the control system 3600 intelligently controls the operation of the various components (e.g., the pumps 3631, the thermoelectric system 3632, the fans 3633, etc.) of the thermoelectric heating and cooling system 3630 by controlling the power that is supplied to such components by the power supply system 3610. For example, the microprocessor 3601 can control the power supply system 3610 to control the amount of DC power that is applied to the thermoelectric system 3632 for operating the thermoelectric modules thereof (e.g., to turn OFF and ON the thermoelectric system 3632, to adjust/modulate the BTU output of the thermoelectric system 3632 at any given time, etc.), as well as switch the polarity of the DC power that is applied to the thermoelectric system 3632 to switch between cooling and heating operating modes of the thermoelectric heating and cooling system 3630.

Furthermore, the microprocessor 3601 can control the power supply system 3610 to control the amount of power (e.g., AC or DC power) that is applied the pumps 3631 to turn the pumps 3631 OFF and ON, and to adjust the operating speeds of the pumps 3631 to increase or decrease the flow rates of the thermal fluids flowing in the closed loop systems. Similarly, the microprocessor 3601 can control the power supply system 3610 to control the amount of power (e.g., AC or DC power) that is applied the fans 3632 to turn the fans 3633 OFF and ON, and adjust the operating speeds of the fans 3633 to increase or decrease the air flow rates through the coil assemblies and thereby increase or decrease the rates of heat exchange achieved by operation of the fan and coil units of the thermoelectric heating and cooling system 3630.

In some embodiments, the power supply system 3610 implements AC-to-DC converter circuitry which is configured to generate a DC voltage from AC power supplied by an AC power source (e.g., AC mains), and one or more DC-to-DC converter circuits to generate regulated DC voltages (with variable DC voltage outputs) based on the DC voltage output from the AC-to-DC converter circuitry. The regulated DC voltages are used to control the operation of the thermoelectric system 3632. In some embodiments, the pumps 3631 and fans 3633 are configured to operate with AC power. In such embodiments, the power supply system 3610 can implement AC power regulation circuitry that is configured to modulate/regulate the amount of AC power that is supplied to the pumps 3631 and fans 3633, under control of the microprocessor 3601, to control the operating speeds of the pumps 3631 and fans 3633.

In some embodiments, the optional transceiver 3604 can be implemented to enable remote control of the control system 3600 from a remote computing node or device over a wired network connection (e.g., ethernet) or a wireless network (e.g., Bluetooth, WiFi, etc.). For example, an individual can utilize a remote device to instruct the microprocessor 3601 of the control system 3600 to change the operating mode (cooling or heating) of the thermoelectric heating and cooling system 3630, adjust a temperature setpoint, etc. In addition, the transceiver 3604 can be utilized for remote monitoring of the operational state of the thermoelectric heating and cooling system 3630, etc. For example, the microprocessor 3601 can utilize the transceiver 3604 to send operational status information of the thermoelectric heating and cooling system 3630 to a remote monitoring node or device (periodically, on demand, etc.), generate alerts that are automatically transmitted to a remote monitoring node or device when error conditions of the thermoelectric heating and cooling system 3630 are detected by the control system 3600. It is to be noted that in some embodiments, the control system 3600 can be implemented in an intelligent thermostat device which utilized to control the thermoelectric heating and cooling system 3630.

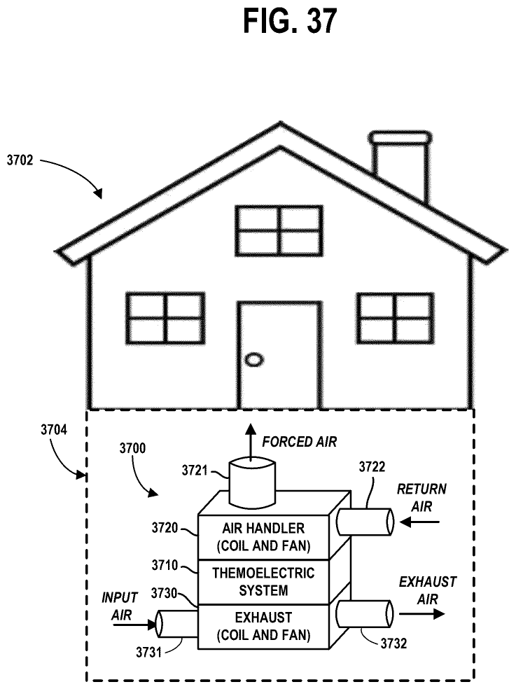

FIG. 37 schematically illustrates a thermoelectric heating and cooling system which can be implemented in a building, according to an exemplary embodiment of the disclosure. In particular, FIG. 37 schematical illustrates a thermoelectric heating and cooling system 3700 which can be implemented within a residential building 3702 such as within a basement 3704 of the residential building 3702, or in other places within the building such as a garage, attic, utility closet, etc. In some embodiments, the thermoelectric heating and cooling system 3700 comprises modular equipment components including a thermoelectric system 3710, an air handler 3720 (which comprises a first coil and fan unit, and a first pump), and an exhaust module 3730 (which comprises a second coil and fan unit, and pump).

The air handler 3720 comprises a supply plenum 3721 and a return plenum 3722. The supply plenum 3721 is connected to a network of air supply ducts within the building 3702, and the return plenum 3722 is connected to a network of air return ducts within the building 3702. The air handler 3720 blows (via operation of the fan or blower motor) forced air (which either cooled or heated) into the supply plenum 3721, and the air supply ducts distribute the forced air (cooled or heated) into the into the temperature-regulated environment within the building 3702. In addition, the air handler 3720 pulls (via operation of the fan or blower motor) return air through the air return ducts within the building 3702 into the return plenum 3722, wherein the return air passes through the coil assembly of the air handler 3720 where the return air is either cooled or heated, and then blown into the supply plenum 3721 and distributed again (via the air supply ducts) into the temperature-regulated environment within the building 3702.

The exhaust module 3730 comprises an air input port 3731 and an air exhaust port 3732. In some embodiments, the air input port 3731 is connected to one or more ducts that are routed within the building to one or more air inlet vents that are disposed to receive external air outside of the building 3702. Moreover, in some embodiments, the air exhaust port 3732 is connected to one or more ducts that are routed within the building 3702 to one or more air outlet vents that are configured to emit exhaust air outside of the building 3702.

The thermoelectric system 3710 can be implemented using any of the exemplary thermoelectric system configurations as described herein (with thermoelectric modules and thermal fluid chambers) depending on the desired BTU capacity. The thermoelectric heating and cooling system 3710 can be operated in a cooling mode or heating mode by, e.g., switching the control voltage polarity applied to thermoelectric modules of the thermoelectric system 3710, or by configuring a plurality of solenoid values (as in FIG. 34), etc. In a cooling mode of operation, thermoelectric heating and cooling system 370 is configured such that (i) cold thermal fluid is circulated in a first closed loop system which includes the coil assembly of the air handler 3720, and the thermal fluid chambers of the thermoelectric system 3710 which interface with cold sides of the thermoelectric modules of the thermoelectric system 3710, and (ii) hot thermal fluid is circulated in a second closed loop system which includes the coil assembly of the exhaust module 3730, and the thermal fluid chambers of the thermoelectric system 3710 which interface with hot sides of the thermoelectric modules of the thermoelectric system 3710.

In the cooling mode of operation, cooled air is generated and circulated within the temperature-regulated environment of the building 3702 by operation of the air handler 3720 and the air supply and return ducts, as discussed above. Moreover, the hot thermal fluid flowing in the second closed loop is cooled down by operation of the exhaust module 3730 where the fan (or blower motor) blows external air (which supplied from the air input port 3731) through the coil assembly to cool down the hot thermal fluid flowing through the coil assembly, and forces the heated exhaust air out through the air exhaust port 3732, where the heated exhaust air is routed and vented outside of the building 3702 through via the exhaust duct(s), and exhaust vent(s).

On the other hand, in a heating mode of operation, thermoelectric heating and cooling system 370 is configured such that (i) hot thermal fluid is circulated in the first closed loop system which includes the coil assembly of the air handler 3720, and the thermal fluid chambers of the thermoelectric system 3710 which interface with hot sides of the thermoelectric modules of the thermoelectric system 3710, and (ii) cold thermal fluid is circulated in the second closed loop system which includes the coil assembly of the exhaust module 3730, and the thermal fluid chambers of the thermoelectric system 3710 which interface with cold sides of the thermoelectric modules of the thermoelectric system 3710.

In the heating mode of operation, heated air is generated and circulated within the temperature-regulated environment of the building 3702 by operation of the air handler 3720 and the air supply and return ducts, as discussed above. Moreover, the cold thermal fluid flowing in the second closed loop is heated up by operation of the exhaust module 3730 where the fan (or blower motor) blows external air (which supplied from the air input port 3731) through the coil assembly to heat up the cold thermal fluid flowing through the coil assembly, and forces the cooled exhaust air out through the air exhaust port 3732, where the cooled exhaust air is routed and vented outside of the building 3702 through via the exhaust duct(s), and exhaust vent(s). As noted above, in instances where the temperature of the external air, which is pulled into the exhaust module 3730 via the fan unit, is not sufficient to heat up the cold thermal fluid flowing in the coil assembly of the exhaust module 3730, an auxiliary heating element of the exhaust module 3730 can be used to heat up the input air before is it blown through the coil assembly of the exhaust module 3730.

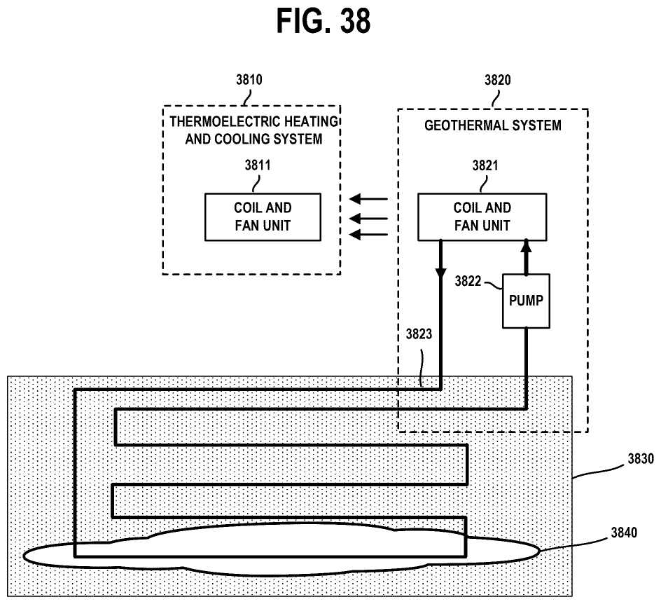

FIG. 38 schematically illustrates a thermoelectric heating and cooling system which can be implemented with a geothermal system, according to an exemplary embodiment of the disclosure. In particular, FIG. 38 schematically illustrates a thermoelectric heating and cooling system 3810 and a geothermal system 3820. The geothermal system 3820 comprises a closed loop system which comprises a coil assembly of a coil and fan unit 3821, a pump 3822, and underground piping 3823 which is routed underground 3830 and possibly passing through an underground aquifer 3840. The closed loop system of the geothermal system 3820 circulates a thermal liquid (e.g., water) which is cooled down as the thermal liquid flows through the underground piping 3823 due to the cool underground temperature. For example, depending on the given geolocation, season (e.g., summer, winter), and the depth of the underground piping 3823, etc., the temperature underground 3830 can range from 50° F. to 70° F. and remain stable over long periods as compared to the temperature above ground which can widely vary over the course of a day. In this regard, the thermal fluid (water) circulating in the closed loop system of the geothermal system 3820 is cooled down as its flows through the underground piping 3823, and utilized to provide augmented/auxiliary cooling for the thermoelectric heating and cooling system 3810.

For example, as schematically illustrated in FIG. 38, the thermoelectric heating and cooling system 3810 comprises a coil and fan unit 3811, which can be, e.g., a coil and fan unit of the air handler 3720 (FIG. 37). When the thermoelectric heating and cooling system 3810 is initially turned ON to operate in a cooling mode, the geothermal system 3820 can be utilized as an auxiliary cooling unit to blow cool air (via operation of the geothermal coil and fan unit 3821) through the coil assembly of the cold and fan unit 3811 of the air handler of the thermoelectric heating and cooling system 3810 to provide “instant” cold air that is circulated (via operation of the air handler) within the internal, temperature-regulated environment, until such time that the cold thermal fluid flowing in the coil assembly of the coil and fan unit 3811 is cooled to a target temperature by operation of the thermoelectric system. The geothermal system 3820 can be deactivated when the cold thermal fluid flowing in the coil assembly of the coil and fan unit 3811 reaches the target temperature. In other embodiments, when the temperature underground 3830 is relatively low (e.g. 55° F.) the geothermal system 3820 can remain activated to provide primary cooling by simply turning on the blower fan of the coil and fan unit 3811 of the air handler, without having to fully activate the thermoelectric heating and cooling system 3810.

In other embodiments, when the thermoelectric heating and cooling system 3810 is operating in a heating mode, the geothermal system 3820 can be utilized as an auxiliary heat source in conjunction with, e.g., the coil assembly of the exhaust module 3730 (FIG. 37) in instances where the temperature of the external air, which is pulled into the exhaust module 3730 via the fan unit, is too cold and insufficient to properly heat up the cold thermal fluid flowing in the coil assembly of the exhaust module 3730. For example, there can be an instance where the outside temperature is relatively low (e.g., 35° F. or lower), while the temperature underground 3830 is relatively higher (e.g., 55° F. or higher). In this regard, with higher temperature water circulating in the closed loop system of the geothermal system 3820, the coil and fan unit 3821 of the geothermal system 3820 can be used as an auxiliary heating element to blow warmer air through the coil assembly of the exhaust module 3730 (FIG. 37) and thereby heat up the cold thermal fluid flowing in the coil assembly of the exhaust module 3730. Moreover, in some embodiments, the geothermal system 3820 can implement two geothermal coil fan units that are utilized in conjunction with the thermoelectric heating and cooling system 3700 of FIG. 37, where one geothermal coil fan unit is disposed adjacent to the coil and fan unit of the air handler 3720, and the other geothermal coil fan unit is disposed adjacent to the coil and fan unit of the exhaust module 3730 to thereby provide the auxiliary cooling and heating operations, as discussed above, when the thermoelectric heating and cooling system 3700 is operating in a cooling mode or heating mode.

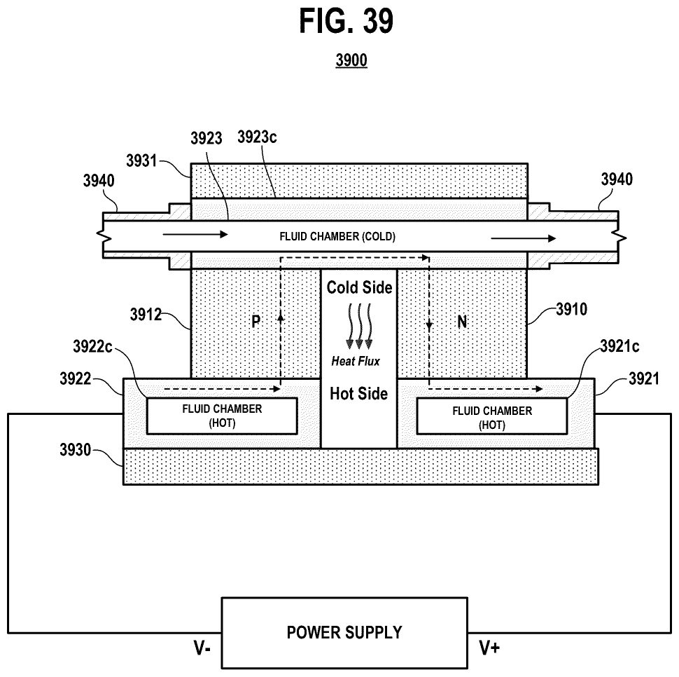

FIG. 39 schematically illustrates a thermoelectric module, according to another exemplary embodiment of the disclosure. In particular, FIG. 39 schematically illustrates a thermoelectric module 3900 comprising an architecture in which electrical interconnect pads which connect the thermoelectric pellet serve a dual purpose of providing electrical connections and incorporating thermal fluid chambers in which thermal fluid flows to perform cooling and heating functions as described herein. The thermoelectric module 3900 comprises an N-type semiconductor thermoelectric element 3910 (or N-type thermoelectric pellet) and a P-type semiconductor thermoelectric element 3912 (or P-type thermoelectric pellet), first, second, and third electrical interconnects 3921, 3922, and 3923, a first substrate 3930, and a second substrate 3931. As schematically illustrated in FIG. 39, the first, second, and third electrical interconnects 3921, 3922, and 3923 comprise respective internal thermal fluid chambers 3921c, 3922c, and 3923c. In this exemplary configuration, the first, second, and third electrical interconnects 3921, 3922, and 3923 provide electrical connections to the thermoelectric pellets, as well as provide the thermal fluid chambers 3921c, 3922c, and 3923c which are part of closed loops systems for circulating cold and hot thermal fluids for a thermoelectric heating and cooling system that is implemented using exemplary architectures and techniques as discussed above.

For example, FIG. 39 illustrates an exemplary mode of operation of the thermoelectric module 3900 with a positive polarity (V+) applied to the first electrical interconnect 3921, and a negative polarity (V−) applied to the second electrical interconnect 3922, resulting in a current flow (flow of electrons) through the thermoelectric device 3900 in the electrical path (as schematically illustrated by the dashed-line arrows) from the second electrical interconnect 3922 to the first electrical interconnect 3921. The resulting current flow through the N-type and P-type thermoelectric pellets 3910 and 3912 causes the first and second electrical interconnects 3921 and 2922 to be heated, and the third electrical interconnect 3923 to be cooled. The heating of the first and second electrical interconnects 3921 and 3922 causes heating of thermal fluid flowing in the internal thermal fluid chambers 3921c and 3922c of the first and second electrical interconnects 3921 and 3922. On the other hand, the cooling of the third electrical interconnect 3923 causes cooling of the thermal fluid flowing in the internal thermal fluid chamber 3923c of the third electrical interconnect 3923. The illustrative architecture shown in FIG. 39 can be extended to construct thermoelectric modules having an array of thermoelectric couples. In such embodiments, the internal thermal fluid chambers of adjacent electrical interconnect can be coupled using insulating water chamber elements 3904 that allow thermal fluid to flow between the internal thermal fluid chambers of the adjacent electrical interconnects, while electrically insulating the adjacent electrical interconnects.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

We claim:

1. A device, comprising:
a thermoelectric module, which comprises:
a support structure having a first outer side and a second outer side, opposite the first outer side;
a first array of interconnect pads disposed on the first outer side of the support structure;
a second array of interconnect pads disposed on the second outer side of the support structure; and
a plurality of thermoelectric semiconductor pellets disposed within the support structure, wherein each thermoelectric semiconductor pellet is connected to at least one interconnect pad of the first array of interconnect pads or the second array of interconnect pads.

2. The device of claim 1, wherein the support structure further comprises:
a first conformal layer of sealant material disposed on the first outer side of the support structure to seal perimeter edges of the interconnect pads of the first array of interconnect pads; and
a second conformal layer of sealant material disposed on the second outers side of the support structure to seal perimeter edges of the interconnect pads of the second array of interconnect pads.

3. The device of claim 1, wherein:
the support structure comprises a ceramic substrate having an array of through-holes formed through the ceramic substrate; and
each thermoelectric semiconductor pellet of the array of thermoelectric semiconductor pellets is disposed within a corresponding through-hole of the array of through-holes.

4. The device of claim 3, wherein:
the first outer side of the support structure comprises a first side of the ceramic substrate; and
the second outer side of the support structure comprise a second side of the ceramic substrate.

5. The device of claim 1, wherein:
the support structure comprises a polymer substrate having an array of through-holes formed through the polymer substrate; and
each thermoelectric semiconductor pellet of the array of thermoelectric semiconductor pellets is disposed within a corresponding through-hole of the array of through-holes.

6. The device of claim 5, wherein:
the support structure comprises a first ceramic layer disposed on a first surface of the polymer substrate, and a second ceramic layer disposed on a second surface of the polymer substrate;
the first outer side of the support structure comprises a surface of the first ceramic layer on which the first array of interconnect pads is disposed; and
the second outer side of the support structure comprises a surface of the second ceramic layer on which the second array of interconnect pads is disposed.

7. The device of claim 6, wherein the first ceramic layer and the second ceramic layer are formed of a zirconium oxide material.

8. The device of claim 5, wherein:
the support structure comprises a first glass layer disposed on a first surface of the polymer substrate, and a second glass layer disposed on a second surface of the polymer substrate;
the first outer side of the support structure comprises a surface of the first glass layer on which the first array of interconnect pads is disposed; and
the second outer side of the support structure comprises a surface of the second glass layer on which the second array of interconnect pads is disposed.

9. The device of claim 1, wherein:
the support structure comprises a first substrate and a second substrate which are fixedly disposed apart from each other with an air space therebetween;
the first substrate comprises a first array of through-holes formed through the first substrate;
the second substrate comprises a second array of through-holes formed through the second substrate, which is aligned to the first array of through-holes of the first substrate;
first ends of the thermoelectric semiconductor pellets extend through corresponding through-holes of the first array of through-holes; and
second ends of the thermoelectric semiconductor pellets extend through corresponding through-holes of the second array of through-holes.

10. The device of claim 9, wherein:
the first outer side of the support structure comprises a surface of the first substrate on which the first array of interconnect pads is disposed; and
the second outer side of the support structure comprises a surface of the second substrate on which the second array of interconnect pads is disposed.

11. The device of claim 9, wherein:
the support structure comprises a first ceramic layer disposed on a first surface of the first substrate, and a second ceramic layer disposed on a second surface of the second substrate;
the first outer side of the support structure comprises a surface of the first ceramic layer on which the first array of interconnect pads is disposed; and
the second outer side of the support structure comprises a surface of the second ceramic layer on which the second array of interconnect pads is disposed.

12. The device of claim 11, wherein the first ceramic layer and the second ceramic layer are formed of a zirconium oxide material.

13. The device of claim 1, wherein:
the support structure comprises:
a first substrate, a second substrate, and a third substrate disposed between the first substrate and the second substrate and spaced apart from the first substrate and the second substrate with air spaces therebetween;
a third array of interconnect pads disposed on a first surface of the third substrate; and
a fourth array of interconnect pads disposed on a second surface of the third substrate;
the first substrate comprises a first array of through-holes formed through the first substrate;
the second substrate comprises a second array of through-holes formed through the second substrate;
the plurality of thermoelectric semiconductor pellets comprises a first array of thermoelectric semiconductor pellets and a second array of thermoelectric semiconductor pellets;
first ends of the thermoelectric semiconductor pellets of the first array of thermoelectric semiconductor pellets extend through corresponding through-holes of the first array of through-holes and are connected to corresponding interconnect pads of the first array of interconnect pads;
second ends of the thermoelectric semiconductor pellets of the first array of thermoelectric semiconductor pellets are connected to corresponding interconnect pads of the third array of interconnect pads;
first ends of the thermoelectric semiconductor pellets of the second array of thermoelectric semiconductor pellets extend through corresponding through-holes of the second array of through-holes and are connected to corresponding interconnect pads of the second array of interconnect pads; and
second ends of the thermoelectric semiconductor pellets of the second array of thermoelectric semiconductor pellets are connected to corresponding interconnect pads of the fourth array of interconnect pads.

14. The device of claim 13, wherein:
the first substrate and the second substrate comprise polymer substrates; and
the third substrate comprises a ceramic substrate.

15. A system, comprising:
a thermoelectric module, a first fluid chamber, and a second fluid chamber;
wherein the thermoelectric module comprises:
a support structure having a first outer side and a second outer side, opposite the first outer side;
a first array of interconnect pads disposed on the first outer side of the support structure;
a second array of interconnect pads disposed on the second outer side of the support structure; and
a plurality of thermoelectric semiconductor pellets disposed within the support structure, wherein each thermoelectric semiconductor pellet is connected to at least one interconnect pad of the first array of interconnect pads or the second array of interconnect pads;
wherein the thermoelectric module is disposed between the first fluid chamber and the second fluid chamber;
wherein the first array of interconnect pads is disposed within a first opening of the first fluid chamber to enable the first array of interconnect pads to be in direct contact with a thermal transfer fluid which flows in the first fluid chamber; and
wherein the second array of interconnect pads is disposed within a second opening of the second fluid chamber to enable the second array of interconnect pads to be in direct contact with a thermal transfer fluid which flows in the second fluid chamber.

16. The system of claim 15, wherein the support structure further comprises:
a first conformal layer of sealant material disposed on the first outer side of the support structure to seal perimeter edges of the interconnect pads of the first array of interconnect pads; and
a second conformal layer of sealant material disposed on the second outers side of the support structure to seal perimeter edges of the interconnect pads of the second array of interconnect pads.

17. The system of claim 15, wherein:
the support structure comprises a first substrate and a second substrate which are fixedly disposed apart from each other with an air space therebetween;
the first substrate comprises a first array of through-holes formed through the first substrate;
the second substrate comprises a second array of through-holes formed through the second substrate, which is aligned to the first array of through-holes of the first substrate;
first ends of the thermoelectric semiconductor pellets extend through corresponding through-holes of the first array of through-holes; and
second ends of the thermoelectric semiconductor pellets extend through corresponding through-holes of the second array of through-holes.

18. The system of claim 17, wherein:
the first substrate comprises a first printed circuit board; and
the second substrate comprises a second printed circuit board.

19. The system of claim 18, wherein:
the first printed circuit board comprises a plurality of first metallic frames that are patterned on a surface of the first printed circuit board and having an array of through-holes that match the first array of through-holes;
the second printed circuit board comprises a plurality of second metallic frame that are patterned on a surface of the second printed circuit board and having an array of through-holes that match the second array of through-holes;
the interconnect pads of the first array of interconnect pads are soldered to respective first metallic frames of the plurality of first metallic frames and to respective first ends of the thermoelectric semiconductor pellets; and
the interconnect pads of the second array of interconnect pads are soldered to respective second metallic frames of the plurality of second metallic frames and to respective second ends of the thermoelectric semiconductor pellets.

20. A system, comprising:
a first fluid chamber comprising a first array of interconnect pads disposed on a first outer surface of the first fluid chamber;
a second fluid chamber comprising a second array of interconnect pads disposed on second outer surface of the second fluid chamber;
an array of thermoelectric semiconductor pellets disposed between the first outer surface of the first fluid chamber and the second outer surface of the second fluid chamber;
wherein each thermoelectric semiconductor pellet comprises (i) a first end which is connected to a given interconnect pad of the first array of interconnect pads disposed on the first outer surface of the first fluid chamber, and (ii) a second end which is connected to a given interconnect pad of the second array of interconnect pads disposed on the second outer surface of the second fluid chamber.
